(19) United States
(12) Patent Application Publication
(10) Pub. No.: US 2025/0377596 A1
(43) Pub. Date: Dec. 11, 2025

(54) SILICON-CONTAINING RESIST UNDERLAYER FILM-FORMING COMPOSITION

(71) Applicant: NISSAN CHEMICAL CORPORATION, Tokyo (JP)

(72) Inventors: Satoshi TAKEDA, Toyama (JP); Wataru SHIBAYAMA, Toyama (JP)

(73) Assignee: NISSAN CHEMICAL CORPORATION, Tokyo (JP)

(21) Appl. No.: 19/100,337

(22) PCT Filed: Sep. 19, 2023
(86) PCT No.: PCT/JP2023/033871

§ 371 Date: Jan. 31, 2025

(30) Foreign Application Priority Data
Sep. 21, 2022 (JP) 2022-150084

(51) Int. Cl. G03F 7/075; G03F 7/00; G03F 7/11; G03F 7/40; H01L 21/311

(52) U.S. Cl. CPC G03F 7/0757; G03F 7/11; G03F 7/40; G03F 7/70033; H01L 21/31138; H01L 21/31144

(57) ABSTRACT

A silicon-containing resist underlayer film-forming composition that includes a component [A]: a polysiloxane; a component [B]: an aromatic iodine compound; and a component [C]: a solvent.

### TECHNICAL FIELD

The present invention relates to a silicon-containing resist underlayer film-forming composition.

### BACKGROUND ART

In the related art, microfabrication by lithography using photoresists has been performed in the production of semiconductor devices. The microfabrication is a processing method including: forming a photoresist thin film on a semiconductor substrate such as a silicon wafer; irradiating the thin film with active rays such as ultraviolet rays through a mask pattern having a semiconductor device pattern drawn thereon; developing the irradiated thin film; and etching the substrate with the resultant photoresist pattern serving as a protective film to form, on the surface of the substrate, fine irregularities corresponding to the pattern.

In recent years, as a result of an increase in the degree of integration of semiconductor devices, active rays having a shorter wavelength have tended to be used, i.e. shifting from KrF excimer laser (248 nm) to ArF excimer laser (193 nm). The use of such active rays having a shorter wavelength causes a serious problem in terms of reflection of active rays from a semiconductor substrate. In order to avoid such a problem, there has been widely used a method of providing a resist underlayer film called anti-reflective coating (Bottom Anti-Reflective Coating, BARC) between a photoresist and a to-be-processed substrate.

A film known as a hard mask containing a metal element such as silicon or titanium has been used as an underlayer between a semiconductor substrate and a photoresist. In this case, the resist and the hard mask are significantly different in components, and the rates to remove the resist and hard mask by dry etching are greatly dependent on the types of gas used for dry etching. Therefore, the appropriate selection of a gas type allows the hard mask to be removed by dry etching without a large reduction in the film thickness of the photoresist. Thus, in the production of semiconductor devices in recent years, a resist underlayer film has been increasingly disposed between a semiconductor substrate and a photoresist to achieve various effects such as an antireflection effect.

Although compositions for resist underlayer films have been studied so far, and development of a new material for the resist underlayer film has been desired because a variety of characteristics are required for the resist underlayer film. For example, Patent Literature 1 discloses a coating-type composition for forming a boron phosphorus glass (BPSG) film containing a structure having a specific silicic acid as a skeleton in response to the issue of forming a wet-etchable film, and Patent Literature 2 discloses a silicon-containing resist underlayer film-forming composition containing a carbonyl structure in response to the issue of providing a method for removing a mask residue with a chemical solution after lithography.

### CITATION LIST

### Patent Literature

Patent Literature 1: JP 2016-74774 A
Patent Literature 2: WO 2018/181989 A

### SUMMARY OF INVENTION

### Technical Problem

In the most advanced semiconductor device processing, as the microfabrication further progresses, there is an issue of reducing line width roughness (LWR) of a line pattern. A pattern having high roughness deteriorates electrical characteristics of a device, and thus it is necessary to reduce roughness of a resist pattern and reduce roughness of a resist underlayer film pattern formed by transfer of the resist pattern.

The present invention has been made in view of such circumstances, and it is an object of the present invention to provide a silicon-containing resist underlayer film-forming composition capable of forming a silicon-containing resist underlayer film having a small LWR, a silicon-containing resist underlayer film formed from the silicon-containing resist underlayer film-forming composition, a laminate including the silicon-containing resist underlayer film, a method for producing a semiconductor element using the silicon-containing resist underlayer film-forming composition, and a method for forming a pattern.

### Solution to Problem

As a result of intensive studies to solve the above problem, the present inventors have found that the above problem can be solved, thereby completing the present invention having the following gist.

That is, the present invention includes the followings.

[1] A silicon-containing resist underlayer film-forming composition including:
a component [A]: a polysiloxane;
a component [B]: an aromatic iodine compound; and
a component [C]: a solvent.

[2] The silicon-containing resist underlayer film-forming composition according to [1], wherein the component [B] includes at least one selected from a carboxy group, a hydroxy group, a sulfo group, and an amino group.

[3] The silicon-containing resist underlayer film-forming composition according to [1] or [2], wherein the component [B] is an aromatic iodonium salt.

[4] The silicon-containing resist underlayer film-forming composition according to any one of [1] to [3], wherein a content of the component [B] is 0.1 to 20 parts by mass relative to 100 parts by mass of the component [A].

[5] The silicon-containing resist underlayer film-forming composition according to any one of [1] to [4], wherein the component [A] includes a modified polysiloxane in which at least some of silanol groups are alcohol-modified or acetal-protected.

[6] The silicon-containing resist underlayer film-forming composition according to any one of [1] to [5], wherein the component [C] contains an alcohol-based solvent.

[7] The silicon-containing resist underlayer film-forming composition according to [6], wherein the component [C] contains alkylene glycol monoalkyl ether.

[8] The silicon-containing resist underlayer film-forming composition according to any one of [1] to [7], wherein the component [C] contains water.

[9] The silicon-containing resist underlayer film-forming composition according to any one of [1] to [8], further including a component [D]: a curing catalyst.

[10] The silicon-containing resist underlayer film-forming composition according to [9], wherein the component [D] is not an aromatic iodonium salt.

[11] The silicon-containing resist underlayer film-forming composition according to any one of [1] to [10], further including a component [E]: nitric acid.

[12] The silicon-containing resist underlayer film-forming composition according to any one of [1] to [11], wherein the component [A] does not have an iodine atom directly bonded to a benzene ring.

[13] The silicon-containing resist underlayer film-forming composition according to any one of [1] to [12], which is for a resist underlayer film for lithography.

[14] The silicon-containing resist underlayer film-forming composition according to [13], which is for a resist underlayer film for EUV or ArF lithography.

[15] A silicon-containing resist underlayer film which is a cured product of the silicon-containing resist underlayer film-forming composition according to in any one of [1] to [14].

[16] A laminate including: a semiconductor substrate; and the silicon-containing resist underlayer film according to.

[17] A method for producing a semiconductor element, the method including the steps of:
forming an organic underlayer film on a substrate;
forming a silicon-containing resist underlayer film using the silicon-containing resist underlayer film-forming composition according to any one of [1] to on the organic underlayer film; and
forming a resist film on the silicon-containing resist underlayer film.

[18] The method for producing a semiconductor element according to [17], wherein in the step of forming a silicon-containing resist underlayer film, the silicon-containing resist underlayer film-forming composition filtered through a nylon filter is used.

[19] A method for forming a pattern, the method including the steps of:
forming an organic underlayer film on a semiconductor substrate;
applying the silicon-containing resist underlayer film-forming composition according to any one of [1] to on the organic underlayer film and baking to form a silicon-containing resist underlayer film;
forming a resist film on the silicon-containing resist underlayer film;
exposing and developing the resist film to obtain a resist pattern;
etching the silicon-containing resist underlayer film using the resist pattern as a mask; and
etching the organic underlayer film using the patterned silicon-containing resist underlayer film as a mask.

[20] The method for forming a pattern according to [19], further including a step of removing the silicon-containing resist underlayer film by a wet method using a chemical solution, after the step of etching the organic underlayer film.

### Advantageous Effects of Invention

According to the present invention, it is possible to provide a silicon-containing resist underlayer film-forming composition capable of forming a silicon-containing resist underlayer film having a small LWR, a silicon-containing resist underlayer film formed from the silicon-containing resist underlayer film-forming composition, a laminate including the silicon-containing resist underlayer film, a method for producing a semiconductor element using the silicon-containing resist underlayer film-forming composition, and a method for forming a pattern.

### DESCRIPTION OF EMBODIMENTS

### (Silicon-Containing Resist Underlayer Film-Forming Composition)

The silicon-containing resist underlayer film-forming composition of the present invention contains a polysiloxane as a component [A], an aromatic iodine compound as a component [B], and a solvent as a component [C], further contains an additional component, if necessary.

The present inventors have found that when the silicon-containing resist underlayer film-forming composition containing the polysiloxane includes the aromatic iodine compound as the component [B], the LWR of the resultant line pattern of the silicon-containing resist underlayer film can be reduced, as compared with the case where the aromatic iodine compound is not included.

### <Component [A]: Polysiloxane>

The polysiloxane as the component [A] is not particularly limited as long as it is a polymer having a siloxane bond.

The polysiloxane may include a modified polysiloxane in which some of silanol groups are modified, for example, a modified polysiloxane in which some of silanol groups are alcohol-modified or acetal-protected.

Further, the polysiloxane may contain, as an example, a hydrolysis condensate of a hydrolyzable silane, and may contain a modified polysiloxane in which at least some of silanol groups of the hydrolysis condensate are alcohol-modified or acetal-protected. The hydrolyzable silane corresponding to the hydrolysis condensate may contain one or two or more hydrolyzable silanes.

Further, the polysiloxane may have a structure having a cage-shaped, ladder-shaped, linear, or branched main chain. Furthermore, the polysiloxane to be used may be a commercially available polysiloxane.

In the present invention, the “hydrolysis condensate”, i.e. product of hydrolysis condensation, of the hydrolyzable silane includes a polyorganosiloxane polymer which is a condensate prepared through complete condensation, and a polyorganosiloxane polymer which is a partial hydrolysis condensate prepared through incomplete condensation. Such a partial hydrolysis condensate is a polymer prepared through hydrolysis and condensation of a hydrolyzable silane compound, as in the case of a condensate prepared through complete condensation. However, the partial hydrolysis condensate contains remaining Si—OH groups, due to partial or incomplete hydrolysis and condensation of the silane compound. Further, the silicon-containing resist underlayer film-forming composition may contain an uncondensed hydrolysate (complete hydrolysate or partial hydrolysate) or a remaining monomer (hydrolyzable silane), in addition to the hydrolysis condensate.

In the present specification, the “hydrolyzable silane” may be simply referred to as “silane compound”.

The polysiloxane may have or need not have an iodine atom.

The polysiloxane may have an organic group having an iodine atom, or need not have an organic group having an iodine atom. The organic group is, for example, directly bonded to a silicon atom.

The polysiloxane may have an iodine atom directly bonded to an aromatic ring, or need not have an iodine atom directly bonded to an aromatic ring.

The polysiloxane may have an iodine atom directly bonded to a benzene ring, or need not have an iodine atom directly bonded to a benzene ring.

The polysiloxane may be, for example, a hydrolysis condensate of a hydrolyzable silane containing at least one hydrolyzable silane represented by the following Formula (1).

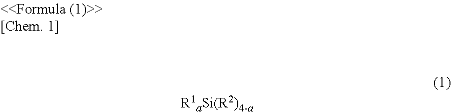

In Formula (1), R¹ is a group bonded to a silicon atom, and represents an optionally substituted alkyl group, an optionally substituted aryl group, an optionally substituted aralkyl group, an optionally substituted alkyl halide group, an optionally substituted aryl halide group, an optionally substituted aralkyl halide group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more of these groups.
R² is a group or atom bonded to a silicon atom, and each independently represents an alkoxy group, an aralkyloxy group, an acyloxy group, or a halogen atom.
a represents an integer of 0 to 3.

### <<<R¹>>>

The alkyl group may be linear, branched, or cyclic, and the number of carbon atoms thereof is not particularly limited, but is preferably 40 or less, more preferably 30 or less, still more preferably 20 or less, and yet still more preferably 10 or less.

Specific examples of the linear or branched alkyl group as the alkyl group include a methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

In the present specification, “i” means “iso”, “s” means “sec”, and “t” means “tert”.

Specific examples of the cyclic alkyl group include cycloalkyl groups, such as cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, cycloalkyl groups, such as 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group; and crosslinked cyclic cycloalkyl groups, such as bicyclobutyl group, bicyclopentyl group, bicyclohexyl group, bicycloheptyl group, bicyclooctyl group, bicyclononyl group, and bicyclodecyl group.

The aryl group may be any of a phenyl group, a monovalent group derived by removing one hydrogen atom from a condensed-ring aromatic hydrocarbon compound, and a monovalent group derived by removing one hydrogen atom from a linked-ring aromatic hydrocarbon compound. The number of carbon atoms of the aryl group is not particularly limited, but is preferably 40 or less, more preferably 30 or less, and still more preferably 20 or less.

Examples of the aryl group include an aryl group having 6 to 20 carbon atoms, and examples thereof include, but are not limited thereto, a phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 5-naphthacenyl group, 2-chrysenyl group, 1-pyrenyl group, 2-pyrenyl group, pentacenyl group, benzopyranyl group, and triphenylenyl group, biphenyl-2-yl group (o-biphenylyl group), biphenyl-3-yl group (m-biphenylyl group), biphenyl-4-yl group (p-biphenylyl group), paraterphenyl-4-yl group, metaterphenyl-4-yl group, orthoterphenyl-4-yl group, 1,1′-binaphthyl-2-yl group, and 2,2′-binaphthyl-1-yl group.

The aralkyl group is an alkyl group substituted with an aryl group, and specific examples of the aryl group and the alkyl group are the same as those described above. The number of carbon atoms of the aralkyl group is not particularly limited, but is preferably 40 or less, more preferably 30 or less, and still more preferably 20 or less.

Specific examples of the aralkyl group include, but are not limited thereto, a phenylmethyl group (benzyl group), 2-phenylethylene group, 3-phenyl-n-propyl group, 4-phenyl-n-butyl group, 5-phenyl-n-pentyl group, 6-phenyl-n-hexyl group, 7-phenyl-n-heptyl group, 8-phenyl-n-octyl group, 9-phenyl-n-nonyl group, and 10 phenyl-n-decyl group.

The alkyl halide group, the aryl halide group, and the aralkyl halide group are an alkyl group substituted with one or more halogen atoms, an aryl group substituted with one or more halogen atoms, and an aralkyl group substituted with one or more halogen atoms, respectively. Specific examples of the alkyl halide group, the aryl halide group, and the aralkyl halide group are the same as those described above.

Examples of the halogen atom include a fluorine atom, a chlorine atom, a bromine atom, and an iodine atom.

The number of carbon atoms of the alkyl halide group is not particularly limited, but is preferably 40 or less, more preferably 30 or less, still more preferably 20 or less, and yet still more preferably 10 or less.

Specific examples of the alkyl halide group include, but are not limited to, a monofluoromethyl group, difluoromethyl group, trifluoromethyl group, bromodifluoromethyl group, 2-chloroethyl group, 2-bromoethyl group, 1,1-difluoroethyl group, 2,2,2-trifluoroethyl group, 1,1,2,2-tetrafluoroethyl group, 2-chloro-1,1,2-trifluoroethyl group, pentafluoroethyl group, 3-bromopropyl group, 2,2,3,3-tetrafluoropropyl group, 1,1,2,3,3,3-hexafluoropropyl group, 1,1,1,3,3,3-hexafluoropropane-2-yl group, 3-bromo-2-methylpropyl group, 4-bromobutyl group, and perfluoropentyl group.

The number of carbon atoms of the aryl halide group is not particularly limited, but is preferably 40 or less, more preferably 30 or less, and still more preferably 20 or less.

Specific examples of the aryl halide include a 2-fluorophenyl group, 3-fluorophenyl group, 4-fluorophenyl group, 2,3-difluorophenyl group, 2,4-difluorophenyl group, 2,5-difluorophenyl group, 2,6-difluorophenyl group, 3,4-difluorophenyl group, 3,5-difluorophenyl group, 2,3,4-trifluorophenyl group, 2,3,5-trifluorophenyl group, 2,3,6-trifluorophenyl group, 2,4,5-trifluorophenyl group, 2,4,6-trifluorophenyl group, 3,4,5-trifluorophenyl group, 2,3,4,5-tetrafluorophenyl group, 2,3,4,6-tetrafluorophenyl group, 2,3,5,6-tetrafluorophenyl group, pentafluorophenyl group, 2-fluoro-1-naphthyl group, 3-fluoro-1-naphthyl group, 4-fluoro-1-naphthyl group, 6-fluoro-1-naphthyl group, 7-fluoro-1-naphthyl group, 8-fluoro-1-naphthyl group, 4,5-difluoro-1-naphthyl group, 5,7-difluoro-1-naphthyl group, 5,8-difluoro-1-naphthyl group, 5,6,7,8-tetrafluoro-1-naphthyl group, heptafluoro-1-naphthyl group, 1-fluoro-2-naphthyl group, 5-fluoro-2-naphthyl group, 6-fluoro-2-naphthyl group, 7-fluoro-2-naphthyl group, 5,7-difluoro-2-naphthyl group, and heptafluoro-2-naphthyl group. Examples thereof also include groups in which fluorine atoms (fluoro groups) in the above groups are optionally substituted with chlorine atoms (chloro groups), bromine atoms (bromo groups), or iodine atoms (iodine groups), but not limited thereto.

The number of carbon atoms of the aralkyl halide group is not particularly limited, but is preferably 40 or less, more preferably 30 or less, and still more preferably 20 or less.

Specific examples of the aralkyl halide group include a 2-fluorobenzyl group, 3-fluorobenzyl group, 4-fluorobenzyl group, 2,3-difluorobenzyl group, 2,4-difluorobenzyl group, 2,5-difluorobenzyl group, 2,6-difluorobenzyl group, 3,4-difluorobenzyl group, 3,5-difluorobenzyl group, 2,3,4-trifluorobenzyl group, 2,3,5-trifluorobenzyl group, 2,3,6-trifluorobenzyl group, 2,4,5-trifluorobenzyl group, 2,4,6-trifluorobenzyl group, 2,3,4,5-tetrafluorobenzyl group, 2,3,4,6-tetrafluorobenzyl group, 2,3,5,6-tetrafluorobenzyl group, and 2,3,4,5,6-pentafluorobenzyl group. Examples thereof also include groups in which fluorine atoms (fluoro groups) in the above groups are optionally substituted with chlorine atoms (chloro groups), bromine atoms (bromo groups), or iodine atoms (iodine groups), but not limited thereto.

The alkoxyalkyl group, the alkoxyaryl group, and the alkoxyaralkyl group are an alkyl group substituted with one or more alkoxy groups, an aryl group substituted with one or more alkoxy groups, and an aralkyl group substituted with one or more alkoxy groups, respectively. Specific examples of the alkoxyalkyl group, the alkoxyaryl group, and the alkoxyaralkyl group are the same as those described above.

The alkoxy group as the substituent is, for example, an alkoxy group having at least any one of linear, branched, and cyclic alkyl moieties having 1 to 20 carbon atoms.

Examples of the linear or branched alkoxy group include a methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group.

Examples of the cyclic alkoxy group include a cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

Specific examples of the alkoxyalkyl group include, but are not limited to, lower (about 5 or less carbon atoms) alkyloxy lower (about 5 or less carbon atoms) alkyl groups, such as methoxymethyl group, ethoxymethyl group, 1-ethoxyethyl group, 2-ethoxyethyl group, and ethoxymethyl group.

Specific examples of the alkoxyaryl group include, but are not limited to, a 2-methoxyphenyl group, 3-methoxyphenyl group, 4-methoxyphenyl group, 2-(1-ethoxy)phenyl group, 3-(1-ethoxy)phenyl group, 4-(1-ethoxy)phenyl group, 2-(2-ethoxy)phenyl group, 3-(2-ethoxy)phenyl group, 4-(2-ethoxy)phenyl group, 2-methoxynaphthalene-1-yl group, 3-methoxynaphthalene-1-yl group, 4-methoxynaphthalene-1-yl group, 5-methoxynaphthalene-1-yl group, 6-methoxynaphthalene-1-yl group, and 7-methoxynaphthalene-1-yl group.

Specific examples of the alkoxyaralkyl group include, but are not limited to, a 3-(methoxyphenyl)benzyl group and a 4-(methoxyphenyl)benzyl group.

The alkenyl group may be linear or branched, and the number of carbon atoms of the linear or branched alkenyl group is not particularly limited, but is preferably 40 or less, more preferably 30 or less, still more preferably 20 or less, and yet still more preferably 10 or less.

Specific examples of the alkenyl group include an ethenyl group (vinyl group), 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3 pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group. Examples thereof also include crosslinked cyclic alkenyl groups such as a bicycloheptenyl group (norbornyl group).

Examples of the substituent in the aforementioned alkyl group, aryl group, aralkyl group, alkyl halide group, aryl halide group, aralkyl halide group, alkoxyalkyl group, alkoxyaryl group, alkoxyaralkyl group, and alkenyl group described above include an alkyl group, an aryl group, an aralkyl group, an alkyl halide group, an aryl halide group, an aralkyl halide group, an alkoxyalkyl group, an aryloxy group, an alkoxyaryl group, an alkoxyaralkyl group, an alkenyl group, an alkoxy group, and an aralkyloxy group. Specific examples thereof and the preferred number of carbon atoms thereof are the same as those described above or below.

The aryloxy group as described in the substituent is a group in which an aryl group is bonded via an oxygen atom (—O—), and specific examples of the aryl group are the same as those described above. The number of carbon atoms in the aryloxy group is not particularly limited, but is preferably 40 or less, more preferably 30 or less, and still more preferably 20 or less. Specific examples thereof include, but are not limited to, phenoxy group and naphthalene-2-yloxy group.

When two or more substituents are present, the substituents may be bonded together to form a ring.

Examples of the organic group having an epoxy group include glycidoxymethyl group, glycidoxyethyl group, glycidoxypropyl group, glycidoxybutyl group, and epoxy cyclohexyl group.

Examples of the organic group having an acryloyl group include an acryloyl methyl group, an acryloyl ethyl group, and an acryloyl propyl group.

Examples of the organic group having a methacryloyl group include a methacryloyl methyl group, a methacryloyl ethyl group, and a methacryloyl propyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include, but are not limited to, an amino group, an aminomethyl group, an aminoethyl group, an aminophenyl, a dimethylaminoethyl group, and a dimethylaminopropyl group. The organic group having an amino group will be described later in more detail.

Examples of the organic group having an alkoxy group include, but are not limited to, a methoxymethyl group and a methoxyethyl group. However, the organic group excludes a group wherein an alkoxy group is directly bonded to a silicon atom.

Examples of the organic group having a sulfonyl group include, but are not limited to, a sulfonylalkyl group and a sulfonylaryl group.

Examples of the organic group having a cyano group include a cyanoethyl group, a cyanopropyl group, a cyanophenyl, and a thiocyanate group.

The organic group having an amino group is, for example, an organic group having at least one of a primary amino group, a secondary amino group, or a tertiary amino group. A hydrolysis condensate in which a hydrolyzable silane having a tertiary amino group is hydrolyzed with a strong acid to form a counter cation having a tertiary ammonium group can be preferably used. The organic group may contain a heteroatom such as an oxygen atom or a sulfur atom, in addition to the nitrogen atom forming the amino group.

A preferable example of the organic group having an amino group is a group represented by the following Formula (A1).

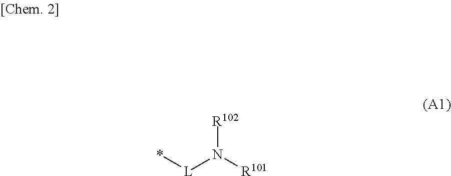

where in Formula (A1), R¹⁰¹ and R¹⁰² each independently represent a hydrogen atom or a hydrocarbon group, and L represents an independently and optionally substituted alkylene group. An asterisk * represents a bonding hand.

Examples of the hydrocarbon group include, but are not limited to, an alkyl group, an alkenyl group, and an aryl group. Specific examples of the alkyl group, the alkenyl group, and the aryl group are the same as those described above regarding R¹.

The alkylene group may be linear or branched, and the number of carbon atoms of the linear or branched alkylene group is ordinarily 1 to 10, preferably 1 to 5. Examples of the linear or branched alkylene group include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group.

Examples of the organic group having an amino group include, but are not limited to, an amino group, an aminomethyl group, an aminoethyl group, an aminophenyl, a dimethylaminoethyl group, and a dimethylaminopropyl group.

### <<<R²>>>

Examples of the alkoxy group in R² include the alkoxy groups exemplified in the description of R¹.

Examples of the halogen atom in R² include the halogen atoms exemplified in the description of R¹.

The aralkyloxy group is a monovalent group derived by removing a hydrogen atom from a hydroxy group of aralkyl alcohol, and specific examples of the aralkyl group in the aralkyloxy group are the same as those described above.

The number of carbon atoms of the aralkyloxy group is not particularly limited, but may be, for example, 40 or less, preferably 30 or less, and more preferably 20 or less.

Specific examples of the aralkyloxy group include, but are not limited to, a phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl n-hexyloxy group, 7-phenyl-n-heptyloxy group, 8-phenyl-n-octyloxy group, 9-phenyl-n-nonyloxy group, and 10-phenyl-n-decyloxy group.

The acyloxy group is a monovalent group derived by removing a hydrogen atom from a carboxyl group (—COOH) of a carboxylic acid compound, and examples of the acyloxy group typically include, but are not limited to, an alkylcarbonyloxy group, an arylcarbonyloxy group, or an aralkylcarbonyloxy group, derived by removing a hydrogen atom from a carboxyl group of an alkyl carboxylic acid, an aryl carboxylic acid, or an aralkyl carboxylic acid. Specific examples of the alkyl group, aryl group, and aralkyl group in the alkyl carboxylic acid, aryl carboxylic acid, and aralkyl carboxylic acid are the same as those described above.

Specific examples of the acyloxy group include an acyloxy group having 2 to 20 carbon atoms, and examples thereof include a methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

### <<<Specific Example of Hydrolyzable Silane Represented by Formula (1)>>>

Specific examples of the hydrolyzable silane represented by Formula (1) include, but are not limited to, tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl) propyltrimethoxysilane, γ-(3,4-epoxycyclohexyl) propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl) silane, triethoxy ((2-methoxy-4-(methoxymethyl) phenoxy)methyl) silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenethylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanatepropyltriethoxysilane, chloromethyltrimethoxysilane, chloromethyltriethoxysilane, triethoxysilylpropyldiallylisocyanurate, bicyclo[2,2,1]heptenyltriethoxysilane, benzenesulfonylpropyltriethoxysilane, benzenesulfonamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiehoxysilane, methylvinyldimethoxysilane, methylvinyldiethoxysilane, silanes represented by the following Formulae (A-1) to (A-41), silanes represented by the following Formulae (1-1) to (1-290).

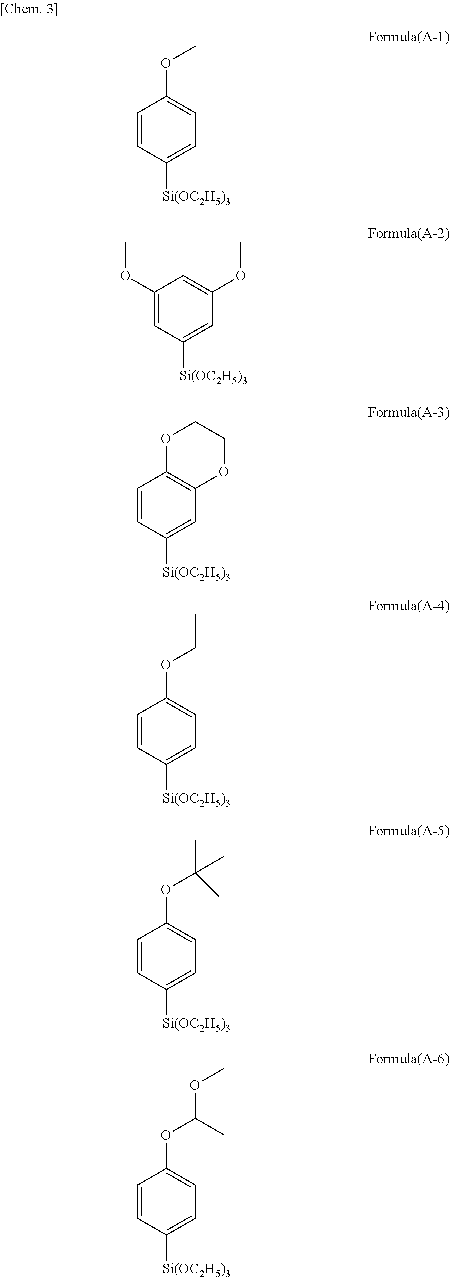

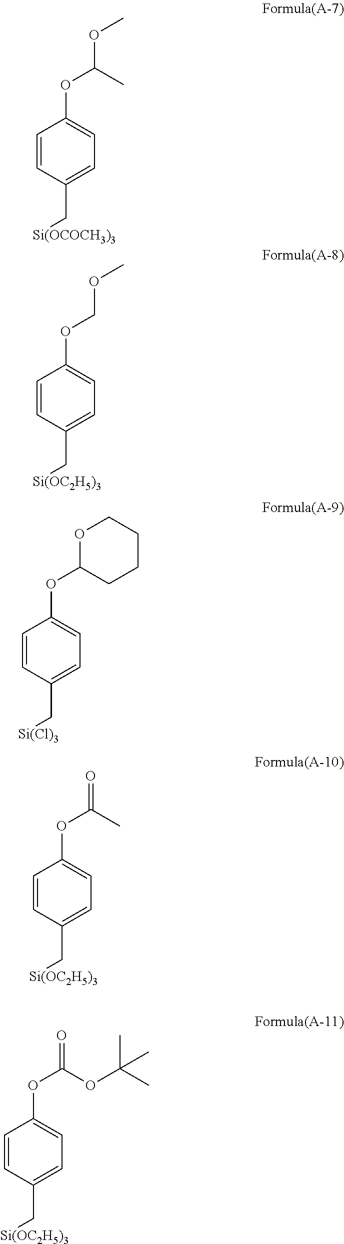

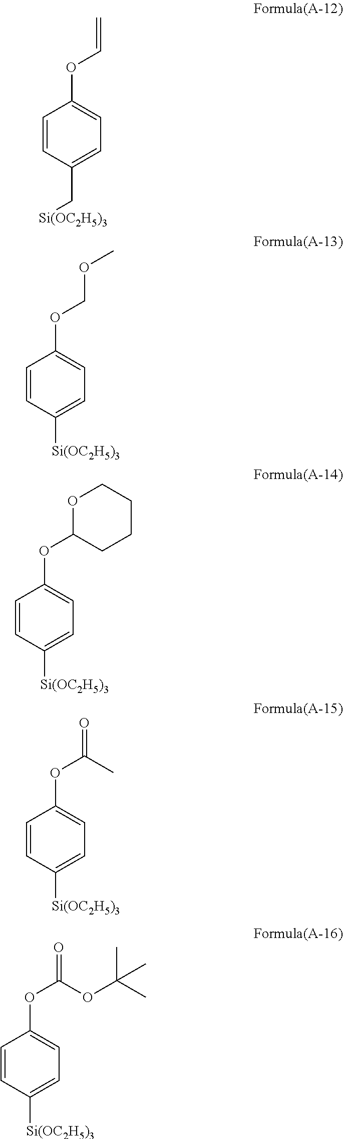

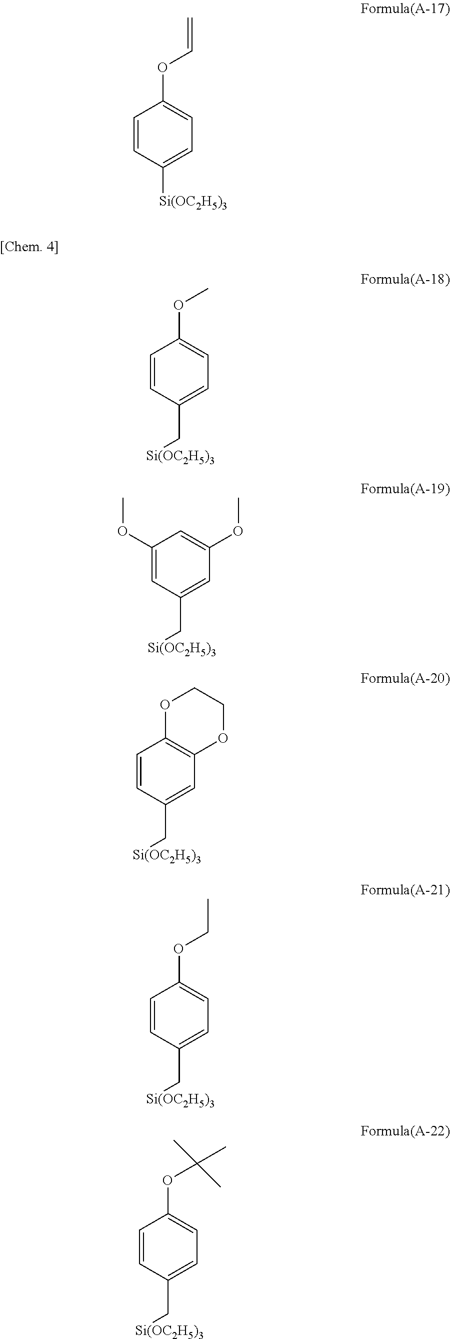

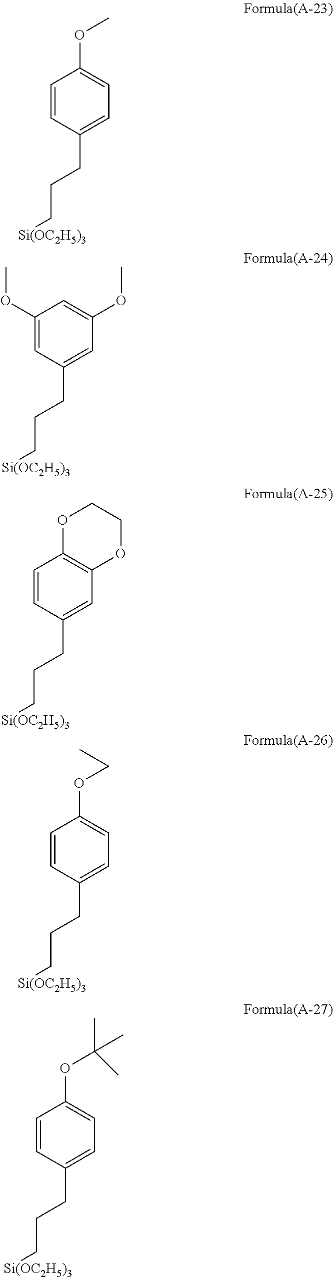

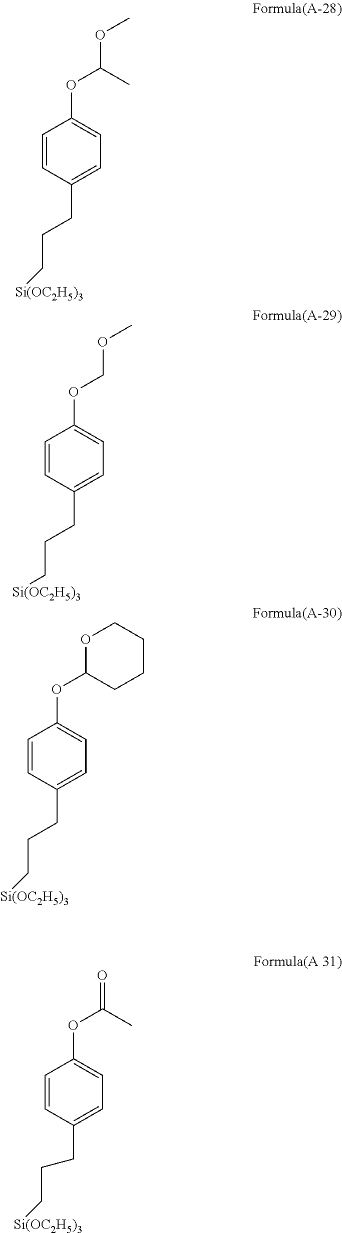

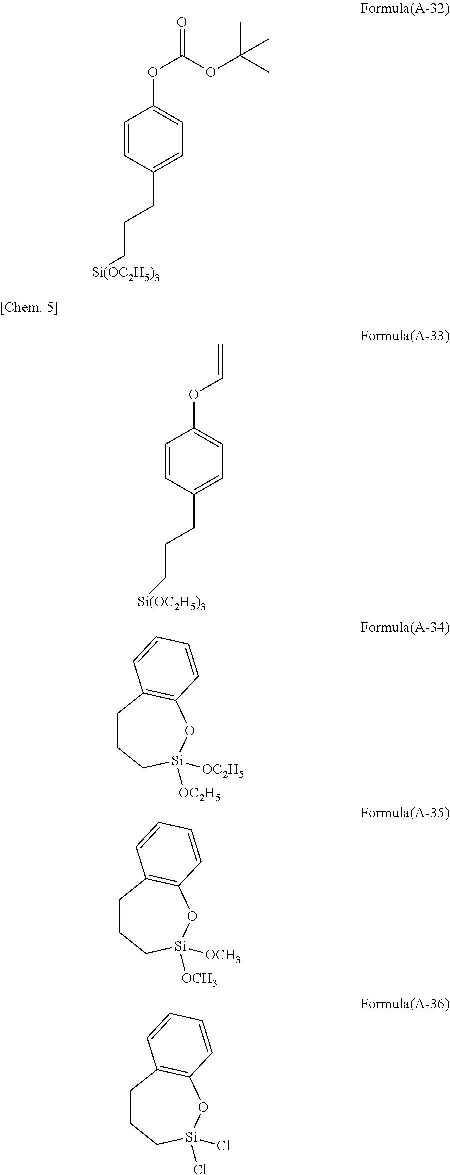

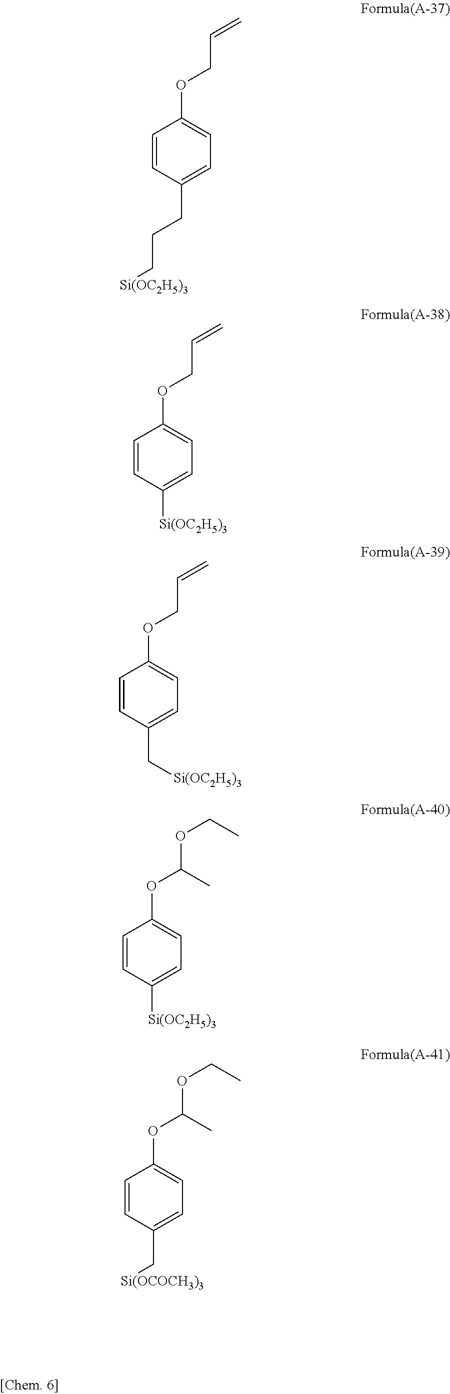

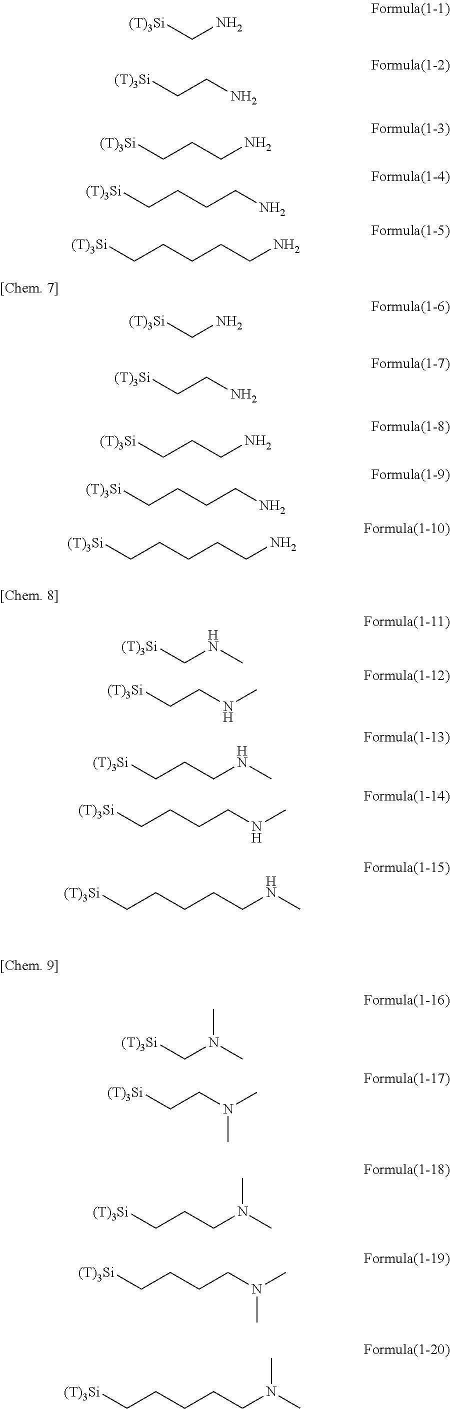

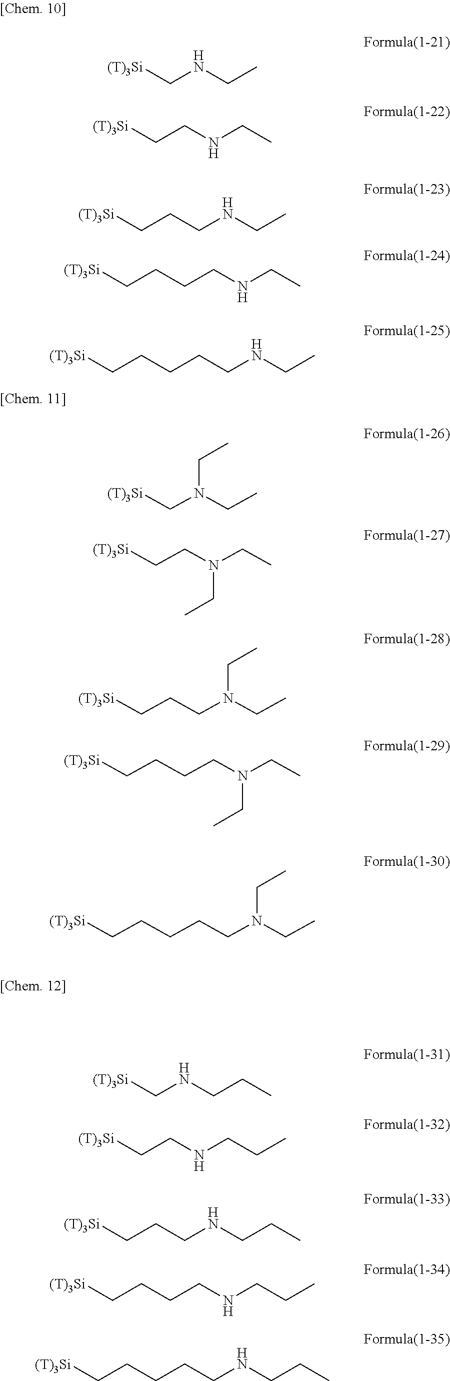

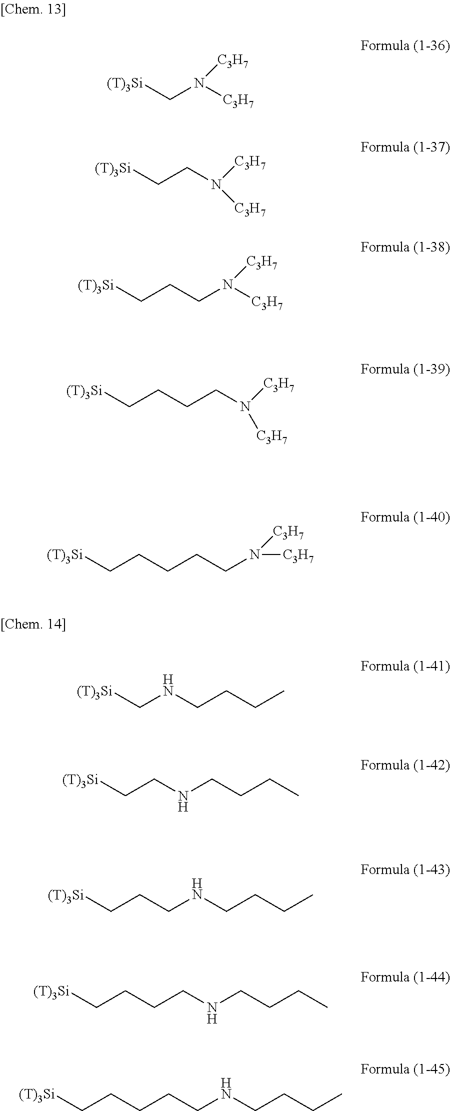

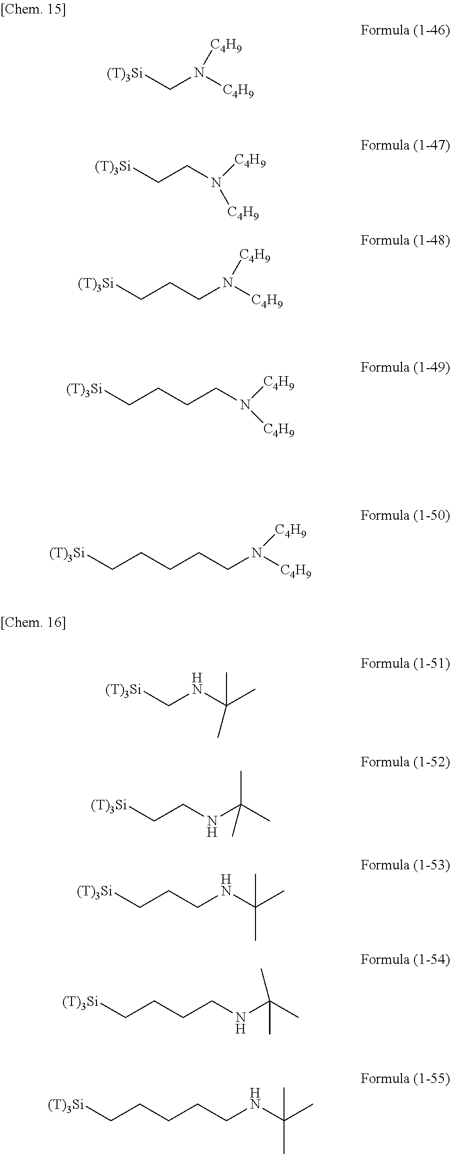

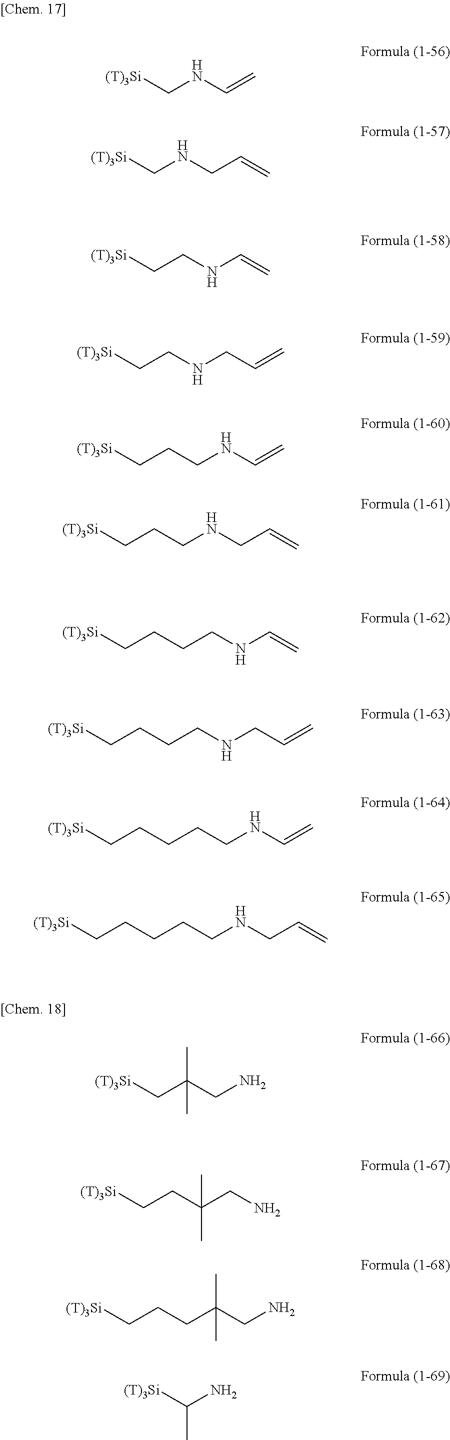

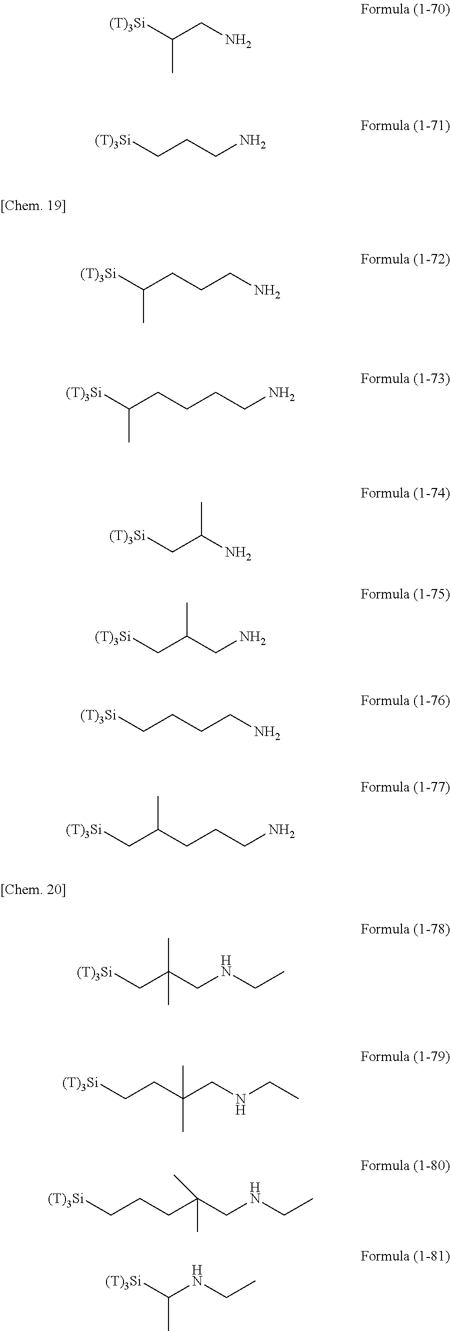

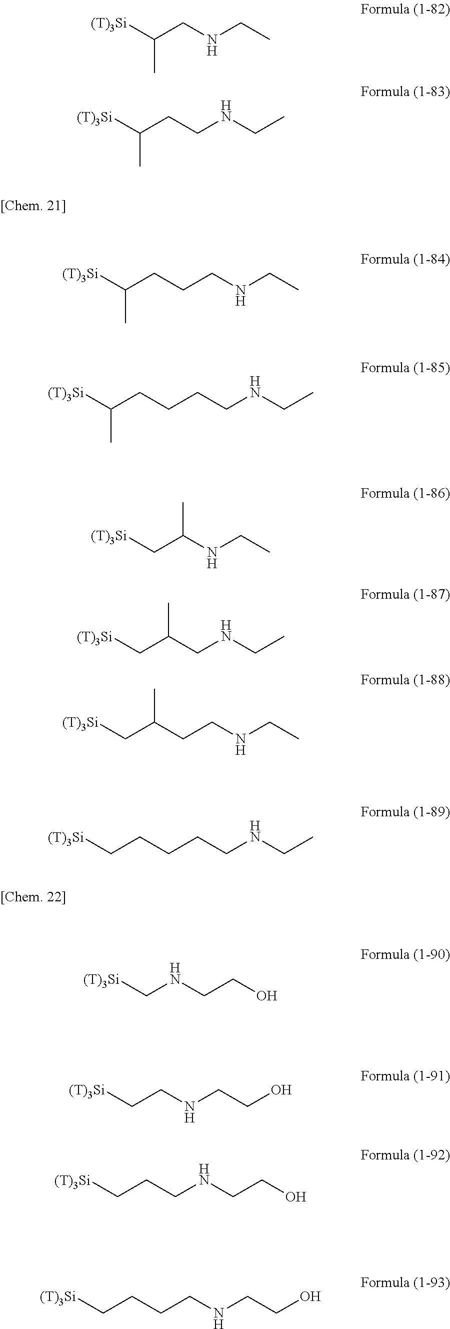

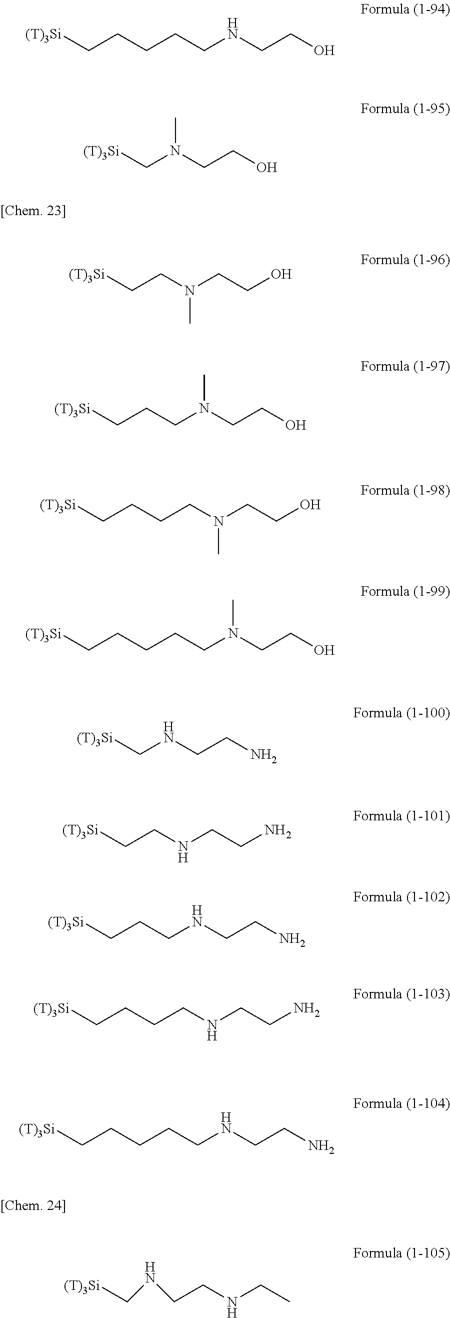

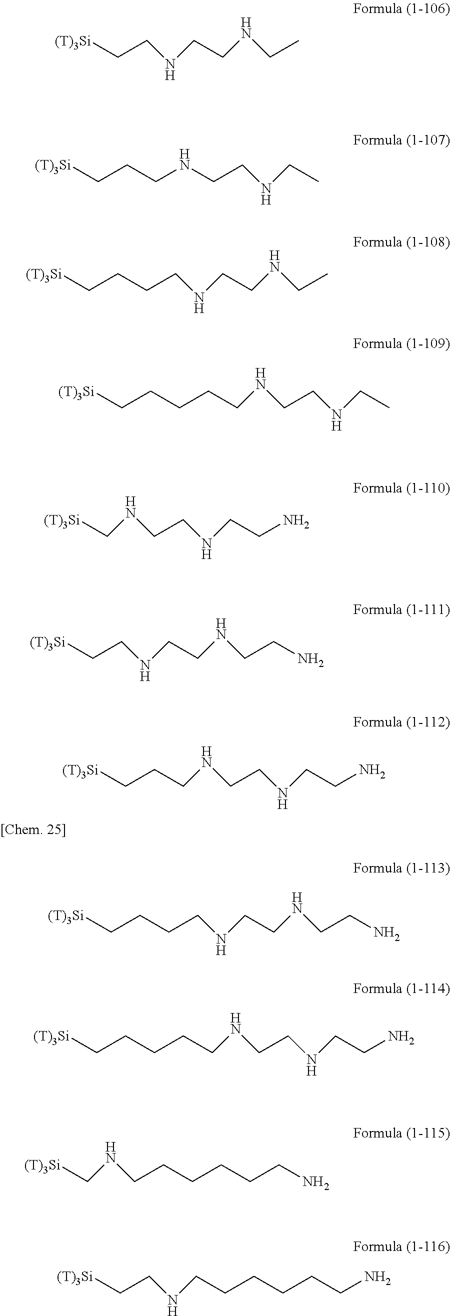

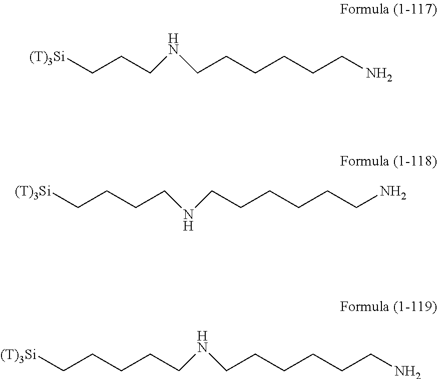

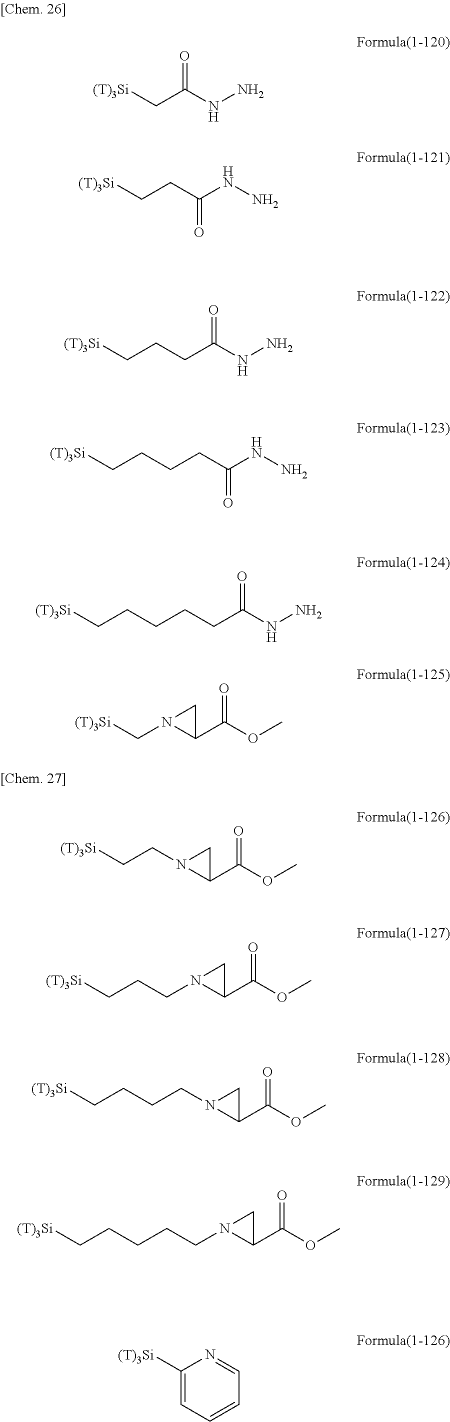

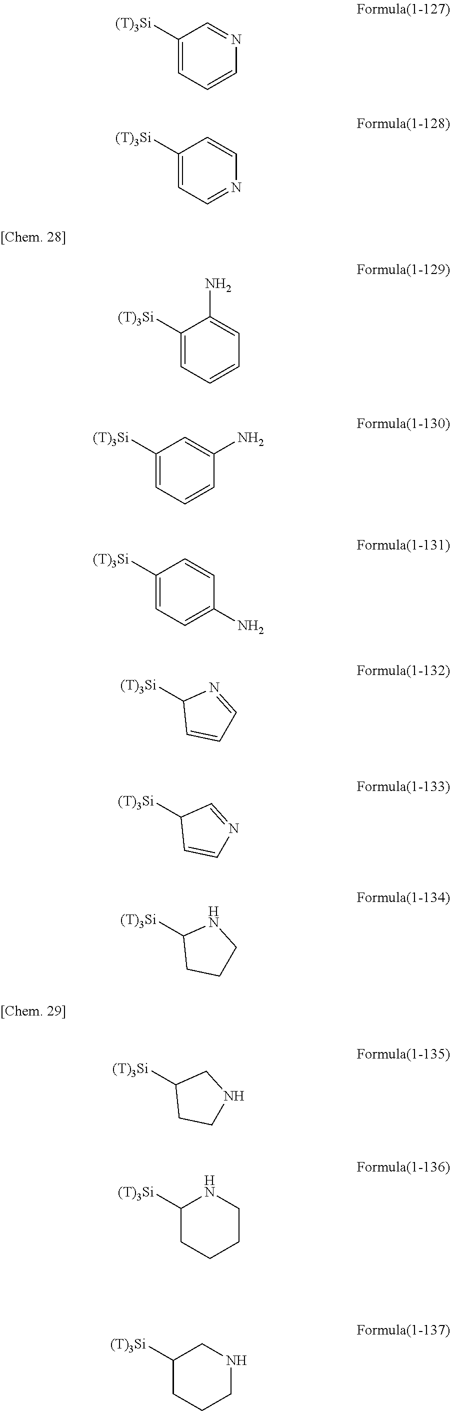

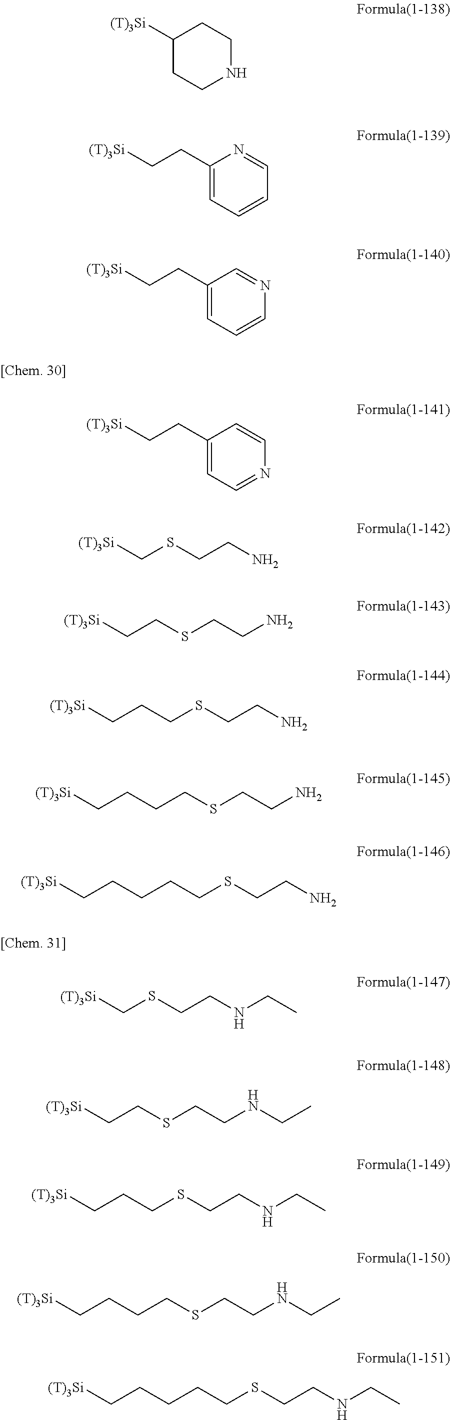

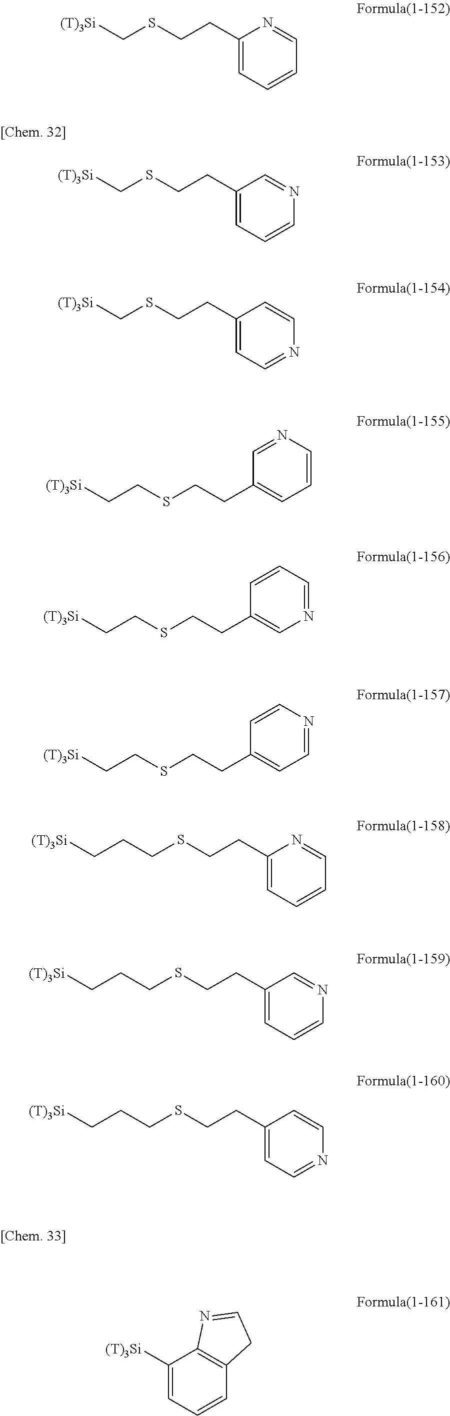

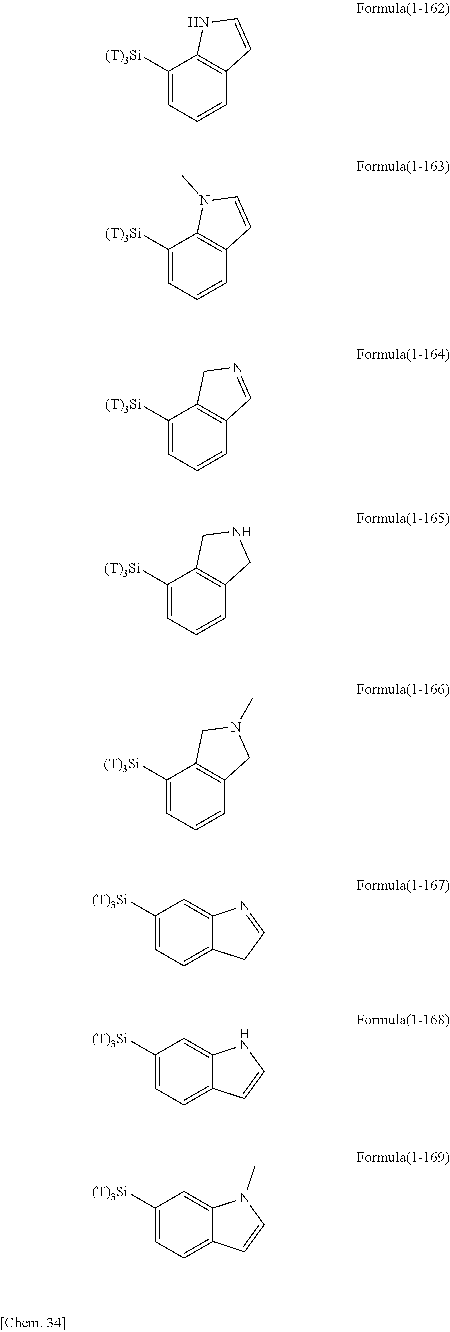

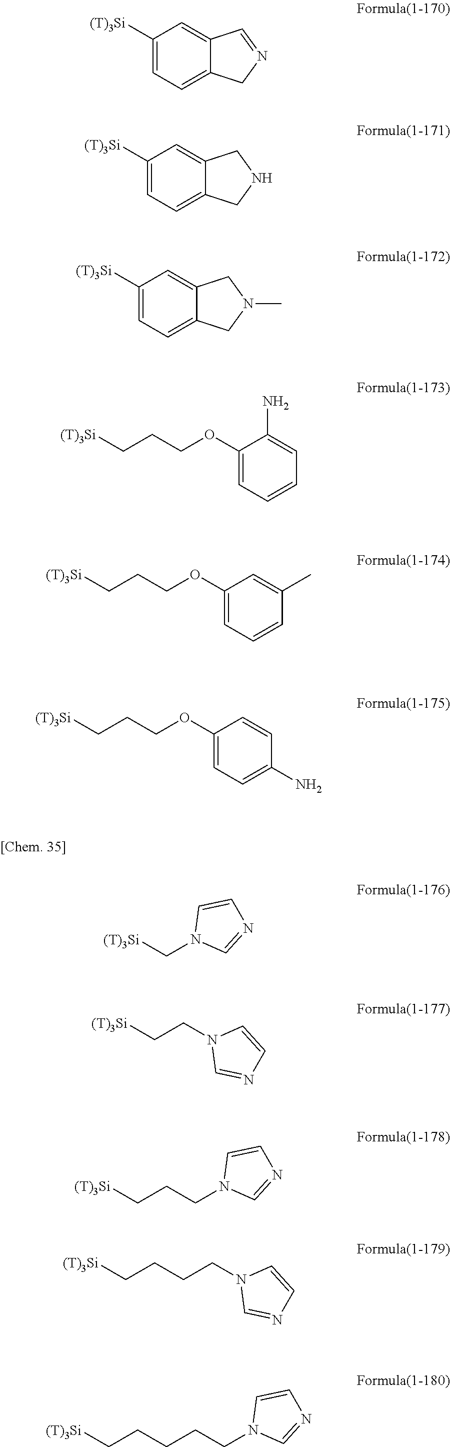

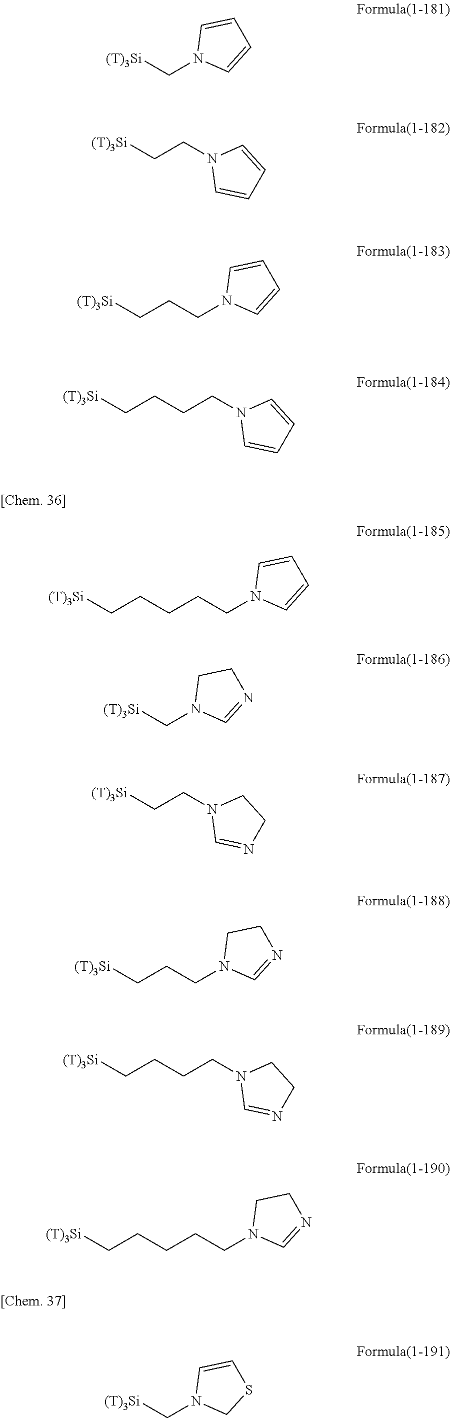

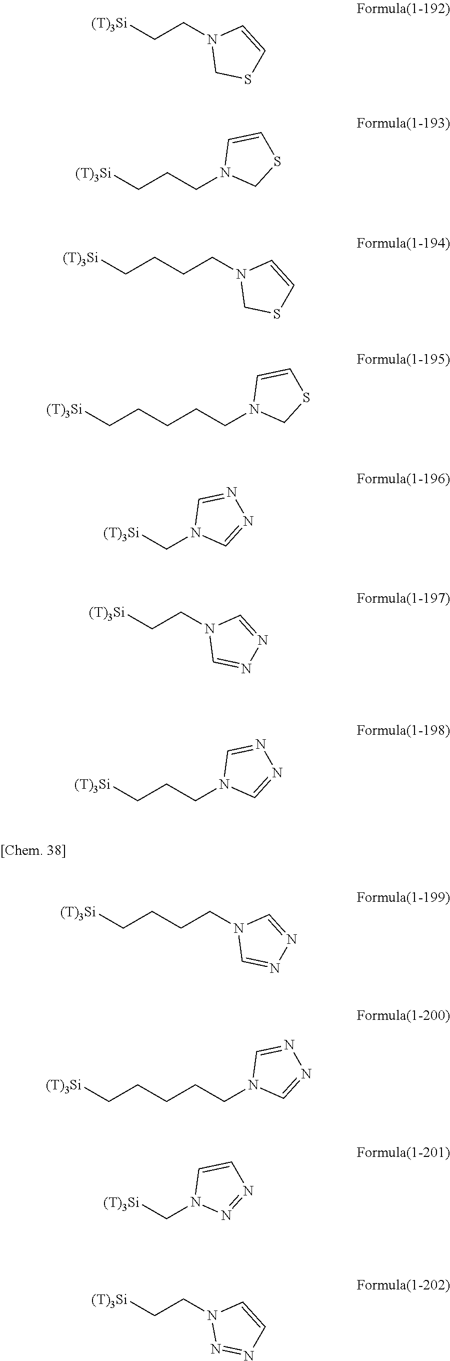

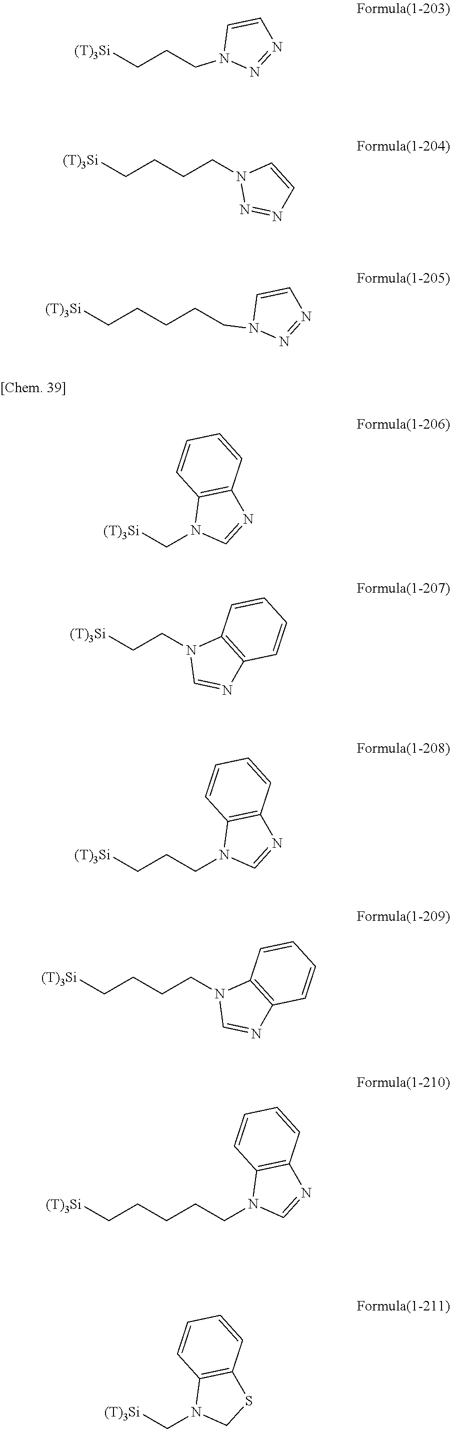

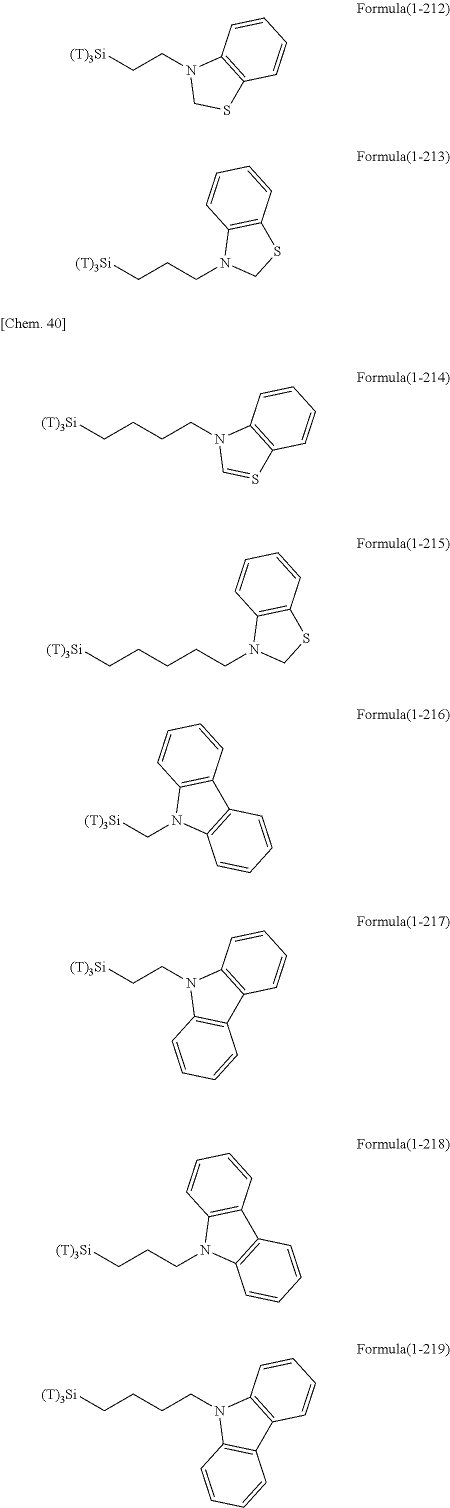

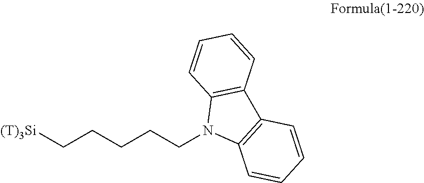

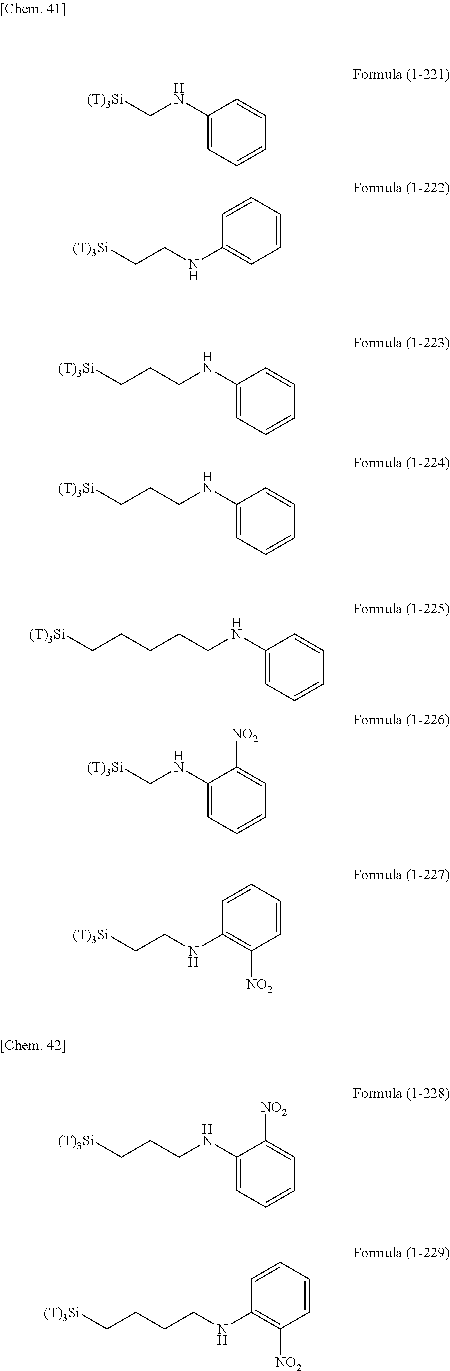

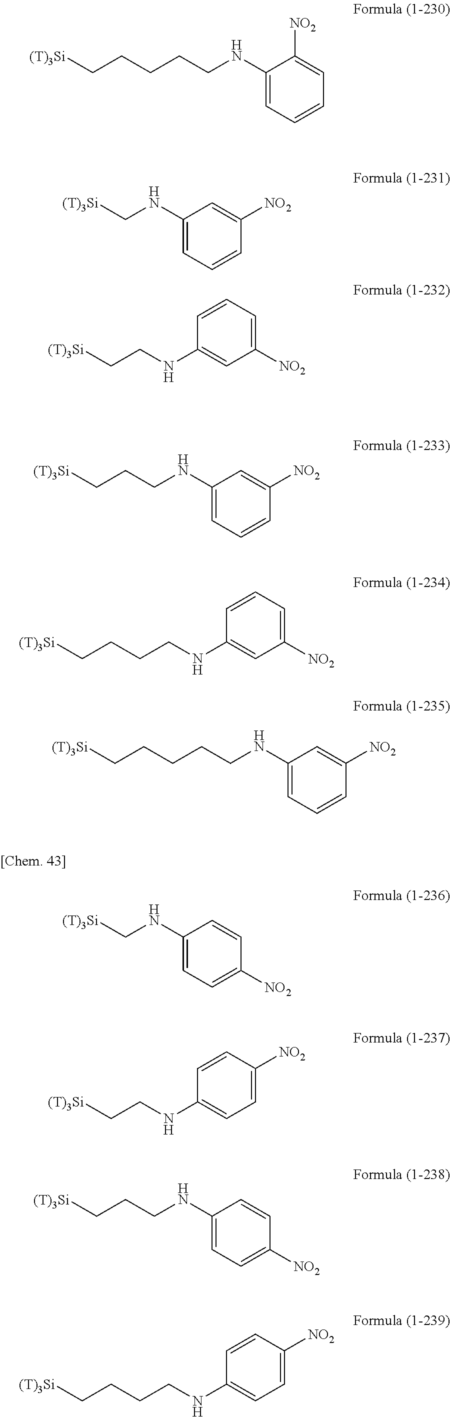

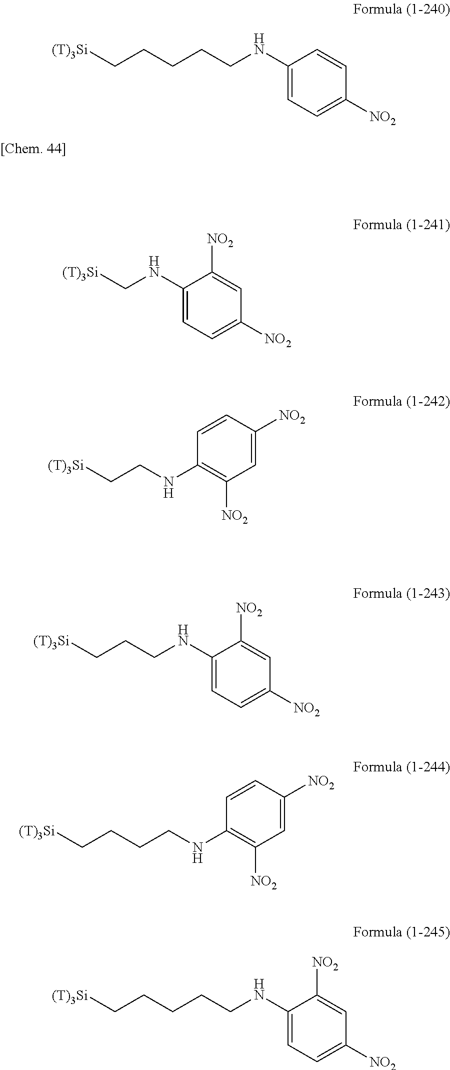

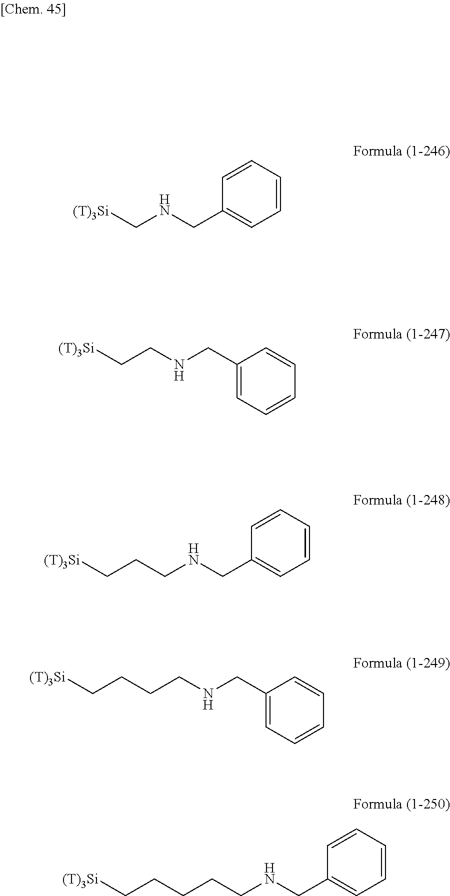

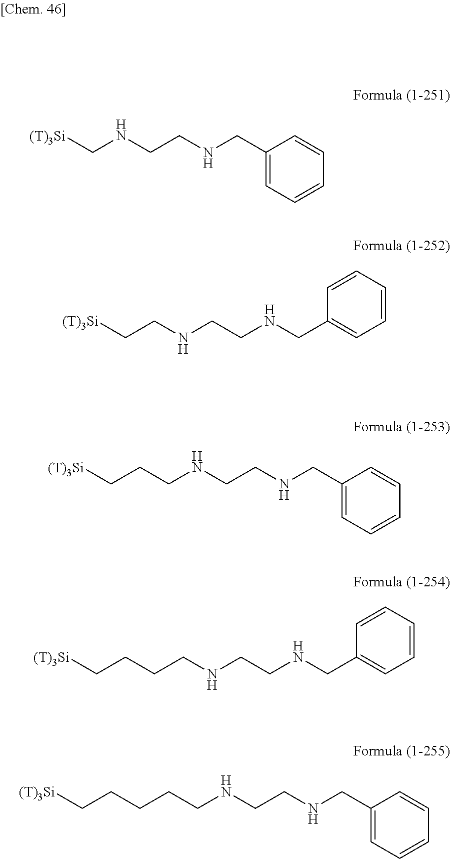

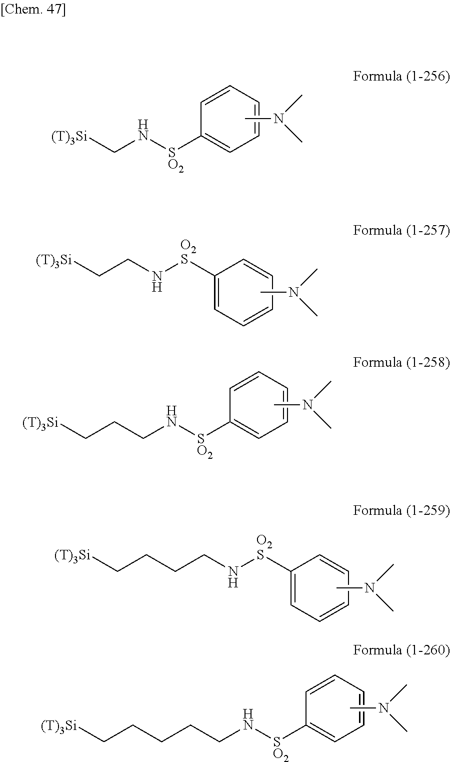

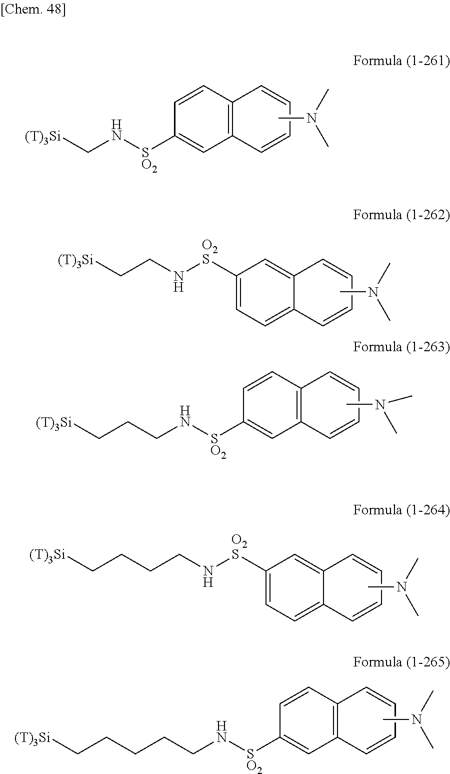

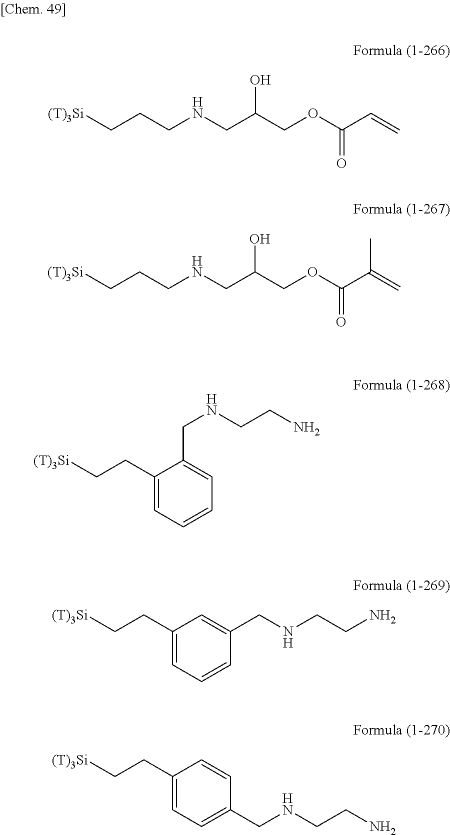

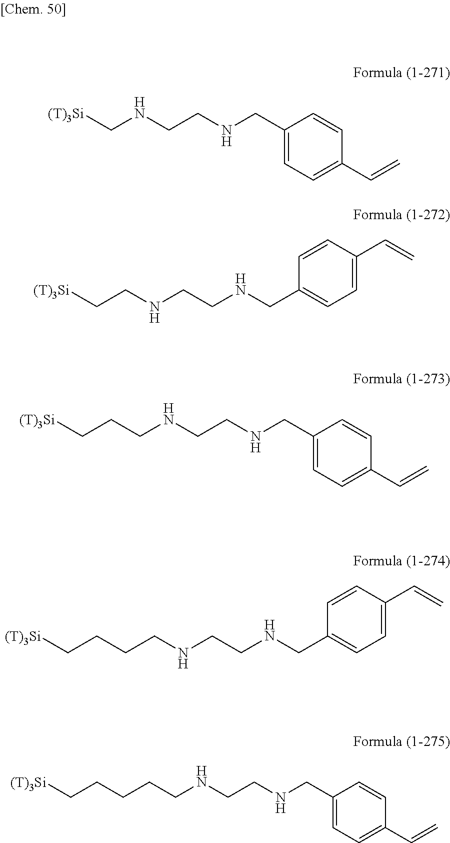

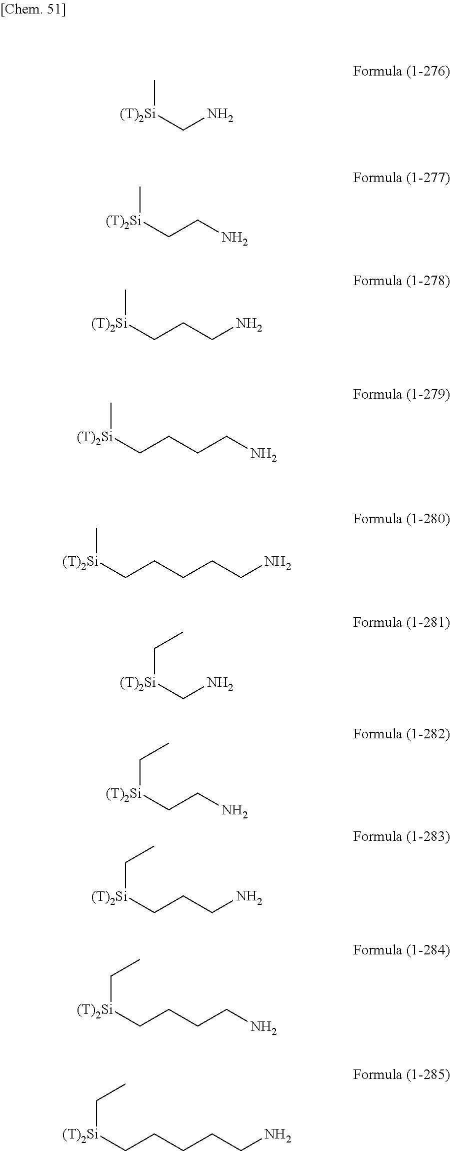

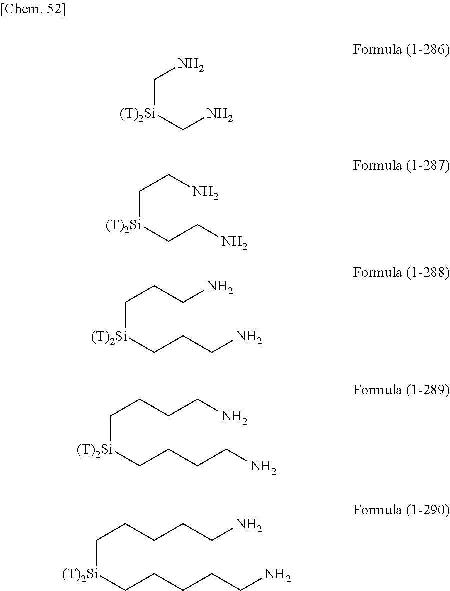

In Formulae (1-1) to (1-290), Ts each independently represent an alkoxy group, an acyloxy group, or a halogen group, and represents preferably a methoxy group or an ethoxy group, for example.

The polysiloxane [A] may be, for example, a hydrolysis condensate of a hydrolyzable silane containing the hydrolyzable silane represented by the following Formula (2) together with the hydrolyzable silane represented by Formula (1) or in place of the hydrolyzable silane represented by Formula (1).

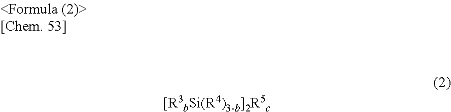

In Formula (2), R³ is a group bonded to a silicon atom, and represents an optionally substituted alkyl group, an optionally substituted aryl group, an optionally substituted aralkyl group, an optionally substituted alkyl halide group, an optionally substituted aryl halide group, an optionally substituted aralkyl halide group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more of these groups.

R⁴ is a group or atom bonded to a silicon atom, and each independently represents an alkoxy group, an aralkyloxy group, an acyloxy group, or a halogen atom.

R⁵ is a group bonded to a silicon atom, and each independently represents an alkylene group or an arylene group.

b represents 0 or 1, and c represents 0 or 1.

Specific examples of the groups of R³ and preferred number of carbon atoms thereof are the same as the groups and the number of carbon atoms thereof described above regarding R¹.

Specific examples of the groups and atoms of R⁴ and preferred number of carbon atoms thereof are the same as the groups and the number of carbon atoms thereof described above regarding R².

Specific examples of the alkylene group in R⁵ include, but are not limited to, alkylene groups, for example, linear alkylene groups such as a methylene group, an ethylene group, a trimethylene group, a tetramethylene group, a pentamethylene group, a hexamethylene group, a heptamethylene group, an octamethylene group, a nonamethylene group, a decamethylene group; branched alkylene groups, such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, a 1-ethyltrimethylene group; and alkanetriyl groups, such as a methanetriyl group, an ethane-1,1,2-triyl group, an ethane-1,2,2-triyl group, an ethane-2,2,2-triyl group, a propane-1,1,1-triyl group; a propane-1,1,2-triyl group, a propane-1,2,3-triyl group, a propane-1,2,2-triyl group, a propane-1,1,3-triyl group, a butane-1,1,1-triyl group, a butane-1,1,2-triyl group, a butane-1,1,3-triyl group, a butane-1,2,3-triyl group, a butane-1,2,4-triyl group, a butane-1,2,2-triyl group, a butane-2,2,3-triyl group, a 2-methylpropane-1,1,1-triyl group, a 2-methylpropane-1,1,2-triyl group, and a 2-methylpropane-1,1,3-triyl group.

Specific examples of the arylene group in R⁵ include, but are not limited to, a 1,2-phenylene group, a 1,3-phenylene group, a 1,4-phenylene group; groups derived from a condensed-ring aromatic hydrocarbon compound through removal of two hydrogen atoms on the aromatic ring, such as a 1,5-naphthalenediyl group, a 1,8-naphthalenediyl group, a 2,6-naphthalenediyl group, a 2,7-naphthalenediyl group, a 1,2-anthracenediyl group, a 1,3-anthracenediyl group, a 1,4-anthracenediyl group, a 1,5-anthracenediyl group, a 1,6-anthracenediyl group, a 1,7-anthracenediyl group, a 1,8-anthracenediyl group, a 2,3-anthracenediyl group, a 2,6-anthracenediyl group, a 2,7-anthracenediyl group, a 2,9-anthracenediyl group, a 2,10-anthracenediyl group, and a 9,10-anthracenediyl group; and groups derived from a linked-ring aromatic hydrocarbon compound through removal of two hydrogen atoms on the aromatic ring, such as a 4,4′-biphenyldiyl group and a 4,4″-p-terphenyldiyl group.
b is preferably 0.
c is preferably 1.

Specific examples of the hydrolyzable silane represented by Formula (2) include, but are not limited to, methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxysilane, bistrimethoxydisilane, bistriethoxydisilane, bisethyldiethoxydisilane, and bismethyldimethoxydisilane.

Further, the polysiloxane [A] may be, for example, a hydrolysis condensate of a hydrolyzable silane containing the hydrolyzable silane represented by Formula (1) and/or the hydrolyzable silane represented by Formula (2), and an additional hydrolyzable silane described below.

Examples of other hydrolyzable silanes include, but are not limited to, silane compounds having an onium group in the molecule, silane compounds having a sulfone group, silane compounds having a sulfonamide group, and silane compounds having a cyclic urea skeleton in the molecule.

### <<Silane Compound Having Onium Group in Molecule (Hydrolyzable Organosilane)>

A silane compound having an onium group in the molecule is expected to effectively and efficiently promote the crosslinking reaction of a hydrolyzable silane.

One preferred example of the silane compound having an onium group in the molecule is shown in Formula (3).

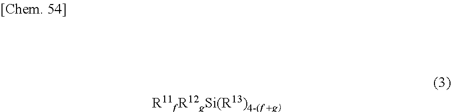

R¹¹ is a group bonded to a silicon atom, and represents an onium group or an organic group having the onium group.

R¹² is a group bonded to a silicon atom, and each independently represents an optionally substituted alkyl group, an optionally substituted aryl group, an optionally substituted aralkyl group, an optionally substituted alkyl halide group, an optionally substituted aryl halide group, an optionally substituted aralkyl halide group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, or an organic group having a cyano group, or a combination of two or more of these groups.

R¹³ is a group or atom bonded to a silicon atom, and each independently represents an alkoxy group, an aralkyloxy group, an acyloxy group, or a halogen atom.

f represents 1 or 2, g represents 0 or 1, and 1≤f+g≤2 is satisfied.

Specific examples of the alkyl group, the aryl group, the aralkyl group, the alkyl halide group, the aryl halide group, the aralkyl halide group, the alkoxyalkyl group, the alkoxyaryl group, the alkoxyaralkyl group, the alkenyl group, and the organic group having an epoxy group, the organic group having an acryloyl group, the organic group having a methacryloyl group, the organic group having a mercapto group, the organic group having an amino group and the organic group having a cyano group, the alkoxy group, the aralkyloxy group, the acyloxy group, and the halogen atom, specific examples of substituents of the alkyl group, the aryl group, the aralkyl group, the alkyl halide, the aryl halide group, the aralkyl halide group, the alkoxyaryl group, the alkoxyaralkyl group, and the alkenyl group, and the preferred number of carbon atoms thereof include, for R¹², those described above with regard to R¹, and for R¹³, those described above with regard to R².

More specifically, the onium group is, for example, a cyclic ammonium group or a chain ammonium group, and is preferably a tertiary ammonium group or a quaternary ammonium group.

That is, preferred specific examples of the onium group or the organic group having the onium group include a cyclic ammonium group, a chain ammonium group, or an organic group containing at least one of the cyclic ammonium group or the chain ammonium group. Preferred is a tertiary ammonium group or a quaternary ammonium group or an organic group containing at least one of the tertiary ammonium group or the quaternary ammonium group.

When the onium group is a cyclic ammonium group, a nitrogen atom forming the ammonium group also serves as an atom constituting the ring. In this case, the nitrogen atom forming the ring and the silicon atom are bonded directly or via a divalent linking group, or the carbon atom forming the ring and the silicon atom are bonded directly or via a divalent linking group.

In one preferred aspect, R¹¹, i.e. the group bonding to the silicon atom, is a heteroaromatic cyclic ammonium group represented by the following Formula (S1).

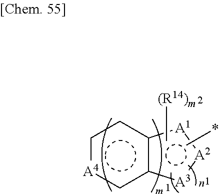

where in Formula (S1), A¹, A², A³, and A⁴ each independently represent a group represented by any one of the following Formulae (J1) to (J3), and at least one of A¹ to A⁴ is a group represented by the following Formula (J2). The bond between each of A¹ to A⁴ and the atom adjacent thereto and constituting the ring is determined to be a single bond or a double bond according to which of A¹ to A⁴ the silicon atom in Formula (3) is bonded, such that the constituted ring exhibits aromaticity. An asterisk * represents a bonding hand.

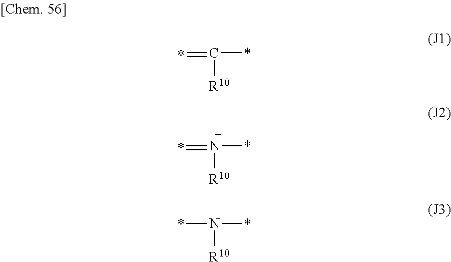

where in Formulae (J1) to (J3), each R¹⁰ independently represents a single bond, a hydrogen atom, an alkyl group, an aryl group, an aralkyl group, an alkyl halide group, an aryl halide group, an aralkyl halide group or an alkenyl group. Specific examples of the alkyl group, the aryl group, the aralkyl group, the alkyl halide group, the aryl halide group, the aralkyl halide group, and the alkenyl group, and the preferred number of carbon atoms thereof are the same as those described above. Each asterisk * represents a bonding hand.

In Formula (S1), each R¹⁴ independently represents an alkyl group, an aryl group, an aralkyl group, an alkyl halide group, an aryl halide group, an aralkyl halide group, an alkenyl group or a hydroxy group. When two or more R¹⁴s are present, the two R¹⁴s may be bonded to each other to form a ring. A ring formed by two R¹⁴s may have a crosslinked ring structure, and in such a case, the cyclic ammonium group has an adamantane ring, a norbornene ring, a spiro ring or the like.

Specific examples of such an alkyl group, an aryl group, an aralkyl group, an alkyl halide group, an aryl halide group, an aralkyl halide group, and an alkenyl group, and the preferred number of carbon atoms thereof are the same as those described above.

In Formula (S1), n¹ is an integer of 1 to 8, m¹ is 0 or 1, and m² is 0 or a positive integer ranging from 1 to the possible maximum number being substituted on a monocyclic or polycyclic ring.

When m¹ is 0, a (4+n¹)-membered ring including A¹ to A⁴ is formed. That is, when n¹ is 1, a 5-membered ring is formed; when n¹ is 2, a 6-membered ring is formed; when n¹ is 3, a 7-membered ring is formed; when n¹ is 4, an 8-membered ring is formed; when n¹ is 5, a 9-membered ring is formed; when n¹ is 6, a 10-membered ring is formed; when n¹ is 7, a 11-membered ring is formed; and when n¹ is 8, a 12-membered ring is formed.

When m¹ is 1, a condensed ring is formed by condensation between a (4+n¹)-membered ring including A¹ to A³ and a 6-membered ring including A⁴.

Since each of A¹ to A⁴ is any of the groups of Formulae (J1) to (J3), the ring-forming atom has or does not have a hydrogen atom. In each of A¹ to A⁴, when the ring-forming atom has a hydrogen atom, the hydrogen atom may be substituted with R¹⁴. Alternatively, a ring-forming atom other than the ring-forming atom in each of A¹ to A⁴ may be substituted with R¹⁴. Because of such circumstances, as described above, m² is selected from 0 or an integer ranging from 1 to the possible maximum number being substituted on a monocyclic or polycyclic ring.

The bonding hand of the heteroaromatic cyclic ammonium group represented by Formula (S1) is present on any carbon atom or nitrogen atom present in such a monocyclic ring or condensed ring, and is directly bonded to a silicon atom. Alternatively, the bonding hand is bonded to a linking group to form an organic group containing the cyclic ammonium group, and the organic group is bonded to a silicon atom.

Examples of the linking group include, but are not limited thereto, an alkylene group, an arylene group, and an alkenylene group.

Specific examples of the alkylene group and the arylene group and preferred number of carbon atoms are the same as those described above.

The alkenylene group is a divalent group derived by further removing one hydrogen atom from the alkenyl group, and specific examples of the alkenyl group are the same as those described above. The number of carbon atoms in the alkenylene group is not particularly limited, but is preferably 40 or less, more preferably 30 or less, and still more preferably 20 or less.

Specific examples thereof include, but are not limited thereto, vinylene, 1-methylvinylene, propenylene, 1-butenylene, 2-butenylene, 1-pentenylene, and 2-pentenylene group.

Specific examples of the silane compound (hydrolyzable organosilane) represented by Formula (3) having the heteroaromatic cyclic ammonium group represented by Formula (S1) include, but are not limited to, silanes represented by the following Formulae (I-1) to (I-50).

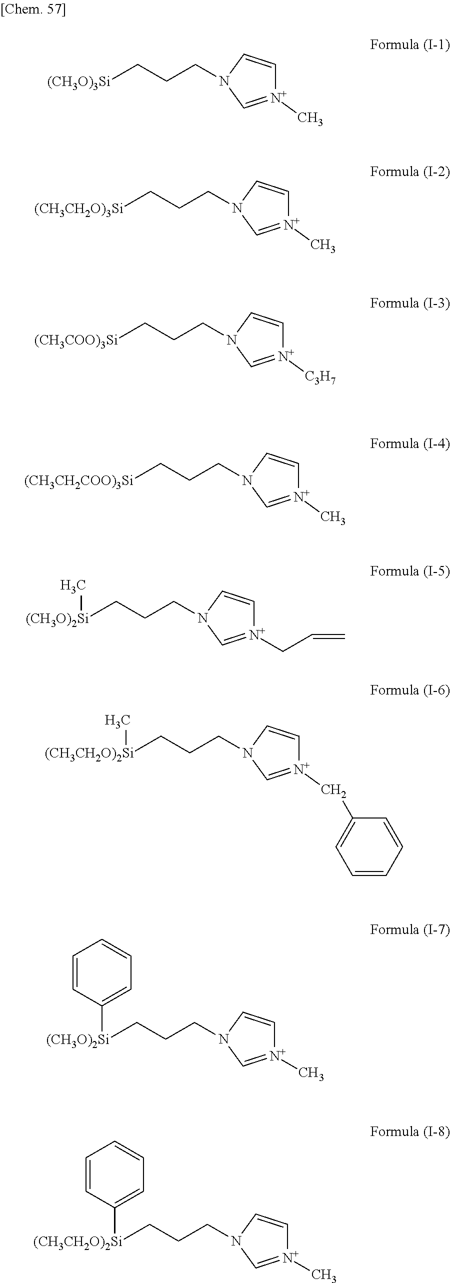

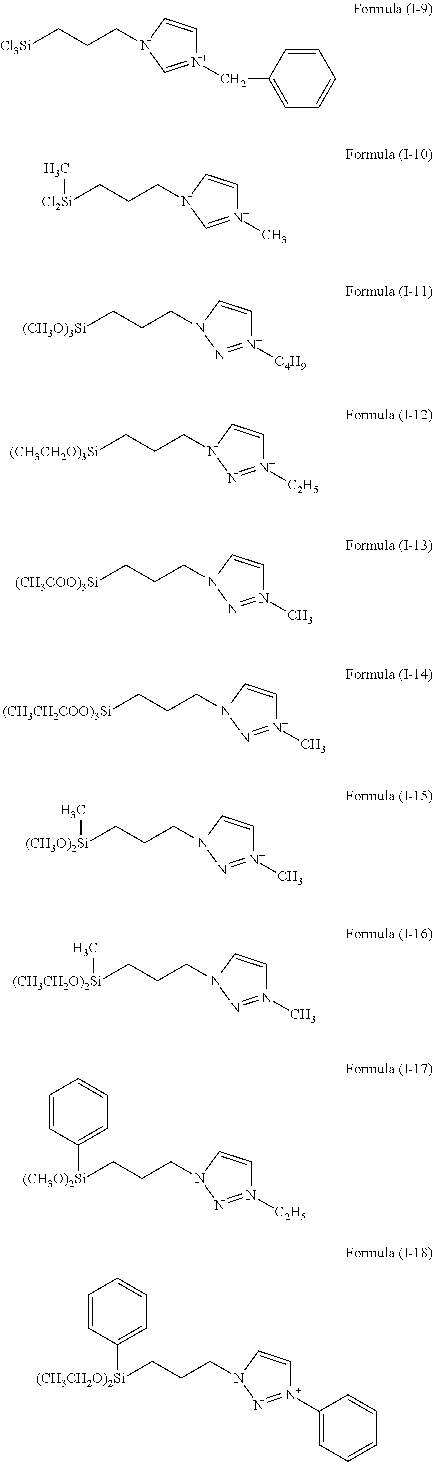

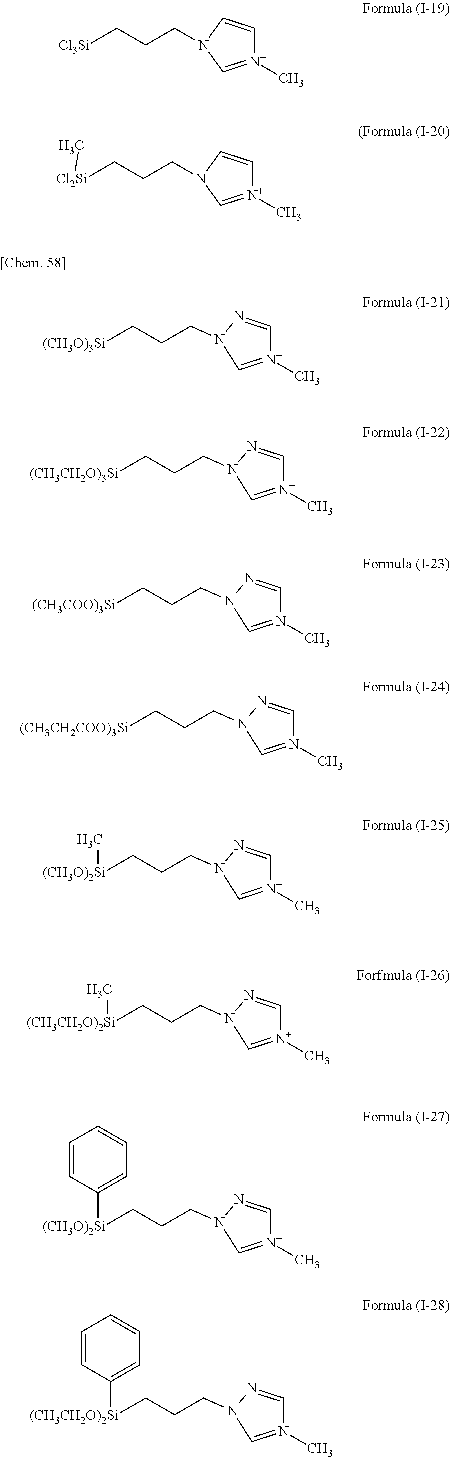

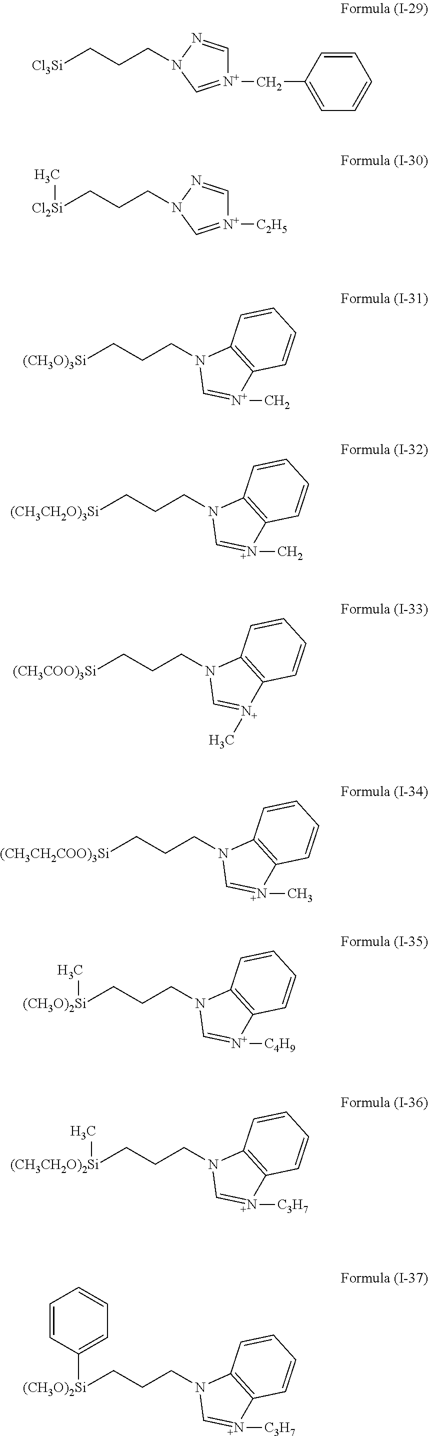

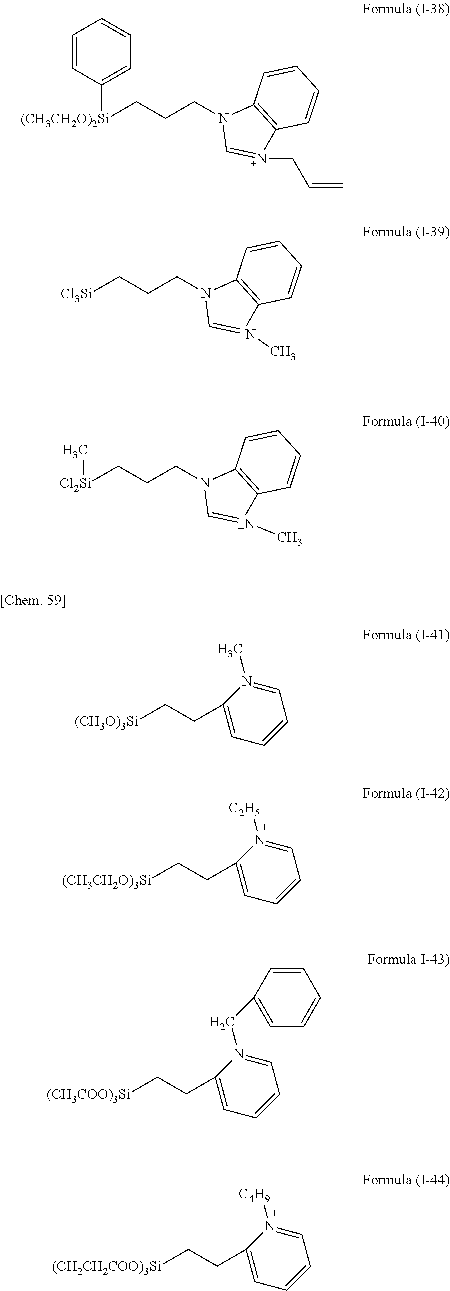

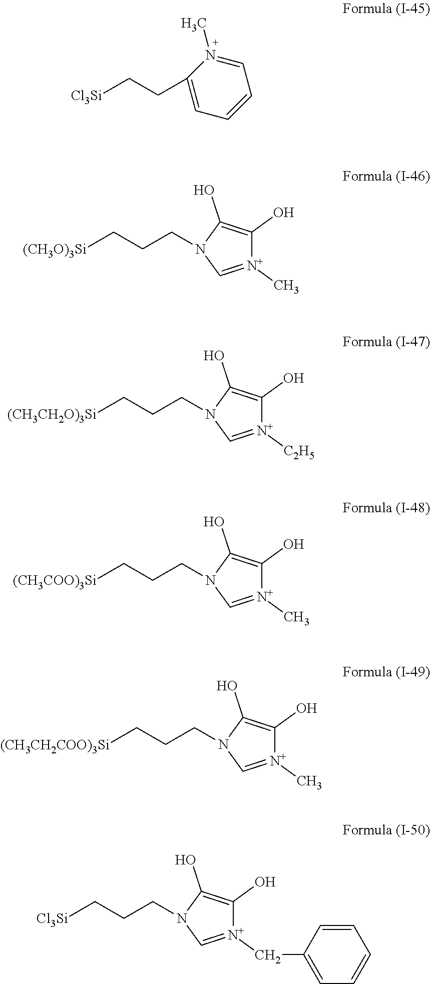

In another example, R¹¹, i.e. the group bonding to the silicon atom in Formula (3), may be a heteroaliphatic cyclic ammonium group represented by the following Formula (S2).

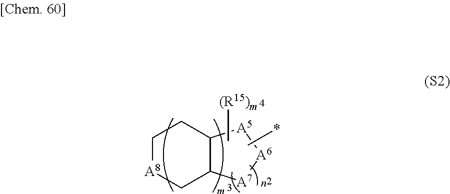

where in Formula (S2), A⁵, A⁶, A⁷, and A⁸ each independently represent a group represented by any one of the following Formulae (J4) to (J6), and at least one of A⁵ to A⁸ represents a group represented by the following Formula (J5). Depending on to which atom of A⁵ to A⁸ a silicon atom in Formula (3) is bonded, it is determined whether a bond between any one of A⁵ to A⁸ and a ring-forming atom adjacent to the any one is a single bond or a double bond so that the ring to be formed exhibits non-aromaticity. An asterisk * represents a bonding hand.

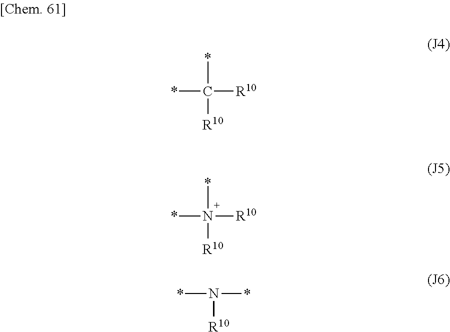

where in Formulae (J4) to (J6), each R¹⁰ independently represents a single bond, a hydrogen atom, an alkyl group, an aryl group, an aralkyl group, an alkyl halide group, an aryl halide group, an aralkyl halide group or an alkenyl group. Specific examples of the alkyl group, the aryl group, the aralkyl group, the alkyl halide group, the aryl halide group, the aralkyl halide group, and the alkenyl group, and the preferred number of carbon atoms thereof are the same as those described above. Each asterisk * represents a bonding hand.

In Formula (S2), each R¹⁵ independently represents an alkyl group, an aryl group, an aralkyl group, an alkyl halide group, an aryl halide group, an aralkyl halide group, an alkenyl group or a hydroxy group. When two or more R¹⁵s are present, the two R¹⁵s may be bonded to each other to form a ring. A ring formed by two R¹⁵s may have a crosslinked ring structure, and in such a case, the cyclic ammonium group has an adamantane ring, a norbornene ring, a spiro ring or the like.

Specific examples of the alkyl group, the aryl group, the aralkyl group, the alkyl halide group, the aryl halide group, the aralkyl halide group, and the alkenyl group, and the preferred number of carbon atoms thereof are the same as those described above.

In Formula (S2), n² is an integer of 1 to 8, m³ is 0 or 1, and m⁴ is 0 or a positive integer ranging from 1 to the possible maximum number being substituted on a monocyclic or polycyclic ring.

When m³ is 0, a (4+n²)-membered ring including A⁵ to A⁸ is formed. That is, when n² is 1, a 5-membered ring is formed; when n² is 2, a 6-membered ring is formed; when n² is 3, a 7-membered ring is formed; when n² is 4, an 8-membered ring is formed; when n² is 5, a 9-membered ring is formed; when n² is 6, a 10-membered ring is formed; when n² is 7, a 11-membered ring is formed; and when n² is 8, a 12-membered ring is formed.

When m³ is 1, a condensed ring is formed by condensation between a (4+n²)-membered ring including A⁵ to A⁷ and a 6-membered ring including A⁸.

Since each of A⁵ to A⁸ is any of the groups of Formulae (J4) to (J6), the ring-forming atom has or does not have a hydrogen atom. In each of A⁵ to A⁸, when the ring-forming atom has a hydrogen atom, the hydrogen atom may be substituted with R¹⁵. Alternatively, a ring-forming atom other than the ring-forming atom in each of A⁵ to A⁸ may be substituted with R¹⁵.

Because of such circumstances, as described above, m⁴ is selected from 0 or an integer ranging from 1 to the possible maximum number being substituted on a monocyclic or polycyclic ring.

The bonding hand of the heteroaliphatic cyclic ammonium group represented by Formula (S2) is present on any carbon atom or nitrogen atom present in such a monocyclic ring or condensed ring, and is directly bonded to a silicon atom. Alternatively, the bonding hand is bonded to a linking group to form an organic group containing the cyclic ammonium group, and the organic group is bonded to a silicon atom.

The linking group is, for example, an alkylene group, an arylene group, or an alkenylene group. Specific examples of the alkylene group, the arylene group, and the alkenylene group and the preferred number of carbon atoms are the same as those described above.

Specific examples of the silane compound (hydrolyzable organosilane) represented by Formula (3) having the heteroaliphatic cyclic ammonium group represented by Formula (S2) include, but are not limited to, silanes represented by the following Formulae (II-1) to (II-30).

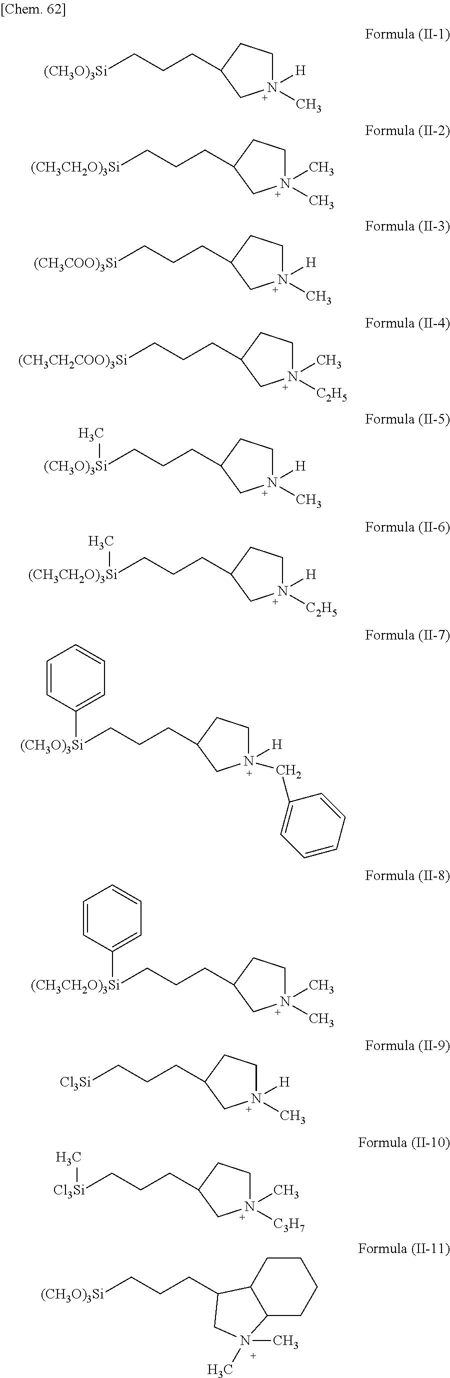

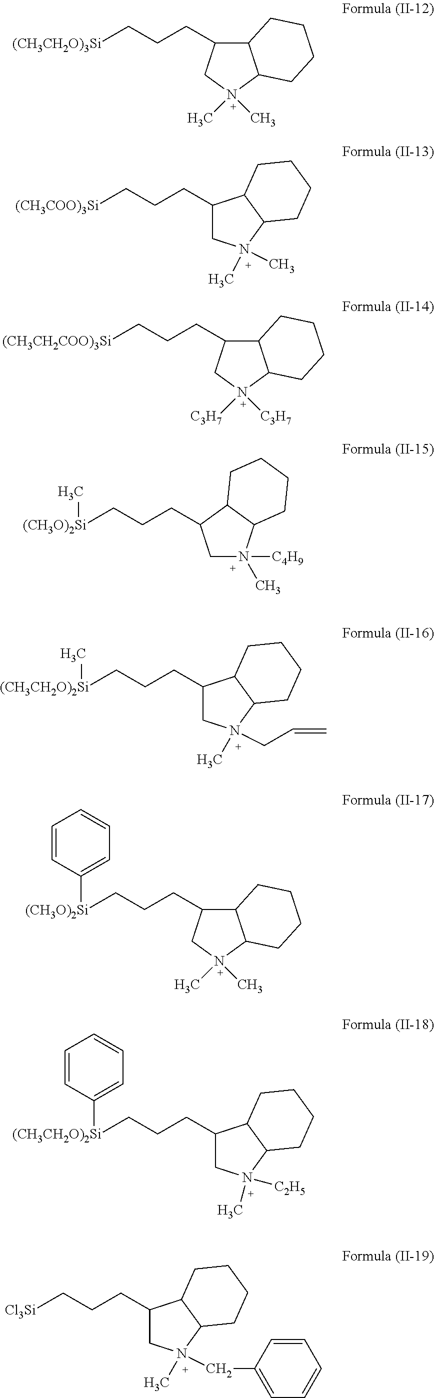

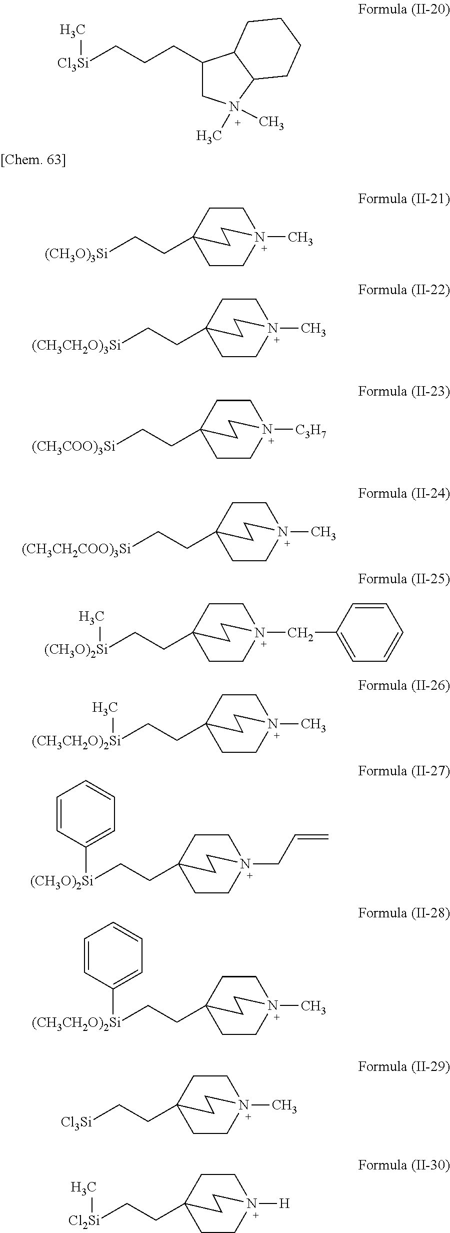

In another example, R¹¹, i.e. the group bonding to the silicon atom in Formula (3), may be a chain ammonium group represented by the following Formula (S3).

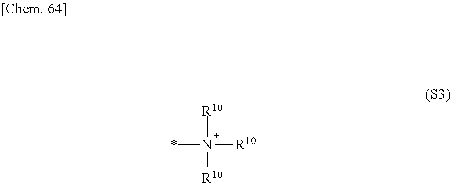

where in Formula (S3), each R¹⁰ independently represents a hydrogen atom, an alkyl group, an aryl group, an aralkyl group, an alkyl halide group, an aryl halide group, an aralkyl halide group or an alkenyl group. Specific examples of the alkyl group, the aryl group, the aralkyl group, the alkyl halide group, the aryl halide group, the aralkyl halide group, and the alkenyl group, and the preferred number of carbon atoms thereof are the same as those described above. An asterisk * represents a bonding hand.

The chain ammonium group represented by Formula (S3) is directly bonded to a silicon atom. Alternatively, the chain ammonium group is bonded to a linking group to form an organic group containing the chain ammonium group, and the organic group is bonded to a silicon atom.

The linking group is, for example, an alkylene group, an arylene group, or an alkenylene group. Specific examples of the alkylene group, the arylene group, and the alkenylene group are the same as those described above.

Specific examples of the silane compound (hydrolyzable organosilane) represented by Formula (3) having the chain ammonium group represented by Formula (S3) include, but are not limited to, silanes represented by the following Formulae (III-1) to (III-28).

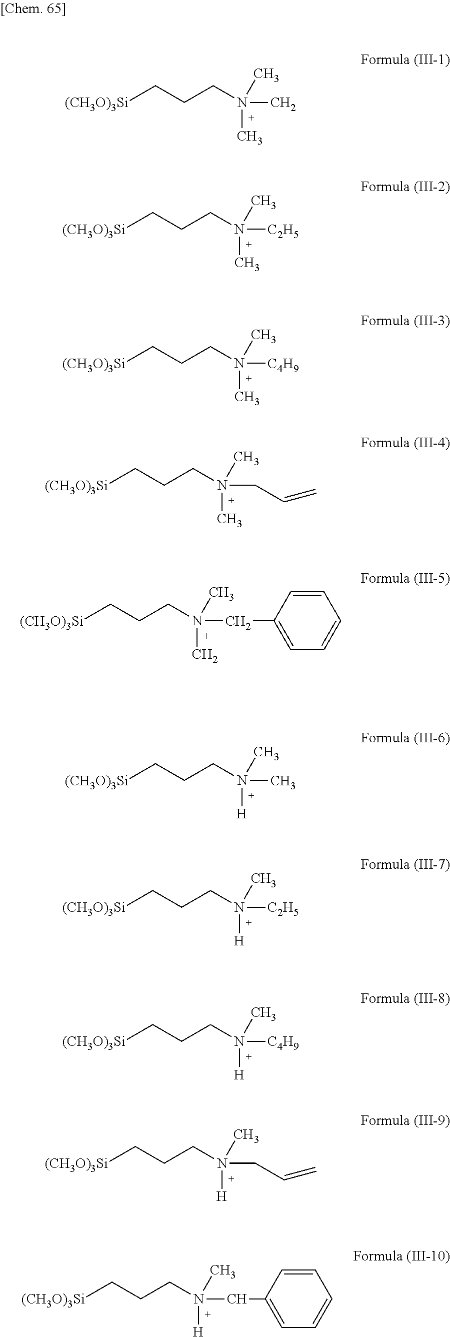

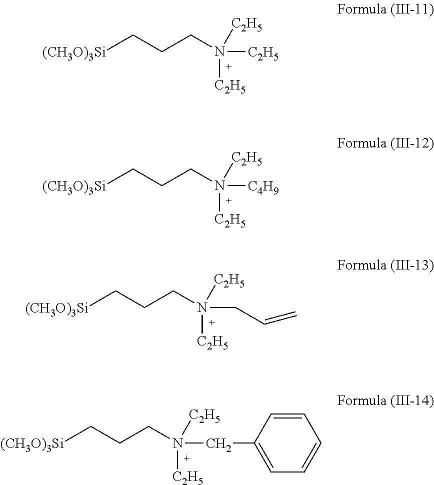

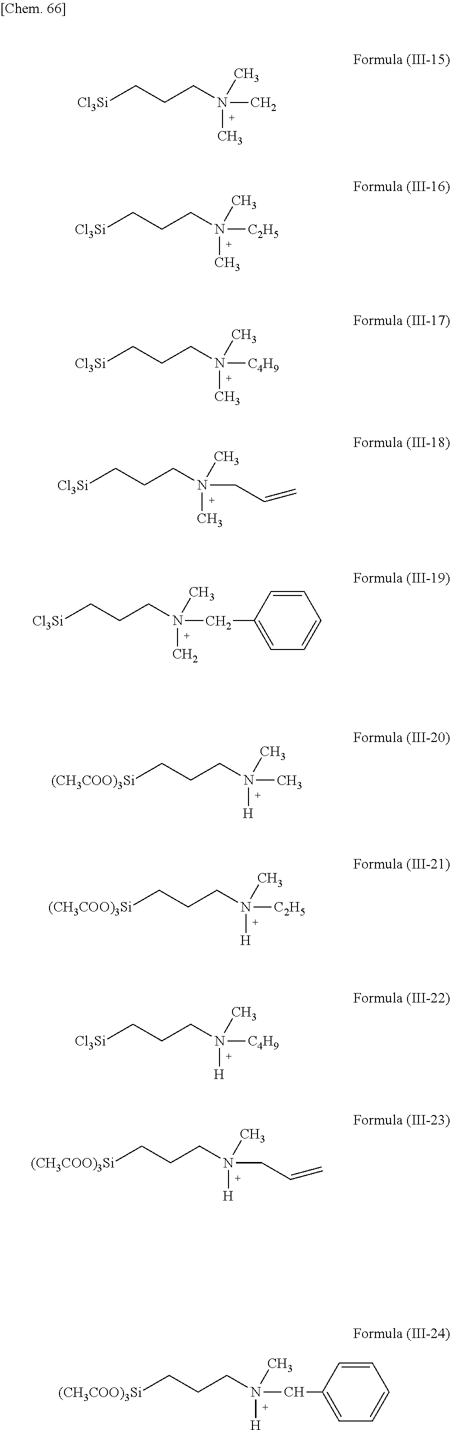

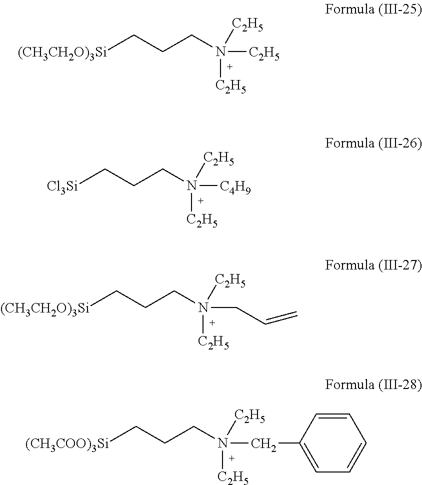

### <<Silane Compounds (Hydrolyzable Organosilanes) Having Sulfone Group or Sulfonamide Group>>

Examples of the silane compounds having a sulfone group and the silane compounds having a sulfonamide group include, but are not limited to, compounds represented by the following Formulae (B-1) to (B-36).

In the following Formulae, Me represents a methyl group, and Et represents an ethyl group.

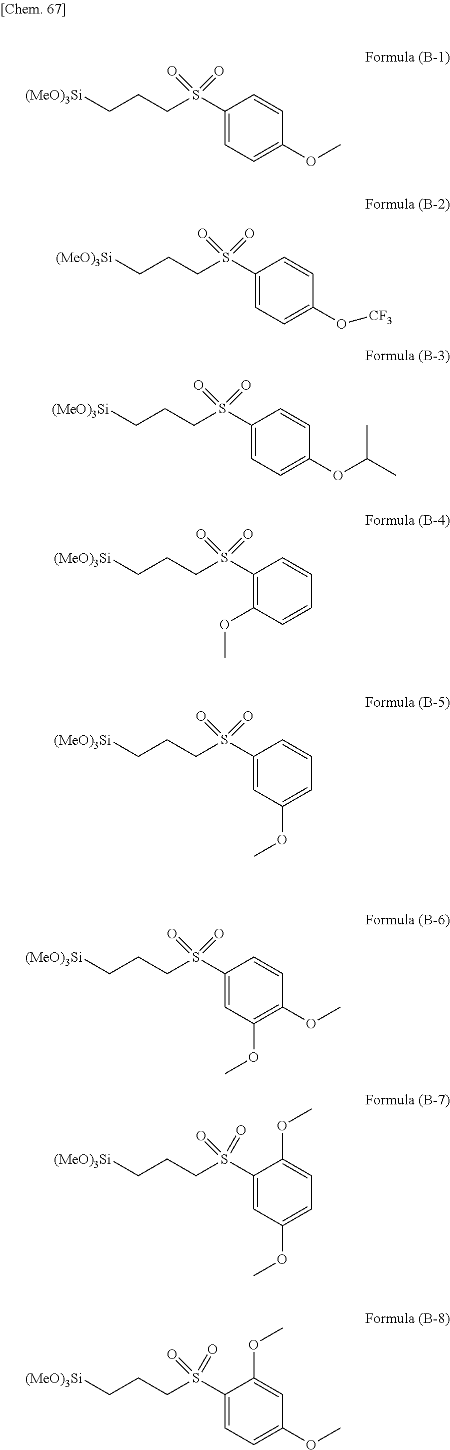

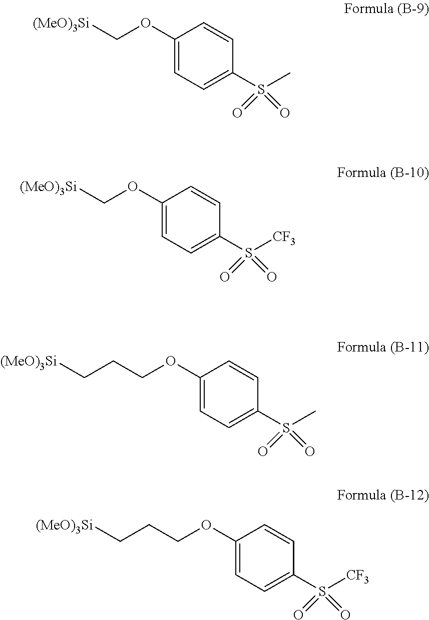

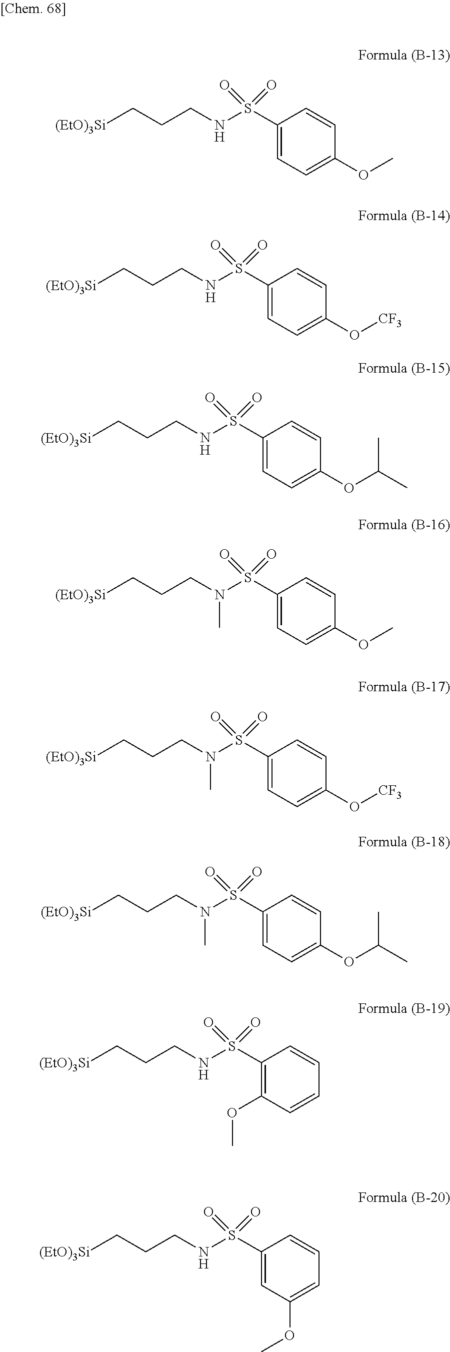

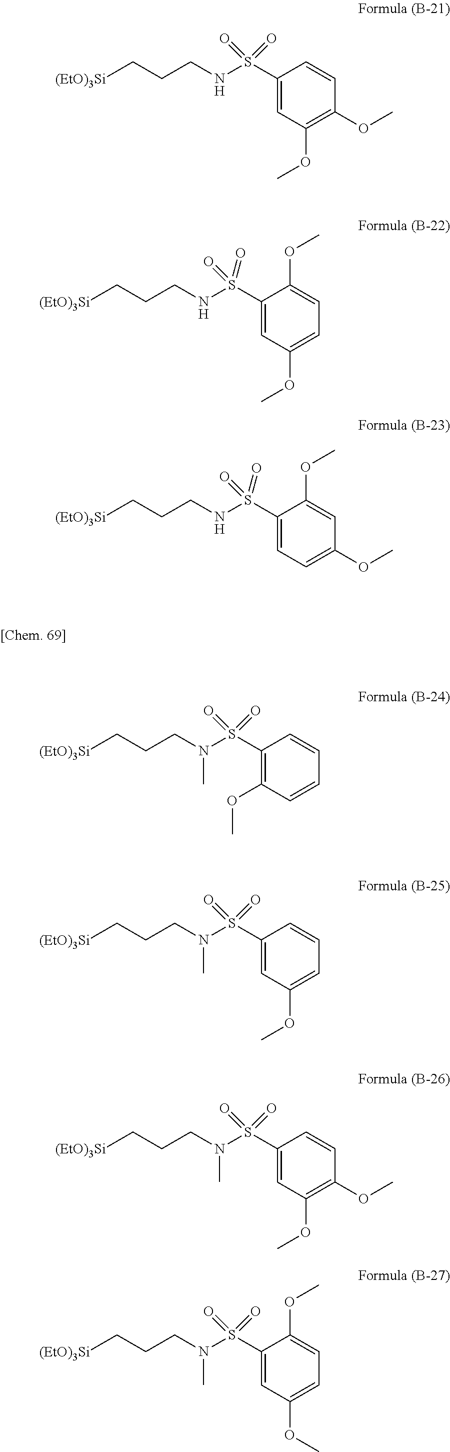

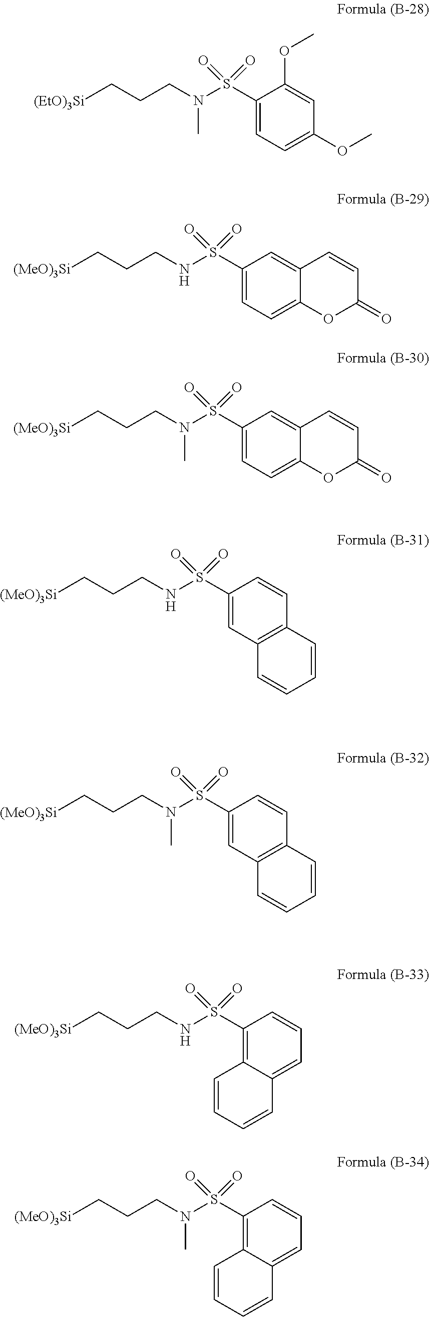

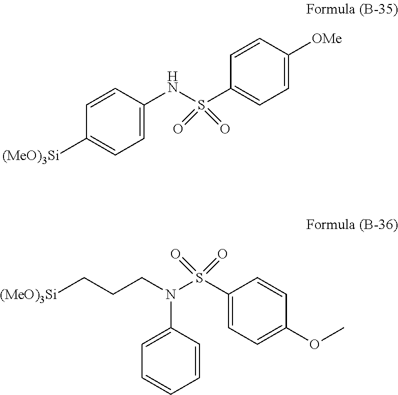

### <<Silane Compounds (Hydrolyzable Organosilanes) Having Cyclic Urea Skeleton in Molecule>>

Examples of the hydrolyzable organosilanes having a cyclic urea skeleton in the molecule include hydrolyzable organosilanes represented by the following Formula (4-1).

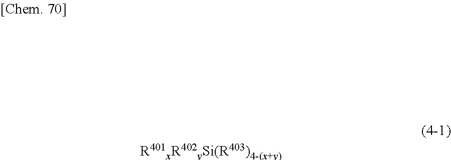

where in Formula (4-1), R⁴⁰¹ is a group bonded to a silicon atom, and each independently represents a group represented by the following Formula (4-2).

R⁴⁰² is a group bonded to a silicon atom, and represents an optionally substituted alkyl group, an optionally substituted aryl group, an optionally substituted aralkyl group, an optionally substituted alkyl halide group, an optionally substituted aryl halide group, an optionally substituted aralkyl halide group, an optionally substituted alkoxyalkyl group, an optionally substituted alkoxyaryl group, an optionally substituted alkoxyaralkyl group, or an optionally substituted alkenyl group, or represents an organic group having an epoxy group, an organic group having an acryloyl group, an organic group having a methacryloyl group, an organic group having a mercapto group, or an organic group having a cyano group, or a combination of two or more of these groups.

R⁴⁰³ is a group or atom bonded to a silicon atom, and each independently represents an alkoxy group, an aralkyloxy group, an acyloxy group, or a halogen atom.
x is 1 or 2, y is 0 or 1, and x+y≤2 is satisfied.

With regard to R⁴⁰², specific examples of the alkyl group, aryl group, aralkyl group, alkyl halide group, aryl halide group, aralkyl halide group, alkoxyalkyl group, alkoxyaryl group, alkoxyaralkyl group, alkenyl group, organic group having an optionally ring-opened epoxy group, organic group having an acryloyl group, organic group having a methacryloyl group, organic group having a mercapto group, and organic group having a cyano group, with regard to R⁴⁰³, specific examples of the alkoxy group, aralkyloxy group, acyloxy group, and halogen atom, substituents thereof, and the preferred number of carbon atoms thereof are the same as described above with regard to R¹ and R².

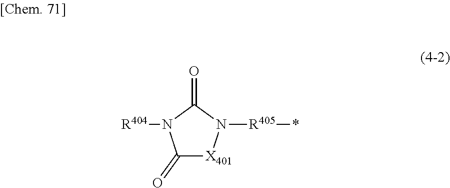

where in Formula (4-2), each R⁴⁰⁴ independently represents a hydrogen atom, an optionally substituted alkyl group, an optionally substituted alkenyl group, or an organic group having an epoxy group or an organic group having a sulfonyl group, and each R⁴⁰⁵ independently represents an alkylene group, a hydroxyalkylene group, a sulfide bond (—S—), an ether bond (—O—), or an ester bond (—CO—O— or —O—CO—). An asterisk * represents a bonding hand.

Note that with regard to R⁴⁰⁴, specific examples of the optionally substituted alkyl group, the optionally substituted alkenyl group, and the organic group having an epoxy group, and the preferred number of carbon atoms are the same as those described above with regard to R¹. In addition, the optionally substituted alkyl group of R⁴⁰⁴ is preferably an alkyl group in which a terminal hydrogen atom is substituted with a vinyl group, and specific examples thereof include an allyl group, a 2-vinylethyl group, a 3-vinylpropyl group, and a 4-vinylbutyl group.

The organic group having a sulfonyl group is not particularly limited as long as it contains a sulfonyl group, and examples thereof include an optionally substituted alkylsulfonyl group, an optionally substituted arylsulfonyl group, an optionally substituted aralkylsulfonyl group, an optionally substituted alkylsulfonyl halide group, an optionally substituted arylsulfonyl halide group, an optionally substituted aralkylsulfonyl halide group, an optionally substituted alkoxyalkylsulfonyl group, an optionally substituted alkoxyarylsulfonyl group, an optionally substituted alkoxyaralkylsulfonyl group, and an optionally substituted alkenylsulfonyl group.

Specific examples of the alkyl group, aryl group, aralkyl group, alkyl halide group, aryl halide group, aralkyl halide group, alkoxyalkyl group, alkoxyaryl group, alkoxyaralkyl group, and alkenyl group in these groups, substituents thereof, and the preferred number of carbon atoms thereof are the same as those described above with regard to R¹.

The alkylene group is a divalent group derived by further removing one hydrogen atom from the alkyl group, and may be linear, branched, or cyclic. Specific examples of the alkylene group are the same as those described above. The number of carbon atoms of the alkylene group is not particularly limited, but is preferably 40 or less, more preferably 30 or less, still more preferably 20 or less, and yet still more preferably 10 or less.

In addition, the alkylene group of R⁴⁰⁵ may have one or more types of bonds selected from a sulfide bond, an ether bond, and an ester bond at terminal ends or in the middle, and preferably in the middle.

Specific examples of the alkylene group include, but are not limited to, linear alkylene groups such as a methylene group, an ethylene group, a trimethylene group, a tetramethylene group, a pentamethylene group, a hexamethylene group, a heptamethylene group, an octamethylene group, a nonamethylene group and a decamethylene group; branched alkylene groups such as a methylethylene group, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group and a 1-ethyltrimethylene group; cyclic alkylene groups such as a 1,2-cyclopropanediyl group, a 1,2-cyclobutanediyl group, a 1,3-cyclobutanediyl group, a 1,2-cyclohexanediyl group and a 1,3-cyclohexanediyl group; and ether groups such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—.

The hydroxyalkylene group is a group in which at least one hydrogen atom of the above-described alkylene group is replaced with a hydroxy group. Specific examples of the hydroxyalkylene group include, but are not limited to, a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group.

In Formula (4-2), each X₄₀₁ independently represents any one of groups represented by the following Formulae (4-3) to (4-5), and a carbon atom of a ketone group in the following Formulae (4-4) and (4-5) is bonded to a nitrogen atom to which R⁴⁰⁵ in Formula (4-2) is bonded.

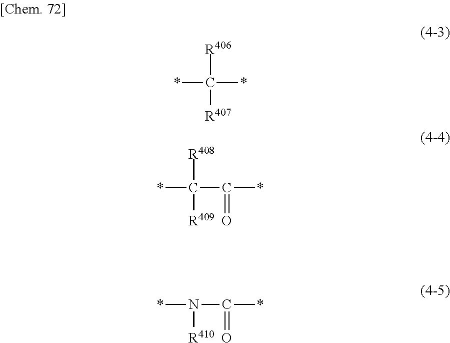

In Formulae (4-3) to (4-5), R⁴⁰⁶ to R⁴¹⁰ each independently represents a hydrogen atom, an optionally substituted alkyl group, an optionally substituted alkenyl group, or an organic group having an epoxy group or a sulfonyl group. Specific examples of the optionally substituted alkyl group, the optionally substituted alkenyl group, and the organic group having an epoxy group or a sulfonyl group, and the preferred number of carbon atoms thereof are the same as those described above with regard to R¹. Specific examples of the organic group having a sulfonyl group and the preferred number of carbon atoms are the same as those described above with regard to R⁴⁰⁴. Each asterisk * represents a bonding hand.

From the viewpoint of realizing excellent lithography characteristics with good reproducibility, X₄₀₁ is preferably a group represented by Formula (4-5) among the above Formulae.

From the viewpoint of realizing excellent lithography characteristics with good reproducibility, at least one of R⁴⁰⁴ and R⁴⁰⁶ to R⁴¹⁰ is preferably an alkyl group in which a terminal hydrogen atom is substituted with a vinyl group.

As the hydrolyzable organosilane represented by Formula (4-1), a commercially available product may be used. The hydrolyzable organosilane can also be synthesized by a known method described in WO 2011/102470 A or the like.

Hereinafter, specific examples of the hydrolyzable organosilane represented by Formula (4-1) include, but are not limited to, silanes represented by the following Formulae (4-1-1) to (Apr. 1, 2029).

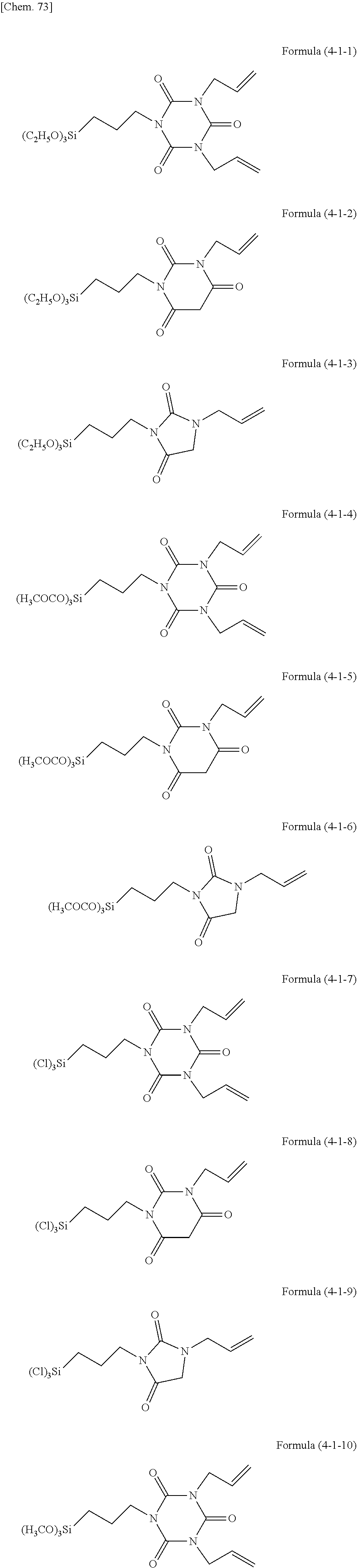

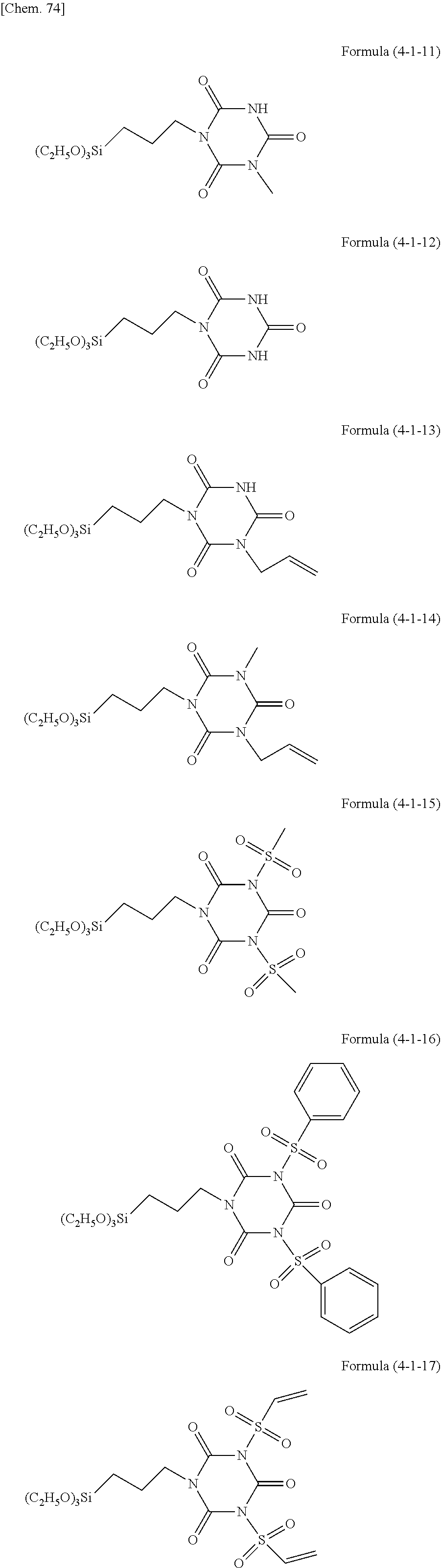

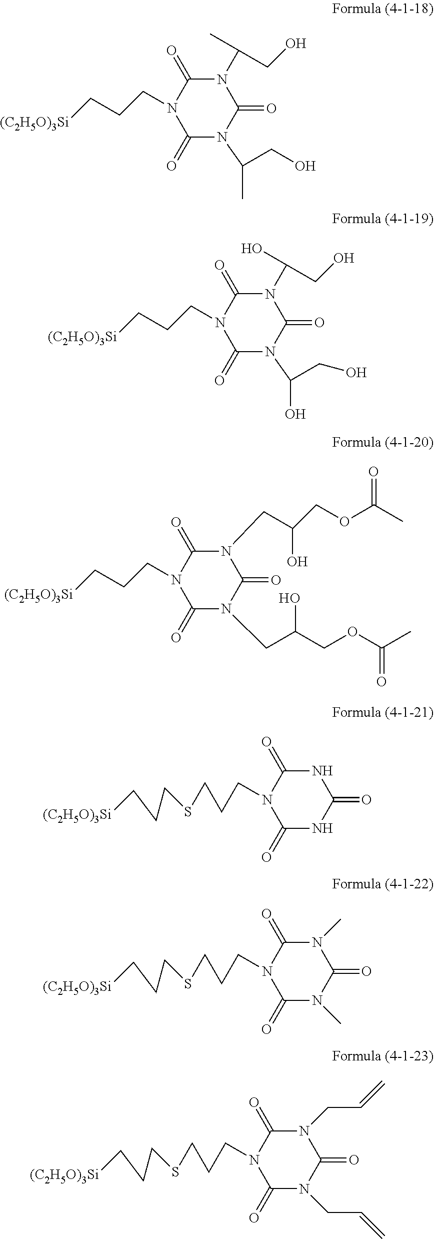

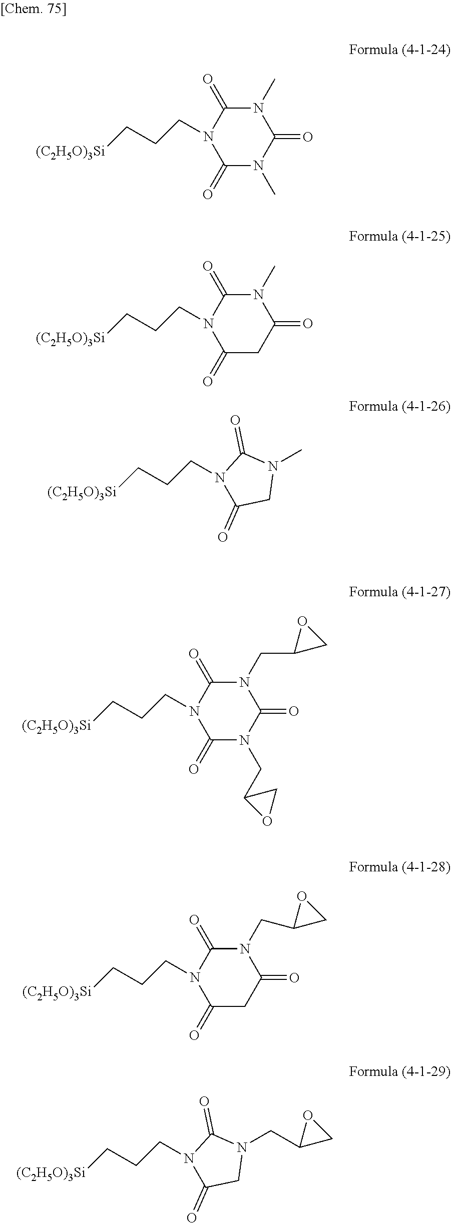

The polysiloxane [A] may be a hydrolysis condensate of a hydrolyzable silane containing a silane compound other than those exemplified above as long as the effects of the present invention are not impaired.

As described above, as the polysiloxane [A], a modified polysiloxane in which at least some of silanol groups are modified can be used. For example, a modified polysiloxane in which some of silanol groups are alcohol-modified or acetal-protected can be used.

Examples of the polysiloxane as the modified product include a product prepared by a reaction between at least some of silanol groups of the above-described hydrolysis condensate of hydrolyzable silane and a hydroxy group of an alcohol, a product prepared by dehydration reaction between the condensate and an alcohol, and a modified product prepared by protection of at least some of silanol groups of the condensate with an acetal group.

As the alcohol, a monohydric alcohol can be used. Examples of the monohydric alcohol include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

For example, alkoxy group-containing alcohols such as 3-methoxybutanol, ethylene glycol monomethyl ether, ethylene glycol monoethyl ether, diethylene glycol monomethyl ether, diethylene glycol monoethyl ether, propylene glycol monomethyl ether (1-methoxy-2-propanol), propylene glycol monoethyl ether (1-ethoxy-2-propanol), and propylene glycol monobutyl ether (1-butoxy-2 propanol) can be used.

The reaction between silanol groups of the condensate and hydroxy groups of the alcohol is performed by bringing the polysiloxane in to contact with the alcohol. A modified polysiloxane containing capped silanol groups is prepared by performing the reaction at a temperature of 40 to 160° C. (e.g. 60° C.) for 0.1 to 48 hours (e.g. 24 hours). In this case, the alcohol serving as a capping agent may be used as a solvent in the composition containing the polysiloxane.

The product by dehydration reaction between the polysiloxane including the hydrolysis condensate of hydrolyzable silane and the alcohol can be produced by reacting the polysiloxane with the alcohol in the presence of an acid as a catalyst, capping silanol groups with the alcohol, and removing water generated through the dehydration to the outside of the reaction system.

The acid may be an organic acid having an acid dissociation constant (pKa) of −1 to 5, preferably 4 to 5. Examples of the acid include trifluoroacetic acid, maleic acid, benzoic acid, isobutyric acid, and acetic acid. In particular, benzoic acid, isobutyric acid, and acetic acid can be exemplified.

As the acid, an acid having a boiling point of 70 to 160° C. may be used. Examples of the acid include trifluoroacetic acid, isobutyric acid, acetic acid, and nitric acid.

Preferably, the acid described above has either an acid dissociation constant (pKa) of 4 to 5 or a boiling point of 70 to 160° C. That is, the acid to be used may be an acid having a weak acidity, or an acid having a strong acidity and a low boiling point.

Either of these properties: acid dissociation constant and boiling point of the acid may be utilized.

The acetal protection of silanol groups of the condensate can be performed with a vinyl ether; for example, a vinyl ether represented by the following Formula (5). Such a reaction can be performed to introduce a partial structure represented by the following Formula (6) into the polysiloxane.

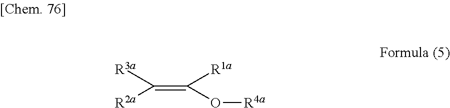

In Formula (5), R^{1a}, R^{2a}, and R^{3a} each represent a hydrogen atom or an alkyl group having 1 to 10 carbon atoms, R^{4a} represents an alkyl group having 1 to 10 carbon atoms, and R^{2a} and R^{4a} may be bonded together to form a ring. Examples of the alkyl group are the same as those described above.

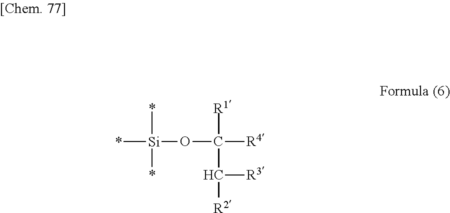

In Formula (6), R^{1′}, R^{2′}, and R^{3′} each represent a hydrogen atom or an alkyl group having 1 to 10 carbon atoms, R^{4′} represents an alkyl group having 1 to 10 carbon atoms, and R^{2′} and R^{4′} may be bonded together to form a ring. In Formula (6), * represents a bond to an adjacent atom. The adjacent atom is, for example, an oxygen atom of a siloxane bond, an oxygen atom of a silanol group, or a carbon atom derived from R¹ of Formula (1). Examples of the alkyl group are the same as those described above.

As the vinyl ether represented by Formula (5), for example, aliphatic vinyl ether compounds, such as methyl vinyl ether, ethyl vinyl ether, isopropyl vinyl ether, normal butyl vinyl ether, 2-ethylhexyl vinyl ether, tert-butyl vinyl ether, and cyclohexyl vinyl ether; and cyclic vinyl ether compounds, such as 2,3-dihydrofuran, 4-methyl-2,3-dihydrofuran, and 3,4-dihydro-2H-pyran, may be used. In particular, ethyl vinyl ether, propyl vinyl ether, butyl vinyl ether, ethylhexyl vinyl ether, cyclohexyl vinyl ether, 3,4-dihydro-2H-pyran, or 2,3-dihydrofuran may be preferably used.

The acetal protection of silanol groups can be performed using a polysiloxane, a vinyl ether, and an aprotic solvent such as propylene glycol monomethyl ether acetate, ethyl acetate, dimethylformamide, tetrahydrofuran, or 1,4-dioxane as a solvent, and a catalyst such as pyridium p-toluenesulfonate, trifluoromethanesulfonic acid, p-toluenesulfonic acid, methanesulfonic acid, hydrochloric acid, or sulfuric acid.

The capping of silanol groups with an alcohol or the acetal protection of silanol groups may be performed simultaneously with the hydrolysis and condensation of the hydrolyzable silane described below.

In a preferred aspect of the present invention, the polysiloxane [A] includes at least one of a hydrolysis condensate of a hydrolyzable silane and a modified product thereof, the hydrolyzable silane including a hydrolyzable silane represented by Formula (1) and, if desired, a hydrolyzable silane represented by Formula (2) and other hydrolyzable silanes.

In a preferred aspect, the polysiloxane [A] includes a dehydration reaction product of a hydrolysis condensate and an alcohol.

The hydrolysis condensate of hydrolyzable silane (which may also include a modified product) may have a weight-average molecular weight of, for example, 500 to 1,000,000. From the viewpoint of preventing the precipitation of the hydrolysis condensate in the composition, the weight-average molecular weight is preferably 500,000 or less, more preferably 250,000 or less, and still more preferably 100,000 or less. From the viewpoint of the compatibility between storage stability and application property, the weight-average molecular weight may be preferably 700 or more, more preferably 1,000 or more.

The weight-average molecular weight is determined by GPC analysis in terms of polystyrene. The GPC analysis can be performed under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (manufactured by Showa Denko K. K.) as a standard sample.

The hydrolysis condensate of hydrolyzable silane is prepared by hydrolysis and condensation of the above-described silane compound (hydrolyzable silane).

The above-described silane compound (hydrolyzable silane) contains an alkoxy group, aralkyloxy group, acyloxy group, or halogen atom directly bonded to a silicon atom; i.e. an alkoxysilyl group, an aralkyloxysilyl group, an acyloxysilyl group, or a halogenated silyl group (hereinafter, such a group is referred to as “hydrolyzable group”).

For the hydrolysis of the hydrolyzable group, ordinarily 0.1 to 100 mol, for example, 0.5 to 100 mol, preferably 1 to 10 mol, of water is used per mol of the hydrolyzable group.

During hydrolysis and condensation, a hydrolysis catalyst may be used for the purpose of promoting the reaction. Alternatively, the hydrolysis and condensation may be performed without use of a hydrolysis catalyst. When a hydrolysis catalyst is used, the amount of the hydrolysis catalyst is ordinarily 0.0001 to 10 mol, preferably 0.001 to 1 mol per mol of the hydrolyzable group.

The reaction temperature for the hydrolysis and condensation is ordinarily equal to or higher than room temperature, or equal to or lower than the reflux temperature at normal pressure of an organic solvent usable for hydrolysis. The reaction temperature may be, for example, 20 to 110° C., or, for example, 20 to 80° C.

The hydrolysis may be performed completely; i.e. all hydrolyzable groups may be converted into silanol groups, or may be performed partially; i.e. unreacted hydrolyzable groups may remain.

Examples of the hydrolysis catalyst usable for the hydrolysis and condensation include a metal chelate compound, an organic acid, an inorganic acid, an organic base, and an inorganic base.

Examples of the metal chelate compound as the hydrolysis catalyst include, but are not limited to, titanium chelate compounds such as triethoxy-mono(acetylacetonate)titanium, tri-n-propoxy-mono(acetylacetonate)titanium, tri-i-propoxy-mono(acetylacetonate)titanium, tri-n-butoxy-mono(acetylacetonate)titanium, tri-sec-butoxy-mono(acetylacetonate)titanium, tri-t-butoxy-mono(acetylacetonate)titanium, diethoxy-bis(acetylacetonate)titanium, di-n-propoxy-bis(acetylacetonate)titanium, di-i-propoxy-bis(acetylacetonate)titanium, di-n-butoxy-bis(acetylacetonate)titanium, di-sec-butoxy-bis(acetylacetonate)titanium, di-t-butoxy-bis(acetylacetonate)titanium, monoethoxy-tris(acetylacetonate)titanium, mono-n-propoxy-tris(acetylacetonate)titanium, mono-i-propoxy-tris(acetylacetonate)titanium, mono-n-butoxy-tris(acetylacetonate)titanium, mono-sec-butoxy-tris(acetylacetonate)titanium, mono-t-butoxy-tris(acetylacetonate)titanium, tetrakis(acetylacetonate)titanium, triethoxy-mono(ethyl acetoacetate)titanium, tri-n-propoxy-mono(ethyl acetoacetate)titanium, tri-i-propoxy-mono(ethyl acetoacetate)titanium, tri-n-butoxy-mono(ethyl acetoacetate)titanium, tri-sec-butoxy-mono(ethyl acetoacetate)titanium, tri-t-butoxy-mono(ethyl acetoacetate)titanium, diethoxy-bis(ethyl acetoacetate)titanium, di-n-propoxy-bis(ethyl acetoacetate)titanium, di-i-propoxy-bis(ethyl acetoacetate)titanium, di-n-butoxy-bis(ethyl acetoacetate)titanium, di-sec-butoxy-bis(ethyl acetoacetate)titanium, di-t-butoxy-bis(ethyl acetoacetate)titanium, monoethoxy-tris(ethyl acetoacetate)titanium, mono-n-propoxy-tris(ethyl acetoacetate)titanium, mono-i-propoxy-tris(ethyl acetoacetate)titanium, mono-n-butoxy-tris(ethyl acetoacetate)titanium, mono-sec-butoxy-tris(ethyl acetoacetate)titanium, mono-t-butoxy-tris(ethyl acetoacetate)titanium, tetrakis(ethyl acetoacetate)titanium, mono(acetylacetonate)tris(ethyl acetoacetate)titanium, bis(acetylacetonate)bis(ethyl acetoacetate)titanium, and tris(acetylacetonate) mono(ethyl acetoacetate)titanium; zirconium chelate compounds such as triethoxy-mono(acetylacetonate)zirconium, tri-n-propoxy-mono(acetylacetonate)zirconium, tri-i-propoxy-mono(acetylacetonate)zirconium, tri-n-butoxy-mono(acetylacetonate)zirconium, tri-sec-butoxy-mono(acetylacetonate)zirconium, tri-t-butoxy-mono(acetylacetonate)zirconium, diethoxy-bis(acetylacetonate)zirconium, di-n-propoxy-bis(acetylacetonate)zirconium, di-i-propoxy-bis(acetylacetonate)zirconium, di-n-butoxy-bis(acetylacetonate)zirconium, di-sec-butoxy-bis(acetylacetonate)zirconium, di-t-butoxy-bis(acetylacetonate)zirconium, monoethoxy-tris(acetylacetonate)zirconium, mono-n-propoxy-tris(acetylacetonato)zirconium, mono-i-propoxy-tris(acetylacetonate)zirconium, mono-n-butoxy-tris(acetylacetonate)zirconium, mono-sec-butoxy-tris(acetylacetonate)zirconium, mono-t-butoxy-tris(acetylacetonate)zirconium, tetrakis(acetylacetonate)zirconium, triethoxy-mono(ethyl acetoacetate)zirconium, tri-n-propoxy-mono(ethyl acetoacetate)zirconium, tri-i-propoxy-mono(ethyl acetoacetate)zirconium, tri-n-butoxy-mono(ethyl acetoacetate)zirconium, tri-sec-butoxy-mono(ethyl acetoacetate)zirconium, tri-t-butoxy-mono(ethyl acetoacetate)zirconium, diethoxy-bis(ethyl acetoacetate)zirconium, di-n-propoxy-bis(ethyl acetoacetate)zirconium, di-i-propoxy-bis(ethyl acetoacetate)zirconium, di-n-butoxy-bis(ethyl acetoacetate)zirconium, di-sec-butoxy-bis(ethyl acetoacetate)zirconium, di-t-butoxy-bis(ethyl acetoacetate)zirconium, monoethoxy-tris(ethyl acetoacetate)zirconium, mono-n-propoxy-tris(ethyl acetoacetate)zirconium, mono-i-propoxy-tris(ethyl acetoacetate)zirconium, mono-n-butoxy-tris(ethyl acetoacetate)zirconium, mono-sec-butoxy-tris(ethyl acetoacetate)zirconium, mono-t-butoxy-tris(ethyl acetoacetate)zirconium, tetrakis(ethyl acetoacetate)zirconium, mono(acetylacetonate)tris(ethyl acetoacetate)zirconium, bis(acetylacetonate)bis(ethyl acetoacetate)zirconium, and tris(acetylacetonate) mono(ethyl acetoacetate)zirconium; and aluminum chelate compounds such as tris(acetylacetonate)aluminum and tris(ethyl acetoacetate)aluminum.

Examples of the organic acid as the hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid as the hydrolysis catalyst include, but are not limited to, hydrochloric acid, nitric acid, sulfuric acid, hydrofluoric acid, and phosphoric acid.

Examples of the organic base as the hydrolysis catalyst include, but are not limited to, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononene, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base as the hydrolysis catalyst include, but are not limited to, ammonia, sodium hydroxide, potassium hydroxide, barium hydroxide, and calcium hydroxide.

Among these catalysts, a metal chelate compound, an organic acid, and an inorganic acid is preferred. These catalysts may be used singly or in combination of two or more kinds thereof.

In particular, nitric acid can be suitably used as a hydrolysis catalyst in the present invention. The use of nitric acid enables an improvement in the storage stability of a reaction solution after the hydrolysis and condensation, and particularly enables suppression of a change in the molecular weight of a hydrolysis condensate. It is known that the stability of the hydrolysis condensate contained in the reaction solution depends on the pH of the solution. As a result of intensive studies, it has been found that the pH of the reaction solution falls in a stable range by use of an appropriate amount of nitric acid.

As described above, nitric acid can also be used for preparation of a modified product of the hydrolysis condensate; for example, for capping of silanol groups with an alcohol. Thus, nitric acid is preferred from the viewpoint that it can contribute to the reactions of hydrolysis and condensation of the hydrolyzable silane, as well as the reaction of capping of the hydrolysis condensate with an alcohol.

An organic solvent may be used for the hydrolysis and condensation. Specific examples of the organic solvent include, but are not limited to, aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents, such as dimethyl sulfide, diethyl sulfide, thiophene, tetrahydrothiophene, dimethyl sulfoxide, sulfolane, and 1,3-propanesultone. These solvents can be used singly or in combination of two or more kinds thereof.

After completion of the hydrolysis and condensation reactions, the reaction solution is used as is, or diluted or concentrated. The resultant reaction solution can be neutralized or treated with an ion exchange resin, and thus the hydrolysis catalyst, e.g. an acid or a base, used for the hydrolysis and condensation can be removed. Before or after such a treatment, alcohols: by-products, water, the used hydrolysis catalyst, and the like can be removed from the reaction solution, for example, by distillation under reduced pressure.

The thus-prepared hydrolysis condensate (hereinafter, also referred to as “polysiloxane”) is in the form of a polysiloxane varnish dissolved in an organic solvent, which may be used as is for preparation of the silicon-containing resist underlayer film-forming composition. That is, the reaction solution may be used as is (or diluted) for preparation of the silicon-containing resist underlayer film-forming composition. In this case, the hydrolysis catalyst used for the hydrolysis and condensation, by-products, and the like may remain in the reaction solution, so long as the effects of the present invention is not impaired. For example, nitric acid used as a hydrolysis catalyst or used for capping of silanol groups with an alcohol may remain in the polymer varnish solution in an amount of about 100 ppm to 5,000 ppm.

The resultant polysiloxane varnish may be subjected to solvent replacement, or may be appropriately diluted with a solvent. In a case where the storage stability of the resultant polysiloxane varnish is not poor, the organic solvent may be distilled off to achieve a film-forming component concentration of 100%. The film-forming component refers to a component resulted from the removal of a solvent component from all the components of the composition.

The organic solvent used for solvent replacement, dilution, or the like of the polysiloxane varnish may be identical to or different from the organic solvent used for the hydrolysis and condensation reactions of the hydrolyzable silane. The solvent for dilution is not particularly limited, and one kind or two or more kinds of solvents may be arbitrarily selected and used.

### <Component [B]>

The aromatic iodine compound as the component [B] is not particularly limited as long as it is a compound having an aromatic ring and an iodine atom directly bonded to the aromatic ring.

The number of iodine atoms directly bonded to the aromatic ring in the aromatic iodine compound is not particularly limited, and may be 1 or 2 or more.

The number of iodine atoms directly bonded to the aromatic ring in the aromatic iodine compound is, for example, 1 to 4.

The number of aromatic rings of the aromatic iodine compound is not particularly limited, and may be 1 or 2 or more.

When the number of aromatic rings in the aromatic iodine compound is 2 or more, an iodine atom may be directly bonded to at least one aromatic ring.

The aromatic ring of the aromatic iodine compound may be an aromatic hydrocarbon ring or an aromatic heterocyclic ring.

Examples of the aromatic hydrocarbon ring include a benzene ring, a naphthalene ring, an anthracene ring, an indene ring, a fluorene ring, a spirobifluorene ring, a phenanthrene ring, a dihydrophenanthrene ring, a pyrene ring, a chrysene ring, and a triphenylene ring.

Examples of the aromatic heterocyclic ring include a pyrrole ring, a diazole ring, a triazole ring, a furan ring, a thiophene ring, an oxadiazole ring, a thiadiazole ring, a pyridine ring, a diazabenzene ring, a triazine ring, an azanaphthalene ring, a diazanaphthalene ring, a triazanaphthalene ring, an azaanthracene ring, a diazaanthracene ring, a triazaanthracene ring, an azaphenanthrene ring, a diazaphenanthrene ring, a triazaphenanthrene ring, a dibenzofuran ring, a dibenzothiophene ring, a dibenzosilole ring, a dibenzophosphole ring, a carbazole ring, an azacarbazole ring, a diazacarbazole ring, a phenoxazine ring, a phenothiazine ring, a dihydroacridine ring, and a dihydrophenazine ring.

In addition to the aromatic ring and the iodine atom directly bonded to the aromatic ring, the aromatic iodine compound may have other atomic groups such as a non-aromatic hydrocarbon group and a polar group.

The aromatic iodine compound preferably has a hydrophilic group from the viewpoint of achieving good solvent solubility.

The aromatic iodine compound preferably has at least one selected from a carboxy group, a hydroxy group, a sulfo group, and an amino group (—NH₂) from the viewpoint of achieving good solvent solubility.

The aromatic iodine compound may be a salt, or need not be a salt.

When the aromatic iodine compound is a salt, the aromatic iodine compound may be an aromatic iodonium salt or a salt other than the aromatic iodonium salt, and is preferably an aromatic iodonium salt. Examples of the aromatic iodonium salt include a compound represented by the following Formula (I-4).

The molecular weight of the aromatic iodine compound is not particularly limited, and may be, for example, 1000 or less, 800 or less, or 550 or less.

Examples of the aromatic iodine compound include compounds represented by the following Formulae (I-1) to (I-4).

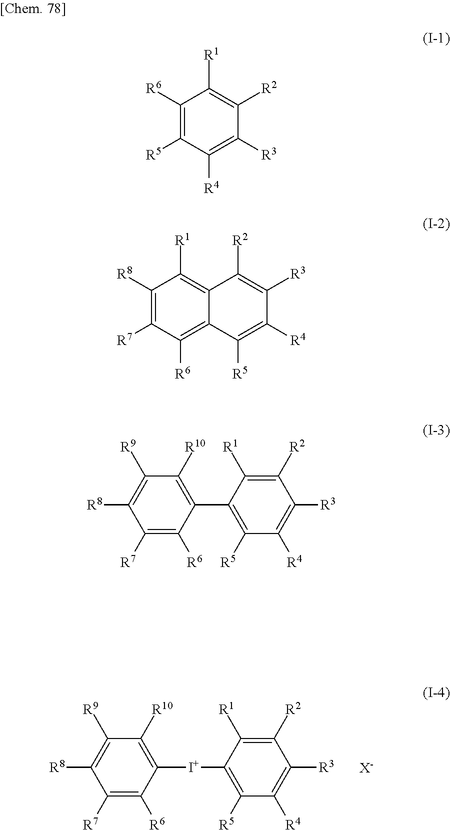

where in Formula (I-1), R¹ to R⁶ each independently represent a hydrogen atom, a halogen atom, an alkyl group having 1 to 6 carbon atoms optionally substituted with a halogen atom, an alkoxy group having 1 to 6 carbon atoms optionally substituted with a halogen atom, an acyl group having 2 to 6 carbon atoms optionally substituted with a halogen atom, a carboxy group, a hydroxy group, a sulfo group, or —NR^{a}R^{b} (R^{a} and R^{b} each independently represent a hydrogen atom or an alkyl group having 1 to 4 carbon atoms), provided that at least one of R¹ to R⁶ represents an iodine atom.

In Formula (I-2), R¹ to R⁸ each independently represent a hydrogen atom, a halogen atom, an alkyl group having 1 to 6 carbon atoms optionally substituted with a halogen atom, an alkoxy group having 1 to 6 carbon atoms optionally substituted with a halogen atom, an acyl group having 2 to 6 carbon atoms optionally substituted with a halogen atom, a carboxy group, a hydroxy group, a sulfo group, or —NR^{a}R^{b} (R^{a} and R^{b} each independently represent a hydrogen atom or an alkyl group having 1 to 4 carbon atoms), provided that at least one of R¹ to R⁸ represents an iodine atom.

In Formula (I-3), R¹ to R¹⁰ each independently represent a hydrogen atom, a halogen atom, an alkyl group having 1 to 6 carbon atoms optionally substituted with a halogen atom, an alkoxy group having 1 to 6 carbon atoms optionally substituted with a halogen atom, an acyl group having 2 to 6 carbon atoms optionally substituted with a halogen atom, a carboxy group, a hydroxy group, a sulfo group, or —NR^{a}R^{b} (R^{a} and R^{b} each independently represent a hydrogen atom or an alkyl group having 1 to 4 carbon atoms), provided that at least one of R¹ to R¹⁰ represents an iodine atom.

In Formula (I-4), R¹ to R¹⁰ each independently represent a hydrogen atom, a halogen atom, an alkyl group having 1 to 6 carbon atoms optionally substituted with a halogen atom, an alkoxy group having 1 to 6 carbon atoms optionally substituted with a halogen atom, an acyl group having 2 to 6 carbon atoms optionally substituted with a halogen atom, a carboxy group, a hydroxy group, a sulfo group, or —NR^{a}R^{b} (R^{a} and R^{b} each independently represent a hydrogen atom or an alkyl group having 1 to 4 carbon atoms), and X⁻ represents a monovalent anion.

Examples of the halogen atom include a fluorine atom, a chlorine atom, an iodine atom, and a bromine atom.

Examples of the alkyl group having 1 to 6 carbon atoms optionally substituted with a halogen atom include an alkyl group having 1 to 6 carbon atoms.

Examples of the alkoxy group having 1 to 6 carbon atoms optionally substituted with a halogen atom include an alkoxy group having 1 to 6 carbon atoms.

Examples of the acyl group having 2 to 6 carbon atoms optionally substituted with a halogen atom include an acyl group having 2 to 6 carbon atoms.

Examples of X— include Cl⁻, Br⁻, I⁻, NO₃⁻, CH₃COO⁻, HOOC—CH═CH—COO⁻, and CF₃SO₃⁻.

Examples of the aromatic iodine compound include the following compounds.

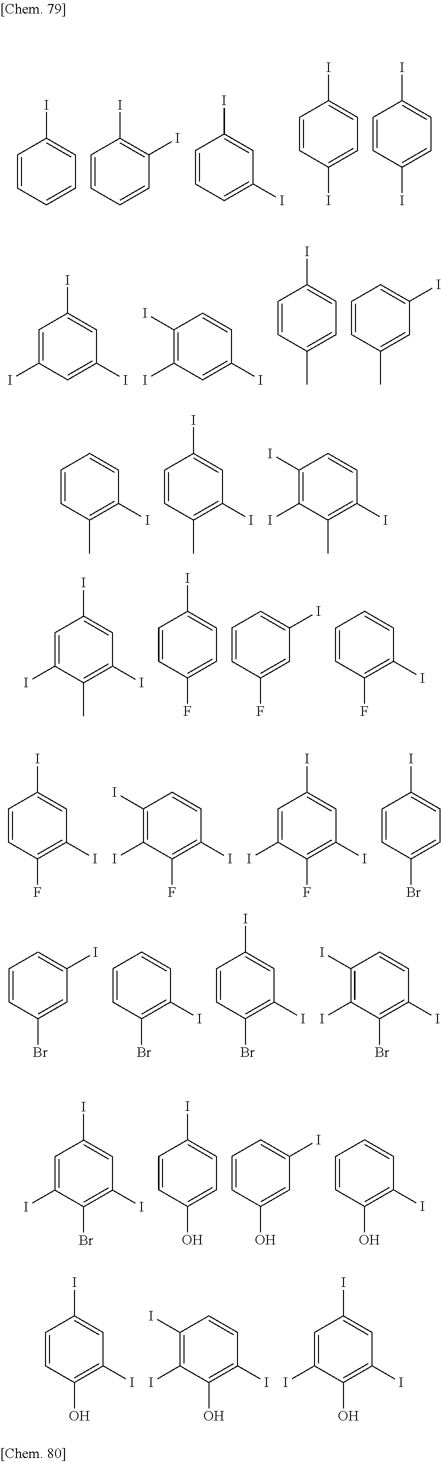

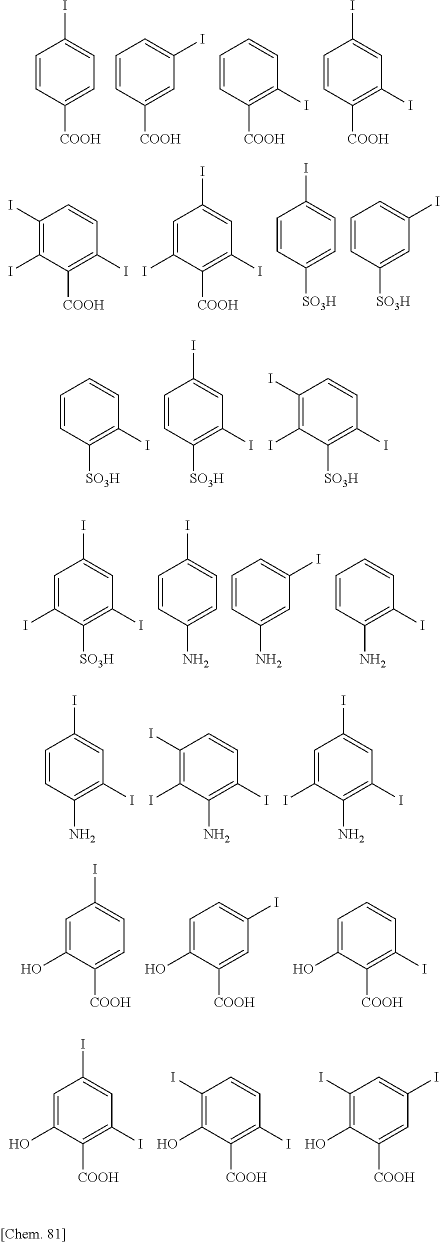

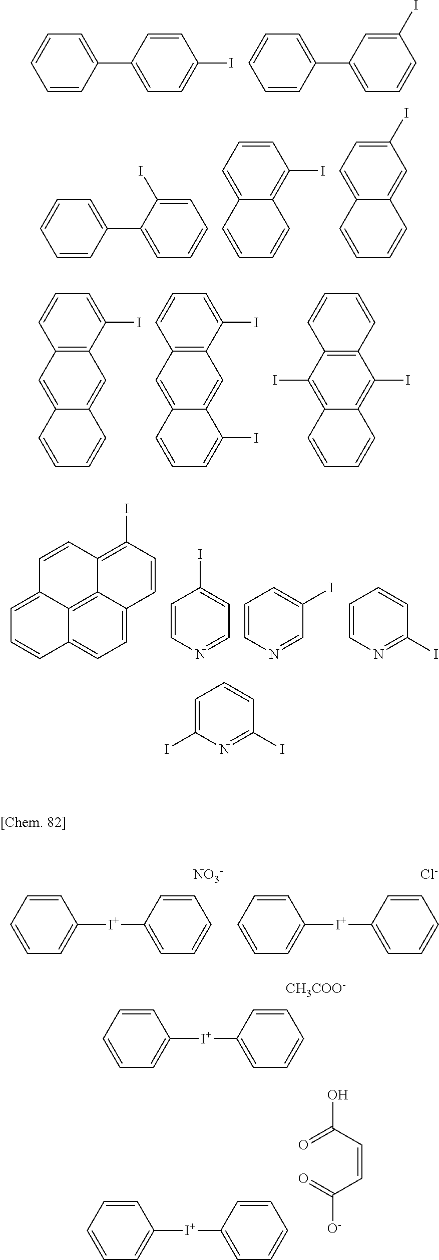

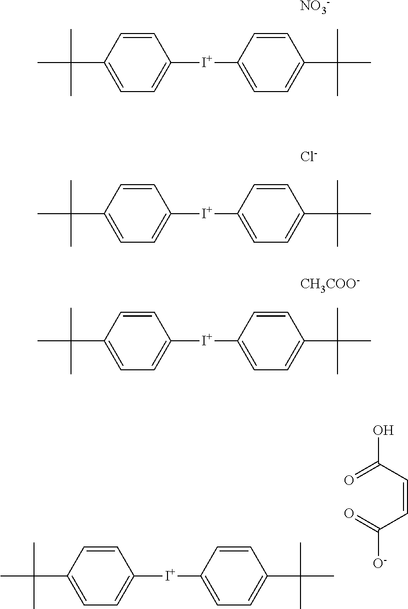

The content of the component [B] in the silicon-containing resist underlayer film-forming composition is not particularly limited, and may be preferably 0.1 to 20 parts by mass, more preferably 0.5 to 10 parts by mass, and still more preferably 1 to 5 parts by mass relative to 100 parts by mass of the polysiloxane [A] from the viewpoint of more sufficiently achieving the effects of the present invention.

### <Component [C]: Solvent>

The solvent as the component [C] can be used without particular limitation as long as it is a solvent capable of dissolving and mixing the component [A] and the component [B] and, if necessary, other components contained in the silicon-containing resist underlayer film-forming composition.

The solvent [C] is preferably an alcohol-based solvent, more preferably alkylene glycol monoalkyl ether: alcohol-based solvent, and still more preferably propylene glycol monoalkyl ether. Since these solvents are also capping agents for silanol groups of the polysiloxane, the solvent replacement or the like is not required. The silicon-containing resist underlayer film-forming composition can be prepared from a solution obtained by preparation of the polysiloxane [A].

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Specific examples of other solvent [C] include methyl cellosolve acetate, ethyl cellosolve acetate, propylene glycol, propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and γ-butyrolactone. These solvents can be used singly or in combination of two or more kinds thereof.

The silicon-containing resist underlayer film-forming composition of the present invention may contain water as a solvent. When water is contained as the solvent, the content thereof may be, for example, 30 mass % or less, preferably 20 mass % or less, and still more preferably 15 mass % or less relative to the total mass of the solvent contained in the composition.

### <Component [D]: Curing Catalyst>

The silicon-containing resist underlayer film-forming composition may contain no curing catalyst. Alternatively, the composition preferably contains a curing catalyst (component [D]).

The curing catalyst may be, for example, an ammonium salt, a phosphine compound, a phosphonium salt, or a sulfonium salt. The salt described below as an example of a curing catalyst may be added in the form of a salt, or may be a compound that forms a salt in the composition (i.e. a compound that forms a salt in the system, but is in a form different from the salt during addition).

The curing catalyst is not, for example, an aromatic iodonium salt.

The curing catalyst is not, for example, aromatic iodonium-perfluoroalkylsulfonate.

The curing catalyst is not, for example, aromatic iodonium-trifluoromethanesulfonate.

Examples of the ammonium salt include: a quaternary ammonium salt having a structure represented by the following Formula (D-1):

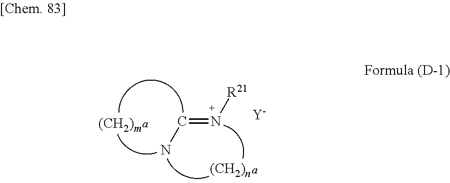

where m^{a} represents an integer of 2 to 11, n^{a} represents an integer of 2 to 3, R²¹ represents an alkyl group, an aryl group, or an aralkyl group, and Y-represents an anion;
a quaternary ammonium salt having a structure represented by the following Formula (D-2):

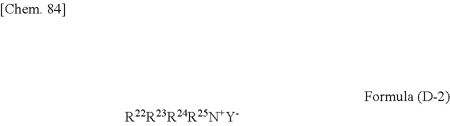

where R²², R²³, R²⁴, and R²⁵ each independently represent an alkyl group, an aryl group, or an aralkyl group, γ-represents an anion, and R²², R²³, R²⁴, and R²⁵ are each bonded to a nitrogen atom;
a quaternary ammonium salt having a structure represented by the following Formula (D-3):

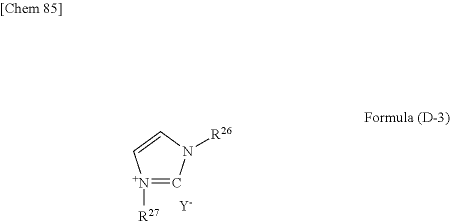

where R²⁶ and R²⁷ each independently represent an alkyl group, an aryl group, or an aralkyl group, and Y— represents an anion;
a quaternary ammonium salt having a structure represented by the following Formula (D-4):

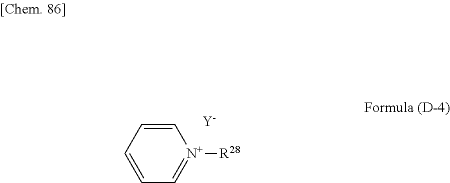

where R²⁸ represents an alkyl group, an aryl group, or an aralkyl group, and Y— represents an anion;
a quaternary ammonium salt having a structure represented by the following Formula (D-5):

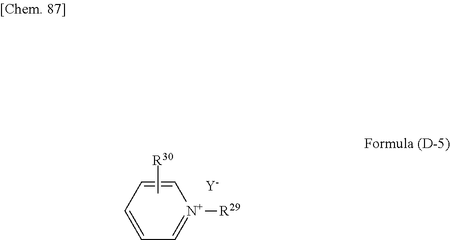

where R²⁹ and R³⁰ each independently represent an alkyl group, an aryl group, or an aralkyl group, and Y⁻ represents an anion;
a tertiary ammonium salt having a structure represented by the following Formula (D-6):

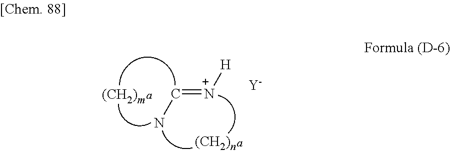

where m^{a} represents an integer of 2 to 11, n^{a} represents an integer of 2 to 3, and Y-represents an anion.

Examples of the phosphonium salt include a quaternary phosphonium salt represented by the following Formula (D-7):

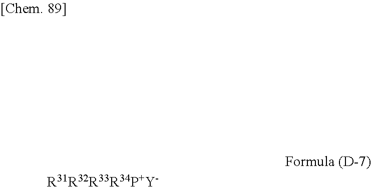

where R³¹, R³², R³³, and R³⁴ each independently represent an alkyl group, an aryl group, or an aralkyl group, γ-represents an anion, and each of R³¹, R³², R³³, and R³⁴ is bonded to the phosphorus atom.

Examples of the sulfonium salt include a tertiary sulfonium salt represented by the following Formula (D-8):

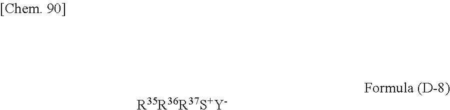

where R³⁵, R³⁶, and R³⁷ each independently represent an alkyl group, an aryl group, or an aralkyl group, γ-represents an anion, and each of R³⁵, R³⁶, and R³⁷ is bonded to the sulfur atom.

The compound of Formula (D-1) is a quaternary ammonium salt derived from an amine, where m^{a} represents an integer of 2 to 11, and n^{a} represents an integer of 2 to 3. R²¹ of the quaternary ammonium salt represents, for example, an alkyl group having 1 to 18 carbon atoms, preferably 2 to 10 carbon atoms, an aryl group having 6 to 18 carbon atoms, or an aralkyl group having 7 to 18 carbon atoms. Examples thereof include linear alkyl groups such as an ethyl group, a propyl group, and a butyl group; a benzyl group, a cyclohexyl group, a cyclohexylmethyl group, and a dicyclopentadienyl group. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻).

The compound of Formula (D-2) is a quaternary ammonium salt represented by R²²R²³R²⁴R²⁵N⁺Y⁻. R²², R²³, R²⁴, and R²⁵ of the quaternary ammonium salt are each, for example, an alkyl group having 1 to 18 carbon atoms, such as ethyl group, propyl group, butyl group, cyclohexyl group, and cyclohexylmethyl group, an aryl group having 6 to 18 carbon atoms, such as phenyl group, or an aralkyl group having 7 to 18 carbon atoms, such as benzyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. The number of carbon atoms of each of R²⁶ and R²⁷ is, for example, 1 to 18, and the total number of carbon atoms of R²⁶ and R²⁷ is preferably 7 or more. Examples of R²⁶ include alkyl groups, such as a methyl group, an ethyl group, and a propyl group, and aryl groups, such as a phenyl group. Examples of R²⁷ include aralkyl groups, such as a benzyl group, and alkyl groups, such as an octyl group and an octadecyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between an imidazole compound (e.g. 1-methylimidazole or 1-benzylimidazole) and an aralkyl halide, an alkyl halide, or an aryl halide, such as benzyl bromide, methyl bromide, or benzene bromide.

The compound of Formula (D-4) is a quaternary ammonium salt derived from pyridine. R²⁸ is, for example, an alkyl group having 1 to 18 carbon atoms, preferably 4 to 18 carbon atoms, an aryl group having 6 to 18 carbon atoms, or an aralkyl group having 7 to 18 carbon atoms. Examples thereof include a butyl group, an octyl group, a benzyl group, and a lauryl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between pyridine and an alkyl halide or an aryl halide, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. R²⁹ is, for example, an alkyl group having 1 to 18 carbon atoms, preferably 4 to 18 carbon atoms, an aryl group having 6 to 18 carbon atoms, or an aralkyl group having 7 to 18 carbon atoms. Examples thereof include a methyl group, an octyl group, a lauryl group, and a benzyl group. R³⁰ is, for example, an alkyl group having 1 to 18 carbon atoms, an aryl group having 6 to 18 carbon atoms, or an aralkyl group having 7 to 18 carbon atoms. For example, R³⁰ is a methyl group when the compound represented by Formula (D-5) is a quaternary ammonium derived from picoline.

Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between a substituted pyridine (e.g. picoline) and an alkyl halide or an aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine, where m^{a} represents an integer of 2 to 11, and n^{a} represents 2 or 3. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The compound may be produced through reaction between an amine and a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are each, for example, an alkyl group having 1 to 18 carbon atoms, such as ethyl group, propyl group, butyl group, or cyclohexylmethyl, an aryl group having 6 to 18 carbon atoms, such as phenyl group, or an aralkyl group having 7 to 18 carbon atoms, such as benzyl group. Three of four substituents of R³¹ to R³⁴ are each preferably an unsubstituted phenyl group or a substituted phenyl group. Examples thereof include a phenyl group or a tolyl group. The remaining one substituent is an alkyl group having 1 to 18 carbon atoms, an aryl group having 6 to 18 carbon atoms, or an aralkyl group having 7 to 18 carbon atoms. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halide and tetra-n-propylphosphonium halide; trialkylbenzylphosphonium halides, such as triethylbenzylphosphonium halide; triphenylmonoalkylphosphonium halides, such as triphenylmethylphosphonium halide and triphenylethylphosphonium halide; triphenylbenzylphosphonium halide; tetraphenylphosphonium halide; tritolylmonoarylphosphonium halide; or tritolylmonoalkylphosphonium halide, where the halogen atom is a chlorine atom or a bromine atom. Particularly preferred are triphenylmonoalkylphosphonium halides, such as triphenylmethylphosphonium halide and triphenylethylphosphonium halide; triphenylmonoarylphosphonium halides, such as triphenylbenzylphosphonium halide; tritolylmonoarylphosphonium halides, such as tritolylmonophenylphosphonium halide; and tritolylmonoalkylphosphonium halides, such as tritolylmonomethylphosphonium halide, where the halogen atom is a chlorine atom or a bromine atom.

Examples of the phosphine compound include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are each, for example, an alkyl group having 1 to 18 carbon atoms, such as an ethyl group, a propyl group, a butyl group, or a cyclohexylmethyl, an aryl group having 6 to 18 carbon atoms, such as a phenyl group, or an aralkyl group having 7 to 18 carbon atoms, such as a benzyl group. Two of three substituents of R³⁵ to R³⁷ are each preferably an unsubstituted phenyl group or a substituted phenyl group. Examples thereof include a phenyl group or a tolyl group. The remaining one substituent is an alkyl group having 1 to 18 carbon atoms, an aryl group having 6 to 18 carbon atoms, or an aralkyl group having 7 to 18 carbon atoms. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), alcoholate (—O⁻), maleate anion, and nitrate anion. This compound is commercially available, and examples of the compound include trialkylsulfonium halides, such as tri-n-butylsulfonium halide and tri-n-propylsulfonium halide; dialkylbenzylsulfonium halides, such as diethylbenzylsulfonium halide; diphenylmonoalkylsulfonium halides, such as diphenylmethylsulfonium halide and diphenylethylsulfonium halide; triphenylsulfonium halides, where the halogen atom is a chlorine atom or a bromine atom; trialkylsulfonium carboxylates, such as tri-n-butylsulfonium carboxylate and tri-n-propylsulfonium carboxylate; dialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. Triphenylsulfonium halide and triphenylsulfonium carboxylate are preferably used.

In addition, a nitrogen-containing silane compound may be added as a curing catalyst. Examples of the nitrogen-containing silane compound include silane compounds containing an imidazole ring, such as N-(3-triethoxysilylpropyl)-4,5-dihydroimidazole.

The content of the curing catalyst [D] in the silicon-containing resist underlayer film-forming composition is preferably 0.1 to 30 parts by mass, more preferably 0.5 to 25 parts by mass, and still more preferably 1 to 20 parts by mass relative to 100 parts by mass of the polysiloxane [A] from the viewpoint of more sufficiently achieving the effects of the present invention.

The mass ratio ([B]/[D]) of the component [B] to the curing catalyst (component [D]) in the silicon-containing resist underlayer film-forming composition is not particularly limited, and is preferably 1 to 15, more preferably 1.5 to 10, and particularly preferably 2 to 8.

### <Component [E]: Nitric Acid>

The silicon-containing resist underlayer film-forming composition preferably contains nitric acid [E].

Nitric acid [E] may be added during preparation of the silicon-containing resist underlayer film-forming composition. Alternatively, nitric acid may be used as a hydrolysis catalyst or used for capping of silanol groups with an alcohol in the production of the polysiloxane described above, and may remain in the resultant polysiloxane varnish.

The amount of the nitric acid [E] (amount of residual nitric acid) added may be, for example, 0.0001 mass % to 1 mass %, 0.001 mass % to 0.1 mass %, or 0.005 mass % to 0.05 mass % relative to the total mass of the silicon-containing resist underlayer film-forming composition.

### <Component [F]: Amine and Hydroxide>

The silicon-containing resist underlayer film-forming composition preferably contains at least one selected from amine and hydroxide [F] from the viewpoint of more sufficiently achieving the effects of the present invention.

Examples of the amine include ammonia; primary amines such as monomethanolamine, monoethanolamine, monopropanolamine, methylamine, ethylamine, propylamine, and butylamine; secondary amines such as dimethylamine, ethylmethylamine, and diethylamine; tertiary amines such as trimethylamine, triethylamine, tripropylamine, dimethylethylamine, methyldiisopropylamine, diisopropylethylamine, diethylethanolamine, and triethanolamine; amines such as ethylenediamine and tetramethylethylenediamine; and cyclic amines such as pyridine and morpholine.

Examples of the hydroxide include an inorganic alkali hydroxide and an organic alkali hydroxide.

Examples of the inorganic alkali hydroxide include sodium hydroxide and potassium hydroxide.

Examples of the organic alkali hydroxide include tetraalkylammonium hydroxide, triarylsulfonium hydroxide, and diaryliodonium hydroxide. Examples of the tetraalkylammonium hydroxide include tetramethylammonium hydroxide, tetraethylammonium hydroxide, and tetrabutylammonium hydroxide. Examples of the triarylsulfonium hydroxide include triphenylsulfonium hydroxide and tris(t-butylphenyl) sulfonium hydroxide. Examples of the diaryliodonium hydroxide include diphenyliodonium hydroxide and bis(t-butylphenyl) iodonium hydroxide.

The content of the component [F] in the silicon-containing resist underlayer film-forming composition may be preferably 0.05 to 20 parts by mass, more preferably 0.1 to 15 parts by mass, and still more preferably 0.5 to 10 parts by mass, relative to 100 parts by mass of the polysiloxane [A].

### <Additional Additives>

The silicon-containing resist underlayer film-forming composition may contain various additives depending on the intended use.

Examples of the additives include known additives incorporated in materials (compositions) for forming various films (e.g. resist underlayer film, anti-reflective coating, and pattern reversing film) that can be used in the production of a semiconductor device, such as a crosslinking agent, a crosslinking catalyst, a stabilizer (e.g. an organic acid, water, or an alcohol), an organic polymer, an acid generator, a surfactant (e.g. a nonionic surfactant, an anionic surfactant, a cationic surfactant, a silicon-based surfactant, a fluorine-based surfactant, or an UV-curable surfactant), a pH adjuster, a metal oxide, a rheology controlling agent, and an adhesion aid.

Hereinafter, various additives will be exemplified, but the additives are not limited thereto.

### <<Stabilizer>>

The stabilizer may be added for the purpose of stabilizing the hydrolysis condensate of the hydrolyzable silane mixture, or the like. Specific example of the stabilizer that include an organic acid, water, alcohol, or a combination thereof.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among these organic acids, oxalic acid and maleic acid are preferred. When the organic acid is added, the amount of the organic acid added is 0.1 to 5.0 mass % relative to the mass of the hydrolysis condensate of the hydrolyzable silane mixture. These organic acids may also serve as pH adjusters.

As the water, pure water, ultrapure water, ion exchanged water, or the like may be used. When pure water, ultrapure water, or ion exchanged water is used, the amount of the water added can be 1 to 20 parts by mass relative to 100 parts by mass of the silicon-containing resist underlayer film-forming composition.

The alcohol is preferably an alcohol that is easily scattered by heating after the application, and examples of the alcohol include methanol, ethanol, propanol, i-propanol, and butanol. When an alcohol is added, the amount of the alcohol added may be 1 to 20 parts by mass relative to 100 parts by mass of the silicon-containing resist underlayer film-forming composition.

### <<Organic Polymer>>

Addition of the organic polymer to the silicon-containing resist underlayer film-forming composition enables adjustment of the dry etching rate (the amount of reduction in film thickness per unit time), attenuation coefficient, refractive index, and the like of a film (resist underlayer film) formed from the composition. The organic polymer is not particularly limited, and is appropriately selected from various organic polymers (polycondensation polymer and addition polymerization polymer) depending on the purpose of addition thereof.

Specific examples of the organic polymer include addition polymerization polymers and polycondensation polymers, such as polyester, polystyrene, polyimide, acrylic polymer, methacrylic polymer, polyvinyl ether, phenol novolac, naphthol novolac, polyether, polyamide, and polycarbonate.

In the present invention, an organic polymer having an aromatic or heteroaromatic ring that functions as a light-absorbing moiety (e.g. a benzene ring, a naphthalene ring, an anthracene ring, a triazine ring, a quinoline ring, or a quinoxaline ring) can also be suitably used in the case where such a function is required. Specific examples of such an organic polymer include, but are not limited to, addition polymerization polymers containing, as structural units, addition polymerizable monomers, such as benzyl acrylate, benzyl methacrylate, phenyl acrylate, naphthyl acrylate, anthryl methacrylate, anthryl methyl methacrylate, styrene, hydroxystyrene, benzyl vinyl ether, and N-phenylmaleimide, and condensation polycondensation polymers, such as phenol novolac and naphthol novolac.

When an addition polymerization polymer is used as an organic polymer, the polymer may be either a homopolymer or a copolymer.

An addition polymerizable monomer is used for the production of the addition polymerization polymer. Specific examples of the addition polymerizable monomer include, but are not limited to, acrylic acid, methacrylic acid, an acrylate ester compound, a methacrylate ester compound, an acrylamide compound, a methacrylamide compound, a vinyl compound, a styrene compound, a maleimide compound, maleic anhydride, and acrylonitrile.

Specific examples of the acrylate ester compound include, but are not limited to, methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornane-2-carboxylic-6-lactone, 3-acryloxypropyltriethoxysilane, and glycidyl acrylate.

Specific examples of the methacrylate ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornane-2-carboxylic-6-lactone, 3-methacryloxypropyltriethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylmethacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinyl acetic acid, vinyltrimethoxysilane, 2-chloroethyl vinyl ether, 2-methoxyethyl vinyl ether, vinylnaphthalene, and vinylanthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a polycondensation polymer is used as the polymer, the polymer is, for example, a polycondensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Further, examples of the polymer include, but are not limited to, polyesters, polyamides, and polyimides, such as polypyromellitimide, poly(p-phenyleneterephthalamide), polybutylene terephthalate, and polyethylene terephthalate.

When the organic polymer contains a hydroxy group, the hydroxy group may be crosslinked with a hydrolysis condensate, or the like.

The organic polymer may ordinarily have a weight-average molecular weight of 1,000 to 1,000,000. From the viewpoint of sufficiently achieving the effect of the polymer function and preventing the precipitation of the polymer in the composition, the weight-average molecular weight of the organic polymer to be added may be, for example, 3,000 to 300,000, 5,000 to 300,000, or 10,000 to 200,000.

The organic polymer may be used singly or in combination of two or more kinds thereof.

When the silicon-containing resist underlayer film-forming composition contains an organic polymer, the content of the organic polymer cannot be univocally determined, since the content should be appropriately determined in consideration of the function of the organic polymer or the like. Ordinarily, the content may be 1 to 200 mass % relative to the mass of the polysiloxane [A]. From the viewpoint of preventing the precipitation of the organic polymer in the composition and the like, the content may be, for example, 100 mass % or less, preferably 50 mass % or less, and more preferably 30 mass % or less. From the viewpoint of sufficiently achieving the effect of the polymer and the like, the content may be, for example, 5 mass % or more, preferably 10 mass % or more, more preferably 30 mass % or more.

### <<Acid Generator>>

Examples of the acid generator include a thermal acid generator and a photoacid generator, and a photoacid generator may be preferably used.

Examples of the photoacid generator include, but are not limited to, an onium salt compound, a sulfonimide compound, and a disulfonyldiazomethane compound. The photoacid generator may also function as a curing catalyst depending on the type thereof, for example, a nitrate salt, a carboxylate salt (e.g. maleate), or a hydrochloride salt of an onium salt compound described below.

Examples of the thermal acid generator include, but are not limited to, tetramethylammonium nitrate.

Specific examples of the onium salt compound include, but are not limited to, iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl) iodonium camphorsulfonate, and bis(4-t-butylphenyl) iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Specific examples of the sulfonimide compound include, but are not limited to, N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Specific examples of the disulfonyldiazomethane compound include, but are not limited to, bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

When the silicon-containing resist underlayer film-forming composition contains an acid generator, the content of the acid generator cannot be univocally determined, since the amount should be appropriately determined in consideration of the type of the acid generator and the like. Ordinarily, the content of the acid generator is 0.01 to 5 mass % relative to the mass of the polysiloxane [A]. From the viewpoint of preventing the precipitation of the acid generator in the composition and the like, the content is preferably 3 mass % or less, more preferably 1 mass % or less. From the viewpoint of sufficiently achieving the effect of the acid generator and the like, the content is preferably 0.1 mass % or more, more preferably 0.5 mass % or more.

The acid generators may be used singly or in combination of two or more kinds thereof. A photoacid generator and a thermal acid generator may be used in combination.

### <<Surfactant>>

When the silicon-containing resist underlayer film-forming composition is applied to a substrate, a surfactant is effective in prevention of formation of pinholes, striations, and the like. Examples of the surfactant include a nonionic surfactant, an anionic surfactant, a cationic surfactant, a silicon-based surfactant, a fluorine-based surfactant, and a UV-curable surfactant. Specific examples of the surfactant include, but are not limited to, nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylaryl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants, such as trade names EFTOP (registered trademark) EF301, EF303, and EF352 (manufactured by Mitsubishi Materials Electronic Chemicals Co., Ltd. (former Tohkem Products Corporation)), trade names MEGAFACE (registered trademark) F171, F173, R-08, R-30, R-30N, and R-40 LM (manufactured by DIC Corporation), Fluorad FC430 and FC431 (manufactured by 3 M Japan Limited), trade name Asahi Guard (registered trademark) AG710 (manufactured by AGC Inc.), and trade names SURFLON (registered trademark) S-382, SC101, SC102, SC103, SC104, SC105, and SC106 (manufactured by AGC Seimi Chemical Co., Ltd.); and Organosiloxane Polymer KP341 (manufactured by Shin-Etsu Chemical Co., Ltd.).

The surfactants may be used singly or in combination of two or more kinds thereof.

When the silicon-containing resist underlayer film-forming composition contains a surfactant, the content of the surfactant is ordinarily 0.0001 to 5 mass %, preferably 0.001 to 4 mass %, and more preferably 0.01 to 3 mass % relative to the mass of the polysiloxane [A].

### <<Rheology Controlling Agent>>

The rheology controlling agent is added mainly for the purpose of improving the fluidity of the silicon-containing resist underlayer film-forming composition, particularly in a baking process, improving the uniformity of the thickness of a film to be formed, or improving the fillability of the composition into holes. Specific examples of the rheology controlling agent include phthalic acid derivatives, such as dimethyl phthalate, diethyl phthalate, di-i-butyl phthalate, dihexyl phthalate, and butyl-1-decyl phthalate; adipic acid derivatives, such as di-normal butyl adipate, di-i-butyl adipate, di-i-octyl adipate, and octyl decyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate.

When such a rheology controlling agent is used, the amount of the rheology controlling agent added is ordinarily less than 30 mass % relative to all film-forming components of the silicon-containing resist underlayer film-forming composition.

### <<Adhesion Aid>>

The adhesion aid is added for the purpose of mainly improving the adhesion between a substrate or a resist and a film (resist underlayer film) formed from the silicon-containing resist underlayer film-forming composition, in particular, suppressing or preventing the peeling of the resist during development. Specific examples of the adhesion aid include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, and dimethylvinylethoxysilane; silazanes, such as hexamethyldisilazane, N,N′-bis(trimethylsilyl) urea, dimethyltrimethylsilylamine, and trimethylsilyl imidazole; other silanes, such as γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, mercaptopyrimidine; and urea or thiourea compounds, such as 1,1-dimethylurea and 1,3-dimethylurea.

When such an adhesion aid is used, the amount of the adhesion aid added is ordinarily less than 5 mass, preferably less than 2 mass %, relative to the film-forming components of the silicon-containing resist underlayer film-forming composition.

### <<pH Adjuster>>

In addition, the pH adjuster may be an acid having one or two or more carboxylic acid groups, for example, an organic acid described above in <<Stabilizer>>. When a pH adjuster is used, the amount of the pH adjuster added may be 0.01 to 20 parts by mass, 0.01 to 10 parts by mass, or 0.01 to 5 parts by mass relative to 100 parts by mass of the polysiloxane [A].

### <<Metal Oxide>>

Examples of the metal oxide that may be added to the silicon-containing resist underlayer film-forming composition include, but are not limited to, oxides of a combination of one or more selected from among metals, such as tin (Sn), titanium (Ti), aluminum (Al), zirconium (Zr), zinc (Zn), niobium (Nb), tantalum (Ta), and W (tungsten), and semimetals, such as boron (B), silicon (Si), germanium (Ge), arsenic (As), antimony (Sb), and tellurium (Te).

The concentration of the film-forming component in the silicon-containing resist underlayer film-forming composition may be, for example, 0.1 to 50 mass %, 0.1 to 30 mass %, 0.1 to 25 mass %, or 0.5 to 20.0 mass % relative to the total mass of the composition.

The content of the polysiloxane [A] in the film-forming component is ordinarily 20 mass % to 100 mass %. From the viewpoint of achieving the effects of the present invention at high reproducibility or the like, the lower limit of the content of the polysiloxane [A] is preferably 50 mass %, more preferably 60 mass %, still more preferably 70 mass %, and yet still more preferably 80 mass %. The upper limit of the content is preferably 99 mass %. The balance may be an additive described below.

Further, the silicon-containing resist underlayer film-forming composition preferably has a pH of 2 to 5, more preferably a pH of 3 to 4.

The silicon-containing resist underlayer film-forming composition can be produced by mixing the polysiloxane [A], the aromatic iodine compound [B], the solvent [C], and, if desired, an additional component. In this case, a solution containing the polysiloxane [A] may be prepared in advance, and this solution may be mixed with the aromatic iodine compound [B], the solvent [C], and an additional component.

The order of mixing these components is not particularly limited. For example, the aromatic iodine compound [B] and the solvent [C] may be added to and mixed with a solution containing the polysiloxane [A], and an additional component may be added to the resultant mixture. Alternatively, a solution containing the polysiloxane [A], the aromatic iodine compound [B], the solvent [C], and an additional component may be mixed simultaneously.

If necessary, the solvent [C] may be finally added, or some components that can be relatively easily dissolved in the solvent [C] may be finally added without being incorporated into the mixture. However, from the viewpoint of preventing aggregation or separation of the components to prepare a highly homogeneous composition with high reproducibility, the composition is preferably produced from a previously prepared solution containing the well-dissolved polysiloxane [A]. It should be noted that the polysiloxane [A] may be aggregated or precipitated when mixed with the aromatic iodine compound [B], the solvent [C], or an additional component, depending on, for example, the type or amount of the aromatic iodine compound [B], the solvent [C], or the amount or nature of the additional component. Further, it should be noted that when a composition is prepared from a solution containing the polysiloxane [A], the concentration of the solution of the polysiloxane [A] or the amount of the solution used must be determined to achieve a desired amount of the polysiloxane [A] contained in the finally produced composition.

During preparation of the composition, the composition may be appropriately heated so long as the components are not decomposed or denatured.

In the present invention, the silicon-containing resist underlayer film-forming composition may be filtered with a submicrometer-order filter or the like during production of the composition or after mixing of all the components. The type of the material of the filter used is not limited. For example, a nylon-made filter or a fluororesin-made filter may be used.

The silicon-containing resist underlayer film-forming composition of the present invention may be suitably used as a composition for forming a resist underlayer film used in a lithography process.

The silicon-containing resist underlayer film-forming composition of the present invention may be suitably used as a composition for forming a resist underlayer film used in an EUV or ArF lithography process.

### (Silicon-Containing Resist Underlayer Film, Laminate, Method for Forming Pattern, and Method for Producing Semiconductor Element)

The silicon-containing resist underlayer film of the present invention is a cured product of the silicon-containing resist underlayer film-forming composition of the present invention.

The laminate of the present invention includes, for example, a semiconductor substrate and the silicon-containing resist underlayer film of the present invention.

The method for producing a semiconductor element of the present invention includes, for example, the steps of:
forming an organic underlayer film on a substrate;
forming a silicon-containing resist underlayer film on the organic underlayer film using the silicon-containing resist underlayer film-forming composition of the present invention; and
forming a resist film on the silicon-containing resist underlayer film.

The method for forming a pattern of the present invention includes, for example, the steps of:
forming an organic underlayer film on a semiconductor substrate;
applying the silicon-containing resist underlayer film-forming composition of the present invention on the organic underlayer film and baking to form a silicon-containing resist underlayer film;
forming a resist film on the silicon-containing resist underlayer film;
exposing and developing the resist film to obtain a resist pattern;
etching the silicon-containing resist underlayer film using the resist pattern as a mask; and
etching the organic underlayer film using the patterned silicon-containing resist underlayer film as a mask.

Hereinafter, as one aspect of the present invention, a laminate, a method for forming a pattern, and a method for producing a semiconductor element using the silicon-containing resist underlayer film of the present invention or the silicon-containing resist underlayer film-forming composition of the present invention will be described.

First, the silicon-containing resist underlayer film-forming composition of the present invention is applied onto a substrate used for the production of a precise integrated circuit element [e.g. a semiconductor substrate such as a silicon wafer coated with a silicon oxide film, a silicon nitride film, or a silicon oxynitride film, a silicon nitride substrate, a quartz substrate, a glass substrate (including alkali-free glass, low alkali glass, or crystallized glass), a glass substrate coated with an ITO (indium tin oxide) film or an IZO (indium zinc oxide) film, a plastic (e.g. polyimide or PET) substrate, a substrate coated with a low dielectric constant material (low-k material), or a flexible substrate] by an appropriate application method with, for example, a spinner or a coater. Thereafter, the composition is cured through baking by heating means (e.g. a hot plate) to form a resist underlayer film. Hereinafter, the term “silicon-containing resist underlayer film” used herein refers to a film formed from the silicon-containing resist underlayer film-forming composition of the present invention.

The baking conditions are appropriately selected from a baking temperature of 40° C. to 400° C., or 80° C. to 250° C., and a baking time of 0.3 minutes to 60 minutes. Preferably, the baking temperature is 150° C. to 250° C., and the baking time is 0.5 minutes to 2 minutes.

The resist underlayer film formed here has a thickness of, for example, 10 nm to 1,000 nm, or 20 nm to 500 nm, or 50 nm to 300 nm, or 100 nm to 200 nm, or 10 to 150 nm.

As the silicon-containing resist underlayer film-forming composition used for formation of the resist underlayer film, the silicon-containing resist underlayer film-forming composition filtered through a nylon filter may be used. Here, the term “silicon-containing resist underlayer film-forming composition filtered through a nylon filter” refers to a composition that has been subjected to filtration with a nylon filter during production of the silicon-containing resist underlayer film-forming composition or after mixing all the components.

In one aspect of the present invention, the resist underlayer film is formed on the substrate, and then the silicon-containing resist underlayer film is formed on the organic underlayer film. In some cases, an aspect may be employed in which the organic underlayer film is not provided.

The organic underlayer film used here is not particularly limited, and may be arbitrarily selected from organic underlayer films commonly used in the lithography process.

In one aspect, the organic underlayer film is formed on the substrate, and the silicon-containing resist underlayer film is formed on the organic underlayer film, followed by formation of a resist film as described below on the silicon-containing resist underlayer film. This can narrow the pattern width of a photoresist film. Thus, even when the photoresist film is formed thinly for preventing pattern collapse, the substrate can be processed through selection of an appropriate etching gas described below. For example, the silicon-containing resist underlayer film can be processed by using, as an etching gas, a fluorine-containing gas that achieves a sufficiently high etching rate for the photoresist film. Further, the organic underlayer film can be processed by using, as an etching gas, an oxygen-containing gas that achieves a sufficiently high etching rate for the silicon-containing resist underlayer film. Further, the substrate can be processed by using, as an etching gas, a fluorine-containing gas that achieves a sufficiently high etching rate for the organic underlayer film.

The substrate and application method usable in this process are the same as those described above.

Subsequently, for example, a layer (resist film) of a photoresist material is formed on the silicon-containing resist underlayer film. The resist film can be formed by a well-known method. For example, the silicon-containing resist underlayer film can be formed by applying a coating-type resist material (e.g. a composition for forming a resist film) onto the silicon-containing resist underlayer film, and baking the resist material.

The resist film has a film thickness of, for example, 10 nm to 10,000 nm, or 100 nm to 2,000 nm, or 200 nm to 1,000 nm, or 30 nm to 200 nm.

The photoresist material used for the resist film formed on the silicon-containing resist underlayer film is not particularly limited as long as it is sensitive to light used for exposure (e.g. a KrF excimer laser or an ArF excimer laser), and both a negative photoresist material and a positive photoresist material can be used. Examples of the photoresist include a positive photoresist material formed of a novolac resin and 1,2-naphthoquinone diazide sulfonic acid ester; a chemically amplified photoresist material formed of a binder having a group that is decomposed by an acid to increase an alkali dissolution rate and a photoacid generator; a chemically amplified photoresist material formed of a low molecular weight compound that is decomposed by an acid to increase an alkali dissolution rate of the photoresist material, an alkali-soluble binder, and a photoacid generator; a chemically amplified photoresist material formed of a binder having a group that is decomposed by an acid to increase an alkali dissolution rate, a low molecular weight compound having a group that is decomposed by an acid to increase an alkali dissolution rate of the photoresist material, and photoacid generator.

Specific examples of commercially available products thereof include, but are not limited to, APEX-E (trade name, manufactured by Shipley Company L.L.C), PAR710 (trade name, manufactured by Sumitomo Chemical Co., Ltd.), AR2772JN (trade name, manufactured by JSR Corporation), and SEPR430 (trade name, manufactured by Shin-Etsu Chemical Co., Ltd.). Further, examples of the photoresist include a fluorine-containing atomic polymer-based photoresist material as described in Proc. SPIE, Vol. 3999, 330-334 (2000), Proc. SPIE, Vol. 3999, 357-364 (2000), or Proc. SPIE, Vol. 3999, 365-374 (2000).

As the resist film formed on the silicon-containing resist underlayer film, a resist film for electron beam lithography (also referred to as an electron beam resist film) or a resist film for EUV lithography (also referred to as an EUV resist film) can be used instead of the photoresist film.

As the electron beam resist material for forming the electron beam resist film, both a negative type material and a positive type material can be used. Specific examples of the negative type material and the positive type material include: a chemically amplified resist material containing an acid generator and a binder having a group that is decomposed by an acid to change the alkali dissolution rate; a chemically amplified resist material containing an alkali-soluble binder, an acid generator, and a low molecular weight compound that is decomposed by an acid to change the alkali dissolution rate of the resist material; a chemically amplified resist material containing an acid generator, a binder having a group that is decomposed by an acid to change the alkali dissolution rate, and a low molecular weight compound that is decomposed by an acid to change the alkali dissolution rate of the resist material; a non-chemically amplified resist material containing a binder having a group that is decomposed by an electron beam to change the alkali dissolution rate; and a non-chemically amplified resist material containing a binder having a moiety that is cleaved by an electron beam to change the alkali dissolution rate. Even when these electron beam resist materials are used, a resist film pattern can be formed similarly to a case in which a photoresist material is used with an electron beam being used as an irradiation source.

As the EUV resist material for forming the EUV resist film, a methacrylate resin-based resist material can be used.

The resist material may be a metal-containing resist.

The metal-containing resist is also called a metal oxide resist (metal oxide resist (MOR)), and typical examples thereof include a tin oxide-based resist.

The material of the metal oxide resist is, for example, a coating composition containing a metal oxo-hydroxo network having an organic ligand through a metal carbon bond and/or a metal carboxylate bond described in JP 2019-113855 A.

In an example of the metal-containing resist, a peroxo ligand is used as a radiation-sensitive stabilizing ligand. Details of the peroxo based metal oxo-hydroxo compounds are described, for example, in paragraph of JP 2019-532489 A: Patent Literature. Examples of the Patent Literature include U.S. Pat. No. 9,176,377 B2, US 2013/0224652 A1, U.S. Pat. No. 9,310,684 B2, US 2016/0116839 A1, and U.S. Ser. No. 15/291,738 A.

Subsequently, light exposure is performed on the resist film formed above the silicon-containing resist underlayer film through a predetermined mask (reticle). The light exposure may be performed using a KrF excimer laser (wavelength: 248 nm), an ArF excimer laser (wavelength: 193 nm), an F₂ excimer laser (wavelength: 157 nm), EUV (wavelength: 13.5 nm), electron beams, or the like.

After the light exposure, post exposure bake may be performed as necessary. The post exposure bake is performed under appropriately selected conditions: a heating temperature of 70° C. to 150° C. and a heating time of 0.3 minutes to 10 minutes.

Next, development is performed with a developer (e.g. an alkaline developer). When, for example, a positive photoresist film is used, an exposed portion of the photoresist film is removed, and thus a pattern of the photoresist film is formed.

Examples of the developer (alkaline developer) include alkaline aqueous solutions (alkaline developers) such as: aqueous solutions of alkali metal hydroxides such as potassium hydroxide and sodium hydroxide; aqueous solutions of quaternary ammonium hydroxides such as tetramethylammonium hydroxide, tetraethylammonium hydroxide, and choline; and aqueous amine solutions such as ethanolamine, propylamine, and ethylenediamine. Furthermore, a surfactant or the like may be added to these developers. Development conditions are appropriately selected from a temperature of 5 to 50° C., and a time of 10 seconds to 600 seconds.

In the present invention, an organic solvent can be used as a developer. Development is performed with a developer (solvent) after light exposure. When, for example, a negative photoresist film is used, an unexposed portion of the photoresist film is removed, and thus a pattern of the photoresist film is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3 methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3 ethoxypropionate, and propyl-3-methoxypropionate. Furthermore, a surfactant or the like may be added to these developers. Development conditions are appropriately selected from a temperature of 5° C. to 50° C., and a time of 10 seconds to 600 seconds.

The resultant patterned photoresist film (upper layer) is used as a protective film to remove the silicon-containing resist underlayer film (intermediate layer). Then, a film including the patterned photoresist film and the patterned silicon-containing resist underlayer film (intermediate layer) is used as a protective film to remove the organic underlayer film (lower layer). Finally, the substrate is processed using the patterned silicon-containing resist underlayer film (intermediate layer) and the patterned organic underlayer film (lower layer) as protective films.

The silicon-containing resist underlayer film (intermediate layer) is removed (patterned) through dry etching by using the patterned resist film (upper layer) as a protective film. The dry etching can be performed using any of gases, such as tetrafluoromethane (CF₄), perfluorocyclobutane (C₄F8), perfluoropropane (C₃F8), trifluoromethane, carbon monoxide, argon, oxygen, nitrogen, sulfur hexafluoride, difluoromethane, nitrogen trifluoride, chlorine trifluoride, chlorine, trichloroborane, and dichloroborane.

The dry etching of the silicon-containing resist underlayer film is preferably performed using a halogen-containing gas. The resist film (photoresist film) made of an organic material is basically less likely to be removed by dry etching with a halogen-containing gas. In contrast, the silicon-containing resist underlayer film containing numerous silicon atoms is quickly removed by a halogen-containing gas. Accordingly, a reduction in the film thickness of the photoresist film in associated with the dry etching of the silicon-containing resist underlayer film can be suppressed. As a result, the photoresist film can be used in the form of thin film. Thus, the dry etching of the resist underlayer film is preferably performed using a fluorine-containing gas. Examples of the fluorine-containing gas include, but are not limited to, tetrafluoromethane (CF₄), perfluorocyclobutane (C₄F₈), perfluoropropane (C₃F8), trifluoromethane, and difluoromethane (CH₂F2), thereto.

When the organic underlayer film is present between the substrate and the silicon-containing resist underlayer film, a film including the patterned resist film (upper layer) (if remains) and the patterned silicon-containing resist underlayer film (intermediate layer) is used as a protective film to remove (pattern) the organic underlayer film (lower layer). The organic underlayer film (lower layer) is preferably removed (patterned) by dry etching with an oxygen-containing gas (e.g. oxygen gas or oxygen/carbonyl sulfide (COS) mixed gas). This is because the silicon-containing resist underlayer film of the present invention, which contains numerous silicon atoms, is less likely to be removed by dry etching with an oxygen-containing gas.

Thereafter, the patterned silicon-containing resist underlayer film (intermediate layer) and, if desired, the patterned organic underlayer film (lower layer) are used as protective films to process (pattern) the (semiconductor) substrate. The (semiconductor) substrate is preferably processed (patterned) by dry etching with a fluorine-containing gas.

Examples of the fluorine-containing gas include tetrafluoromethane (CF₄), perfluorocyclobutane (C₄F₈), perfluoropropane (C₃F₈), trifluoromethane, and difluoromethane (CH₂F₂).

After the removal (patterning) of the organic underlayer film or after the processing (patterning) of the substrate, the resist underlayer film may be removed. The silicon-containing resist underlayer film may be removed by dry etching or wet etching.

The dry etching of the silicon-containing resist underlayer film is preferably performed with a fluorine-containing gas as described in the patterning. Examples of the fluorine-containing gas include, but are not limited to, tetrafluoromethane (CF₄), perfluorocyclobutane (C₄F₈), perfluoropropane (C₃F₈), trifluoromethane, and difluoromethane (CH₂F₂).

Examples of the chemical solution used for wet etching of the silicon-containing resist underlayer film include alkaline solutions, such as dilute hydrofluoric acid (hydrofluoric acid), buffered hydrofluoric acid (mixed solution of HF and NH₄F), an aqueous solution containing hydrochloric acid and hydrogen peroxide (SC-2 chemical solution), an aqueous solution containing sulfuric acid and hydrogen peroxide (SPM chemical solution), an aqueous solution containing hydrofluoric acid and hydrogen peroxide (FPM chemical), and an aqueous solution containing ammonia and hydrogen peroxide (SC-1 chemical solution). Further, examples of the alkaline solution include an aqueous solution containing 1 to 99 mass % of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, a hydrazine compound, an ethylenediamine compound, or guanidine, in addition to the ammonia-hydrogen peroxide mixture prepared by mixing ammonia, hydrogen peroxide water, and water described above (SC-1 chemical solution). These chemical solutions may be used in the form of mixture.

An organic anti-reflective coating may be formed on the silicon-containing resist underlayer film before formation of the resist film. The composition used for formation of the anti-reflective coating is not particularly limited, and for example, the composition may be appropriately selected from anti-reflective coating compositions commonly used in a lithography process. The anti-reflective coating can be formed by a commonly used method, for example, application of the composition with a spinner or a coater, and baking of the composition.

In addition, the substrate to which the silicon-containing resist underlayer film-forming composition is applied may have an organic or inorganic anti-reflective coating formed thereon by, for example, a CVD process. The silicon-containing resist underlayer film may be formed on the anti-reflective coating. Even in a case where the silicon-containing resist underlayer film of the present invention is formed on the organic underlayer film formed on the substrate, the substrate used may have an organic or inorganic anti-reflective coating formed thereon by, for example, a CVD process.

The silicon-containing resist underlayer film formed from the silicon-containing resist underlayer film-forming composition may absorb light used in a lithography process depending on the wavelength of the light. In such a case, the resist underlayer film can function as an anti-reflective coating having the effect of preventing reflection of light from the substrate.

Furthermore, the silicon-containing resist underlayer film can be used as, for example, a layer for preventing the interaction between the substrate and the resist film (such as a photoresist film); a layer having the function of preventing the adverse effect, on the substrate, of a material used for the resist film or a substance generated during the exposure of the resist film to light; a layer having the function of preventing diffusion of a substance generated from the substrate during heating and baking to the resist film; and a barrier layer for reducing a poisoning effect of a dielectric layer of the semiconductor substrate on the resist film.

The silicon-containing resist underlayer film can be applied to a substrate having via holes for use in a dual damascene process, and can be used as a hole filling material (embedding material) to fill up the holes. The resist underlayer film can also be used as a planarization material for planarizing the surface of a semiconductor substrate having irregularities.

The silicon-containing resist underlayer film of the present invention functions as an underlayer of EUV resist film or a hard mask. In addition, the resist underlayer film is capable of, without intermixing with the EUV resist film, preventing the reflection, from a substrate or an interface, of exposure light undesirable for EUV exposure (wavelength: 13.5 nm), such as UV (ultraviolet) light or DUV (deep ultraviolet) light (ArF light, KrF light). Therefore, the silicon-containing resist underlayer film-forming composition of the present invention can be suitably used to form an anti-reflective underlayer coating of EUV resist film. Thus, the resist underlayer film can efficiently prevent the light reflection as the underlayer film of the EUV resist film. When the resist underlayer film is used as an EUV resist underlayer film, the film can be processed in a similar manner to the photoresist underlayer film.

A semiconductor substrate can be suitably processed by using a laminate including the above-described silicon-containing resist underlayer film of the present invention and a semiconductor substrate.

In addition, a semiconductor substrate can be precisely processed at high reproducibility by the above-described semiconductor element production method including the steps of: forming an organic underlayer film; forming a silicon-containing resist underlayer film on the organic underlayer film using the silicon-containing resist underlayer film-forming composition of the present invention; and forming a resist film on the silicon-containing resist underlayer film. Thus, it is expected that the method can stably produce a semiconductor element.

### EXAMPLES

Hereinafter, the present invention will be described more specifically with reference to Synthesis Examples and Examples, but the present invention is not limited to only the following Examples.

In the Examples, apparatuses and conditions used for analysis of the physical properties of samples are as follows.

### (1) Measurement of Molecular Weight

The molecular weight of the polysiloxane used in the present invention is determined by GPC analysis in terms of polystyrene.

The GPC analysis can be performed, for example, under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (manufactured by Showa Denko K. K.) as a standard sample.

### (2) ¹H-NMR

The evaluation was performed using a nuclear magnetic resonance apparatus ¹H-NMR (400 MHZ), manufactured by JEOL Ltd., and d6-Acetone as a solvent.

### [1] Synthesis of Polymer (Hydrolysis Condensate)

### Synthesis Example 1

A 300 ml flask was charged with 20.8 g of tetraethoxysilane, 5.1 g of methyltriethoxysilane, 2.8 g of phenyltrimethoxysilane, and 53.4 g of propylene glycol monoethyl ether. While the resultant mixed solution was stirred with a magnetic stirrer, 8.4 g of 0.2 M aqueous nitric acid solution was added dropwise to the mixed solution.

After the dropwise addition, the flask was transferred to an oil bath set at 60° C. and the mixed solution was refluxed for 20 hours. Thereafter, ethanol, methanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E1), and to have a weight-average molecular weight Mw of 2,700 as determined by GPC in terms of polystyrene.

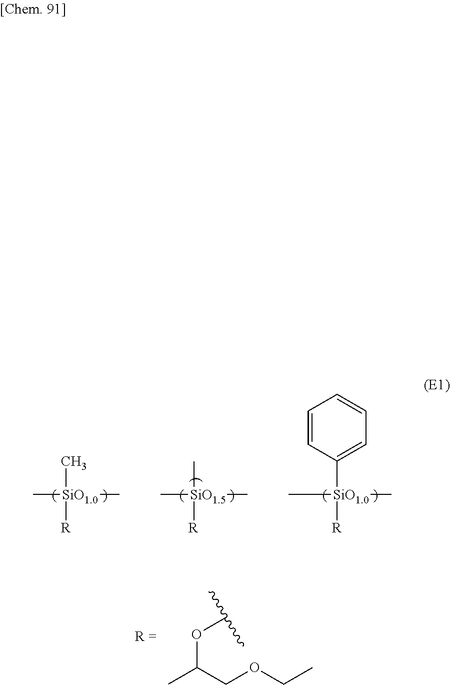

### [2] Preparation of Resist Underlayer Film-Forming Composition

The polysiloxane (polymer) produced in each of the Synthesis Examples describe above, an acid (additive 1), a curing catalyst (additive 2), an aromatic iodine compound (additive 3), and a solvent were mixed in proportions shown in Table 1. The resultant mixture was filtered through a 0.1 μm fluororesin filter, and thus each resist underlayer film-forming composition is prepared. In Table 1, the amount of each component added is shown by part(s) by mass.

Although the composition was prepared from the solution containing the hydrolysis condensate (polymer) produced in each Synthesis Example, the amount of each polymer shown in Table 1 corresponds not to the amount of the polymer solution, but to the amount of the polymer itself.

In Table 1, the meanings of abbreviations are shown below.

### <Solvent>

DIW: ultrapure water
PGEE: propylene glycol monoethyl ether
PGME: propylene glycol monomethyl ether

### <Additive 1 (Stabilizer)>

MA: maleic acid

### <Additive 2 (Curing Catalyst)>

TPSNO3: triphenylsulfonium nitrate

### <Additive 3>

2,4,6-TIP: 2,4,6-triiodophenol
2-IBA: 2-iodobenzoic acid
2,3,5-TIBA: 2,3,5-triiodobenzoic acid
3,5-DISA: 3,5-diiodosalicylic acid
DPINO3: diphenyl iodonium nitrate

TABLE 1

| | Polymer | Additive 1 | Additive 2 | Additive 3 | Solvent | | |
|---|---|---|---|---|---|---|---|
| Example 1 | Synthesis | MA | TPSN03 | 2,4,6-TIP | PGEE | PGME | DIW |
| | Example 1 | | | | | | |
| (parts by | 1.72 | 0.02 | 0.02 | 0.08 | 80 | 8 | 12 |
| mass) | | | | | | | |
| Example 2 | Synthesis | MA | TPSN03 | 2-IBA | PGEE | PGME | DIW |
| | Example 1 | | | | | | |
| (parts by | 1.72 | 0.02 | 0.02 | 0.08 | 80 | 8 | 12 |
| mass) | | | | | | | |
| Example 3 | Synthesis | MA | TPSN03 | 2,3,5-TIBA | PGEE | PGME | DIW |
| | Example 1 | | | | | | |
| (parts by | 1.72 | 0.02 | 0.02 | 0.08 | 80 | 8 | 12 |
| mass) | | | | | | | |
| Example 4 | Synthesis | MA | TPSN03 | 3,5-DISA | PGEE | PGME | DIW |
| | Example 1 | | | | | | |
| (parts by | 1.72 | 0.02 | 0.02 | 0.08 | 80 | 8 | 12 |
| mass) | | | | | | | |
| Example 5 | Synthesis | MA | TPSN03 | DPINO3 | PGEE | PGME | DIW |
| | Example 1 | | | | | | |
| (parts by | 1.72 | 0.02 | 0.02 | 0.08 | 80 | 8 | 12 |
| mass) | | | | | | | |
| Comparative | Synthesis | MA | TPSN03 | | PGEE | PGME | DIW |
| Example 1 | Example 1 | | | | | | |
| (parts by | 1.72 | 0.02 | 0.02 | | 80 | 8 | 12 |
| mass) | | | | | | | |

* Examples 1 to 5 and Comparative Example 1 further contain nitric acid contained in the polymer solution prepared in each Synthesis Example.

### [3] Preparation of Composition for Forming Organic Underlayer Film

In a nitrogen atmosphere, a 100-mL four-necked flask was charged with 6.69 g (0.040 mol) of carbazole (manufactured by Tokyo Chemical Industry Co., Ltd.), 7.28 g (0.040 mol) of 9-fluorenone (manufactured by Tokyo Chemical Industry Co., Ltd.), and 0.76 g (0.0040 mol) of p-toluenesulfonic acid monohydrate (manufactured by Tokyo Chemical Industry Co., Ltd.), and then 6.69 g of 1,4-dioxane (manufactured by Kanto Chemical Co., Inc.) was added to the flask. The resultant mixture was stirred and then heated to 100° C. for dissolution, and thus polymerization was initiated. After 24 hours, the mixture was allowed to cool to 60° C.

The cooled reaction mixture was diluted with 34 g of chloroform (manufactured by Kanto Chemical Co., Inc.), and the diluted mixture was added to 168 g of methanol (manufactured by Kanto Chemical Co., Inc.) for precipitation.

The resultant precipitate was subjected to filtration and recovery, and the recovered solid was dried with a reduced-pressure dryer at 80° C. for 24 hours to obtain 9.37 g of a desired polymer represented by Formula (X) (hereinafter, abbreviated as PCzFL).

The results of ¹H-NMR measurement of PCzFL were as follows.

¹H-NMR (400 MHZ, DMSO-d₆): δ 7.03-7.55 (br, 12H), δ 7.61-8.10 (br, 4H), δ 11.18 (br, 1H)

Further, PCzFL was found to have a weight-average molecular weight (Mw) of 2,800 as determined by GPC in terms of polystyrene and a polydispersity Mw/Mn of 1.77.

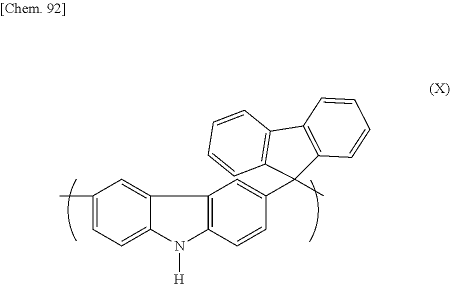

20 g of PCzFL was mixed with 3.0 g of tetramethoxymethyl glycoluril (trade name: Powderlink 1174, manufactured by Cytec Industries Japan LLC. (former Mitsui Cytec Ltd.)) as a crosslinking agent, 0.30 g of pyridinium p-toluenesulfonate as a catalyst, and 0.06 g of MEGAFACE R-30 (trade name, manufactured by DIC Corporation) as a surfactant, and the resultant mixture was dissolved in 88 g of propylene glycol monomethyl ether acetate to prepare a solution. Thereafter, the resultant solution was filtered with a polyethylene microfilter having a pore size of 0.10 μm, and the filtered solution was further filtered with a polyethylene microfilter having a pore size of 0.05 μm to prepare a composition for forming an organic underlayer film.

### [4] Test for Solvent Resistance

Each of the compositions prepared in Examples 1 to 5 and Comparative Example 1 was applied onto a silicon wafer with a spinner. Then, the resultant wafer was heated on a hot plate at 215° C. for one minute to form a Si-containing resist underlayer film. The film thickness of the Si-containing resist underlayer film was measured. The film thickness was approximately 42 nm.

Thereafter, a mixed solvent of propylene glycol monomethyl ether/propylene glycol monomethyl ether acetate (7/3 (V/V)) was applied onto the Si-containing resist underlayer film, and then spin-dried. The film thickness of the underlayer was measured after application of the solvent, thereby evaluating the change (%) in film thickness between before application of the mixed solvent as a reference (100%) and after application of the mixed solvent. Solvent resistance was evaluated as “Good” when a film had a film thickness change of 1% or less before and after application of the mixed solvent, whereas solvent resistance was evaluated as “Not cured” when a film had a film thickness change of more than 1%.

The obtained results are shown in Table 2.

TABLE 2

| | Solvent |
|---|---|
| | resistance |
| Example 1 | Good |
| Example 2 | Good |
| Example 3 | Good |
| Example 4 | Good |
| Example 5 | Good |
| Comparative Example 1 | Good |

### [5] Optical Constant Measurement

The compositions prepared in Examples 1 to 5 and Comparative Example 1 were applied onto silicon wafers with a spinner. The resultant wafers were heated on a hot plate at 215° C. for one minute to form Si-containing resist underlayer films. Then, the refractive indexes (n value) and the optical absorption coefficients (also referred to as k value or “attenuation coefficient) at wavelengths of 193 nm of these Si-containing resist underlayer films were measured using a spectroscopic ellipsometer (VUV-VASE VU-302, manufactured by J.A. Woollam Co.).

The obtained results are shown in Table 3.

TABLE 3

| | n value | k value |
|---|---|---|
| Example 1 | 1.62 | 0.14 |
| Example 2 | 1.63 | 0.14 |
| Example 3 | 1.64 | 0.14 |
| Example 4 | 1.63 | 0.14 |
| Example 5 | 1.63 | 0.14 |
| Comparative Example 1 | 1.62 | 0.14 |

### [6] Measurement of Dry Etching Rate

An etcher: LAM2300 (manufactured by LAM RESEARCH CORPORATION) was used for measuring the dry etching rate, and CF₄ was used as an etching gas. The compositions prepared in Examples 1 to 5 and Comparative Example 1 were applied onto silicon wafers with a spinner. The resultant wafers were heated on a hot plate at 215° C. for one minute to form Si-containing resist underlayer films. Dry etching was performed for 15 seconds using the etching gas CF₄, and the etching rate was measured from the film thickness before and after the treatment. The obtained results are shown in Table 4.

TABLE 4

| | CF₄ etching rate (nm/s) |
|---|---|
| Example 1 | 0.8 |
| Example 2 | 0.8 |
| Example 3 | 0.9 |
| Example 4 | 0.9 |
| Example 5 | 0.9 |
| Comparative Example 1 | 0.8 |

### [7-1] Formation of Resist Pattern by ArF Exposure

The composition for forming an organic underlayer film was spin-coated on a silicon wafer, and heated on a hot plate at 215° C. for 1 minute to form an organic underlayer film (layer A) (film thickness: 90 nm). The composition prepared in Example 1 was spin-coated on the organic underlayer film, and then heated on a hot plate at 215° C. for 1 minute to form a Si-containing resist underlayer film (B layer (film thickness: 42 nm)). Further, an ArF resist solution (AR2772JN) was spin-coated thereon, and heated at 110° C. for 90 seconds to form an ArF resist layer (C layer, film thickness 100 nm). Thereafter, a scanner: NSR-S307E, manufactured by Nikon Corporation (wavelength 193 nm, NA, σ: 0.85, 0.93/0.85) was used to expose each of the films through a mask designed such that the line width and the width between the lines of the photoresist after the development were 65 nm, i.e. a 65 nm dense line with a line and space (L/S)=1/1 was formed. Thereafter, each of the films was heated on a hot plate at 110° C. for 90 seconds, cooled, and then developed for 60 seconds using a 2.38% alkaline aqueous solution to form a positive resist pattern on the Si-containing resist underlayer film (B layer).

A length measuring SEM (CG4100), manufactured by Hitachi High-Technologies Corporation, was used to measure the amount of light exposure formed with a line dimension of 65 nm. The measured amount of light exposure was used as sensitivity. Further, the line width of 147 lines was measured to determine pattern dimension (critical dimension: CD) and line width roughness (LWR). The results are shown in Table 5.

### [7-2] Transfer of Pattern to Si-Containing Resist Underlayer Film (B Layer) by Dry Etching

Next, the resist pattern was used as a mask, and the Si-containing resist underlayer film was dry-etched (LAM2300 (manufactured by LAM RESEARCH CORPORATION), etching gas: CF₄, etching time: 60 seconds) to transfer the resist pattern to the Si-containing resist underlayer film (B layer). The length measuring SEM (CG4100), manufactured by Hitachi High-Technologies Corporation, was used to measure the L/S pattern after transfer. The line width of 147 lines was measured to determine pattern dimension (critical dimension: CD) and line width roughness (LWR). The results are shown in Table 5.

TABLE 5

| | | | | [7-2] | |
|---|---|---|---|---|---|
| | | [7-1] | | Pattern of Si- | |
| | | Pattern of | | containing resist | |
| | | resist film | | underlayer film | |
| | Sensitivity | CD | LWR | CD | LWR |
| | (mJ/cm²) | (nm) | (nm) | (nm) | (nm) |
| Example 1 | 22.5 | 65.5 | 9.1 | 58.4 | 9.2 |
| Example 2 | 22.5 | 65.2 | 8.9 | 58.0 | 8.9 |
| Example 3 | 22.5 | 64.8 | 9.2 | 57.3 | 8.9 |
| Example 4 | 22.5 | 65.0 | 9.3 | 57.5 | 8.9 |
| Example 5 | 22.5 | 65.3 | 9.3 | 57.5 | 9.1 |
| Comparative | 22.5 | 65.2 | 8.9 | 58.2 | 9.8 |
| Example 1 | | | | | |

As shown in Table 5, when each polysiloxane film formed using the silicon-containing resist underlayer film-forming composition containing an aromatic iodine compound is used as a resist underlayer film, deterioration of LWR due to dry etching is suppressed. Meanwhile, the composition of Comparative Example 1 having no aromatic iodine compound resulted in deterioration of LWR.

1. A silicon-containing resist underlayer film-forming composition comprising:
a component [A]: a polysiloxane;
a component [B]: an aromatic iodine compound; and
a component [C]: a solvent.

2. The silicon-containing resist underlayer film-forming composition according to claim 1, wherein the component [B] includes at least one selected from a carboxy group, a hydroxy group, a sulfo group, and an amino group.

3. The silicon-containing resist underlayer film-forming composition according to claim 1, wherein the component [B] is an aromatic iodonium salt.

4. The silicon-containing resist underlayer film-forming composition according to claim 1, wherein a content of the component [B] is 0.1 to 20 parts by mass relative to 100 parts by mass of the component [A].

5. The silicon-containing resist underlayer film-forming composition according to claim 1, wherein the component [A] includes a modified polysiloxane in which at least some of silanol groups are alcohol-modified or acetal-protected.

6. The silicon-containing resist underlayer film-forming composition according to claim 1, wherein the component [C] contains an alcohol-based solvent.

7. The silicon-containing resist underlayer film-forming composition according to claim 6, wherein the component [C] contains alkylene glycol monoalkyl ether.

8. The silicon-containing resist underlayer film-forming composition according to claim 1, wherein the component [C] contains water.

9. The silicon-containing resist underlayer film-forming composition according to claim 1, further comprising a component [D]: a curing catalyst.

10. The silicon-containing resist underlayer film-forming composition according to claim 9, wherein the component [D] is not an aromatic iodonium salt.

11. The silicon-containing resist underlayer film-forming composition according to claim 1, further comprising a component [E]: nitric acid.

12. The silicon-containing resist underlayer film-forming composition according to claim 1, wherein the component [A] does not have an iodine atom directly bonded to a benzene ring.

13. The silicon-containing resist underlayer film-forming composition according to claim 1, which is for a resist underlayer film for lithography.

14. The silicon-containing resist underlayer film-forming composition according to claim 13, which is for a resist underlayer film for EUV or ArF lithography.

15. A silicon-containing resist underlayer film, which is a cured product of the silicon-containing resist underlayer film-forming composition according to claim 1.

16. A laminate comprising:
a semiconductor substrate; and
the silicon-containing resist underlayer film according to claim 15.

17. A method for producing a semiconductor element, the method comprising:
forming an organic underlayer film on a substrate;
forming a silicon-containing resist underlayer film using the silicon-containing resist underlayer film-forming composition according to claim 1 on the organic underlayer film; and
forming a resist film on the silicon-containing resist underlayer film.

18. The method for producing a semiconductor element according to claim 17, wherein in the forming the silicon-containing resist underlayer film, the silicon-containing resist underlayer film-forming composition filtered through a nylon filter is used.

19. A method for forming a pattern, the method comprising:
forming an organic underlayer film on a semiconductor substrate;
applying the silicon-containing resist underlayer film-forming composition according to claim 1 on the organic underlayer film and baking to form a silicon-containing resist underlayer film;
forming a resist film on the silicon-containing resist underlayer film;
exposing and developing the resist film to obtain a resist pattern;
etching the silicon-containing resist underlayer film using the resist pattern as a mask; and
etching the organic underlayer film using the patterned silicon-containing resist underlayer film as a mask.

20. The method for forming a pattern according to claim 19, further comprising removing the silicon-containing resist underlayer film by a wet method using a chemical solution, after etching the organic underlayer film.
